(19) United States
(12) Patent Application Publication
(10) Pub. No.: US 2009/0246653 A1
(43) Pub. Date: Oct. 1, 2009

(54) RELIEF PRINTING PLATE PRECURSOR FOR LASER ENGRAVING, RELIEF PRINTING PLATE, AND METHOD OF MANUFACTURING RELIEF PRINTING PLATE

(75) Inventors: Atsushi SUGASAKI, Shizuoka-ken (JP); Masako IMAI, Shizuoka-ken (JP)

Correspondence Address: Moss & Burke, PLLC, 401 Holland Lane, Suite 407, Alexandria, VA, 22314, US

(73) Assignee: FUJIFILM CORPORATION, Tokyo (JP)

(21) Appl. No.: 12/406,124

(22) Filed: Mar. 18, 2009

(30) Foreign Application Priority Data
Mar. 31, 2008 (JP) 2008-092990
Sep. 3, 2008 (JP) 2008-226319

(51) Int. Cl. G03F 7/004; G03F 7/20

(52) U.S. Cl. 430/18; 430/270.1; 430/306

(57) ABSTRACT

The invention provides a relief printing plate precursor for laser engraving, comprising a relief forming layer, the relief forming layer comprising a resin composition for laser engraving, and the resin composition for laser engraving comprising a binder polymer (A) that is insoluble in water and soluble in an alcohol having 1 to 4 carbon atoms. The invention further provides a method for manufacturing a relief printing plate having crosslinking components of the relief forming layer and laser engraving the relief forming layer, and a relief printing plate formed thereby.

### CROSS-REFERENCE TO RELATED APPLICATIONS

This application claims priorities under 35 USC 119 from Japanese Patent Application (JP-A) No. 2008-092990 filed on Mar. 31, 2008, and JP-A No. 2008-226319 filed on Sep. 3, 2008, the disclosures of which are incorporated by reference herein.

### BACKGROUND OF THE INVENTION

1. Technical Field

The present invention relates to a relief printing plate precursor for laser engraving, a relief printing plate, and a method of manufacturing a relief printing plate.

2. Description of the Related Art

As a method for forming a printing plate by forming a concave-convex structure on a photosensitive resin layer laminated over the surface of a support, a method of exposing a relief forming layer which has been formed using a photosensitive composition, to ultraviolet radiation through an original image film so as to selectively cure image areas, and removing uncured parts by means of a developer solution, that is, so-called “analogue plate making”, is well known.

A relief printing plate is a letterpress printing plate having a relief layer with a concave-convex structure, and such a relief layer having a concave-convex structure may be obtained by patterning a relief forming layer formed from a photosensitive composition containing, as a main component, for example, an elastomeric polymer such as synthetic rubber, a resin such as a thermoplastic resin, or a mixture of a resin and a plasticizer, to thus form a concave-convex structure. Among such relief printing plates, a printing plate having a flexible relief layer is often referred to as a flexo plate.

In the case of producing a relief printing plate by analogue plate making, since an original image film using a silver salt material is needed in general, the plate making process requires time and costs for the production of original image films. Furthermore, since chemical treatments are required in the development of original image films, and also treatments of development waste water are necessary, investigations on simpler methods of plate making, for example, methods which do not use original image films or methods which do not necessitate development treatments, are being undertaken.

### SUMMARY

In recent years, a method of making a plate having a relief forming layer by means of scanning exposure, without requiring an original image film, is being investigated.

As a technique which does not require an original image film, there has been proposed a relief printing plate precursor in which a laser-sensitive type mask layer element capable of forming an image mask is provided on a relief forming layer (see, for example, Japanese Patent No. 2773847 and Japanese Patent Application Laid-Open (JP-A) No. 9-171247). The method of making such a plate precursor is referred to as a “mask CTP method”, because an image mask having the same function as the original image film is formed from the mask layer element by means of laser irradiation that is based on image data. This method does not require an original image film, but the subsequent plate making treatment involves a process of exposing the plate precursor to ultraviolet radiation through an image mask, and then removing uncured parts by development, and from the viewpoint of requiring a development treatment, the method has a room for further improvement.

As a method of plate making which does not require a development process, a so-called “direct engraving CTP method”, in which plate making is carried out by directly engraving a relief forming layer using laser, has been proposed a number of times. The direct engraving CTP method is literally a method of forming a concave-convex structure which will serve as relief, by engraving the structure with laser. This method is advantageous in that the relief shape can be freely controlled, unlike the relief formation processes using original image films. For this reason, in the case of forming images like cutout characters, it is possible to engrave the image regions deeper than other regions, or for microdot images, to carry out shouldered engraving in consideration of resistance to the printing pressure, or the like.

Hitherto, the characteristics of plate materials for direct engraving CTP have depended on the binders used. Various binders have been suggested, such as hydrophobic elastomers (rubbers) (for example, see U.S. Pat. No. 5,798,202, Japanese Patent No. 3438404, and Japanese Patent Application Laid-Open (JP-A) Nos. 2002-3665, 2004-262135, and 2001-121833) and hydrophilic polyvinyl alcohol derivatives (for example, see JP-A No. 2006-2061).

When a hydrophobic elastomer (rubber) is used as a binder polymer in a relief forming layer, a relief layer formed from such a relief forming layer has good water resistance and, therefore, is highly resistant to aqueous inks during printing. However, such a relief layer has poor resistance to hydrophobic inks such as a UV ink. Accordingly, printing using a printing plate having such a relief layer with a hydrophobic ink may cause elution of components from the relief layer during printing, which amounts to deficient strength of the printing plate, causing deterioration in printing durability.

On the other hand, when a hydrophilic binder such as a polyvinyl alcohol derivative is used, a relief layer formed from such a relief forming layer is highly resistant to hydrophobic inks, but has very poor resistance to water. Therefore, printing using a printing plate having such a relief layer with an aqueous ink may cause elution of components from the relief layer during printing and, therefore, practical printing durability is not achieved.

As is understood from the above, a relief forming layer incorporating a commonly-used binder polymer and which is suitable for both aqueous inks and UV inks as well as exhibiting good engraving sensitivity suitable for direct engraving CTP has not yet been provided.

In recent years, relief printing plates suitable for hydrophobic inks and containing ester solvents have been studied, and compositions containing hydrophobic elastomers have been proposed (for example, see JP-A No. 2007-148322). However, such elastomers have a low glass transition temperature, and are in the form of a rubber at normal temperature. Therefore, infrared laser exposure and heat generated by a photothermal conversion agent upon exposure can be used up in amplification of vibration of molecules, which lowers the energy efficiency of the thermal decomposition of the polymer. As a result of this, sufficient engraving sensitivity cannot be achieved.

As described above, various techniques have been proposed with respect to a relief forming layer of a relief printing plate precursor for laser engraving, but a relief printing plate precursor which provides both high sensitivity when subjected to laser engraving and suitability for both aqueous inks and hydrophobic inks such as a UV ink has not yet been provided.

The present invention has been achieved by taking the above circumstances into consideration. The present invention provides a relief printing plate precursor for laser engraving which reveals high engraving sensitivity when subjected to laser engraving and provides a printing plate suitably used for printing with an aqueous ink as well as for printing with a hydrophobic ink.

The present invention further provides a method of manufacturing a relief printing plate for laser engraving using the relief printing plate precursor, and a relief printing plate formed by the manufacturing method.

Namely, a first aspect of the invention provides a relief printing plate precursor for laser engraving, comprising a relief forming layer, the relief forming layer comprising a resin composition for laser engraving, and the resin composition for laser engraving comprising a binder polymer (A) that is insoluble in water and soluble in an alcohol having 1 to 4 carbon atoms.

A second aspect of the invention provides a method for manufacturing a relief printing plate, the method comprising:

crosslinking at least a portion of components of the relief forming layer of the relief printing plate precursor for laser engraving by applying at least one of light or heat; and

laser engraving the relief forming layer that has been subjected to the crosslinking to form a relief layer.

### BRIEF DESCRIPTION OF THE DRAWING

FIG. 1 is a schematic diagram (perspective view) of a plate-making device having a laser recording device of one embodiment of one aspect of the invention.

### DETAILED DESCRIPTION

The relief printing plate precursor according to the invention has a relief forming layer which contains at least a resin composition for laser engraving, in which the resin composition for laser engraving contains at least a binder polymer (A) that is insoluble in water and soluble in an alcohol having 1 to 4 carbon atoms.

The relief forming layer of the relief printing plate precursor according to the invention has high engraving sensitivity when subjected to laser engraving. Accordingly, when the relief printing plate precursor of the invention is used, the laser engraving can be carried out at a high speed. Accordingly, the time necessary for engraving can be shortened. Further, since the resin composition of the invention can form deeper impression than conventional resin compositions for laser engraving by application of a unit amount of energy, it may also be suitable for forming a highly precise image. The relief printing plate precursor of the invention, which has the characteristics as described above, can be used in a wide range of applications for resin-formed objects to be subjected to laser engraving without particular limitation. Specific examples of the application of the relief printing plate precursor of the invention include a printing plate precursor, from a relief forming layer of which a convex relief is formed by laser engraving as described in detail in the followings, as well as to other materials and products having convexs-and-concaves or openings used for various printing plates to form images by laser engraving, such as an intaglio printing plate, a stencil printing plate, and stamp, while the invention is not limited to these. The resin composition of the invention can be particularly preferably used for a relief forming layer of a printing plate precursor for laser engraving. In preferable embodiments, the relief forming layer can be provided on an appropriate support.

Hereinafter, a layer which is an image forming layer having a flat surface to be subjected to laser engraving and contains a binder polymer is called a “relief forming layer”, and a layer which is prepared by subjecting the relief forming layer to laser engraving and has unevenness on the surface formed by the laser engraving is called a “relief layer”. When the relief layer contains a polymerizable compound in its formulation, the relief layer may be optionally subjected to a hardening treatment by heating or exposing to light after unevenness is formed by the laser engraving (a post-crosslinking treatment). It is also possible that a hardening treatment (a crosslinking treatment or a pre-crosslinking treatment) is firstly conducted by means of heating or the like before the laser engraving to make the relief forming layer being hard and then the laser engraving is conducted. The resultant which is previously subjected to a crosslinking treatment may be called a “hard relief forming layer”.

When a relief forming layer contains a polymerizable compound and a laser engraving is conducted without performing a crosslinking treatment, a relief layer which is formed therefrom and unevenness has been formed thereon may be called a “relief layer before hardening”, and a relief layer which is formed by subjecting the “relief layer before hardening” to a post-crosslinking treatment by applying energy such as heat or light may be called a “relief layer after hardening”.

The components of the relief printing plate precursor for laser engraving are further described below.

(A) Binder polymer being Insoluble in Water and Soluble in Alcohol having 1 to 4 carbon atoms

The relief forming layer used in the invention contains a binder polymer (A) which is insoluble in water and is soluble in alcohol, the alcohol having 1 to 4 carbon atoms (hereinafter may be referred to as “the specific polymer”, “the specific polymer (A)”, or “the specific binder polymer (A)”).

In the invention, the binder polymer (A) insoluble in water and soluble in alcohol is used because it can have suitability for both of an aqueous ink and a UV ink. The “alcohol” herein mentioned refers to so-called a “lower alcohol”, which is an alcohol having 1 to 4 carbon atoms.

According to the invention, the specific polymer has high polarity and is insoluble in water to achieve the suitability for both of an aqueous ink and a UV ink when contained in the relief forming layer.

In the invention, the description that a binder polymer is “insoluble in a certain liquid” refers to a state where a precipitate of the binder polymer is found or a state where the solution (dispersion) is cloudy even though no precipitate is found by visual observation after mixing 0.1 g of the binder polymer with 2 ml of the certain liquid (for example, water or an organic solvent), and then allowing the mixture to stand with capping a contained of the mixture at room temperature for 24 hours. The description that a binder polymer is “soluble in a certain liquid” refers to a state where no precipitate of the binder polymer is found and the solution is transparent and uniform by visual observation after mixing and standing under the above conditions.

The mechanism of action caused by the use of the binder polymer (A) insoluble in water and soluble in lower alcohols is unknown, while it is estimated as follows.

The binder is insoluble in water. Therefore, a phenomenon of elution of low molecular components from the relief layer due to swelling of the relief layer by an aqueous ink during printing can be suppressed so that the deterioration of the film strength of the relief forming can be prevented. Accordingly, the suitability of the relief forming layer for an aqueous ink can be improved.

Further, since the binder is soluble in alcohol, molecules of the alcohol used to form the relief forming layer have a high affinity for the specific polymer (A). Therefore, chain structures of the specific polymer (A) can be unfolded (namely, voids at a molecular level can be effectively formed in the structure of the specific polymer (A)) by the molecules of the alcohol when the relief forming layer is formed. As a result of this, other components contained in the relief forming layer can readily get into the unfolded portions or the voids at a molecular level in the specific polymer (A), thus forming the relief forming layer as a uniform film composed of a composition which contains the specific polymer (A) being mixed with the other components at a molecular level. The relief forming layer thus formed can be less susceptible to damages caused by permeation of inks comparing to films having non-uniform configuration at a molecular level.

The specific binder polymer (A) is preferably soluble in alcohol. Examples of the alcohol which are preferable in view of achieving good suitability for UV inks include methanol, ethanol, 2-propanol, 1-propanol, 1 -methoxy-2-propanol, 1 -butanol, and tert-butanol. The specific binder polymer (A) is preferably soluble in at least one of these alcohols. The specific binder polymer (A) is more preferably soluble in at least one of methanol, ethanol, 2-propanol, or 1-methoxy-2-propanol, and particularly preferably soluble in all of methanol, ethanol, and 1-methoxy-2-propanol.

The specific polymer (A) is more preferably insoluble in ester solvents such as ethyl acetate. When the specific polymer (A) is insoluble in ester solvents, a phenomenon of elution of low molecular components from the relief layer due to swelling of the relief layer by a UV ink during printing can be suppressed so that the deterioration of the film strength of the relief forming can be prevented. Accordingly, the suitability of the relief forming layer for a UV ink can be improved.

When the specific polymer (A) is a substance having a glass transition temperature, the glass transition temperature is preferably from 20° C. to below 200° C., more preferably from 20° C. to 170° C., and particularly preferably from 25° C. to 150° C. in view of balancing between the engraving sensitivity and the film forming property of the relief forming layer.

The expression of “the glass transition temperature (Tg) is room temperature or higher” herein means that the Tg is 20° C. or higher.

In view of achieving suitability for both of an aqueous ink and a UV ink as well as high engraving sensitivity and good film forming property, particularly preferable examples of the specific polymer (A) include polyurethane, polyvinyl butyral (PVB) compounds, alcohol-soluble polyamides, water-insoluble cellulose compounds, and acrylic resins having a polar group in a side chain thereof.

In the invention, it is particularly preferable that the specific polymer (A) is used in combination with a photo-thermal conversion agent (D) which absorbs light having a wavelength of 700 nm to 1300 nm. The photo-thermal conversion agent (D), which is explained below, is a preferable additional component of a resin composition for laser engraving to form the relief forming layer. The engraving sensitivity can be improved by using the photo-thermal conversion agent (D) in combination with the specific polymer (A), since the Tg of the specific polymer (A) can be within the above range by the combination. The binder polymer having such the glass transition temperature is hereinafter referred to as a non-elastomer. In this regard, an “elastomer” is defined in the field of science as a polymer having a glass transition temperature not higher than the normal temperature (Kagaku Daijiten, the second edition, edited by Foundation for Advancement of International Science, published by Maruzen Co., Ltd., p. 154). Accordingly, a “non-elastomer” should be understood a polymer having a glass transition temperature higher than the normal temperature.

When the specific polymer (A) is a polymer having a glass transition temperature of not lower than room temperature (20° C.), the specific polymer (A) may be in a glassy state at normal temperature, in which the molecular motion of the specific polymer (A) corresponding to heat is remarkably suppressed in comparison with a state in which the specific polymer (A) is in a rubbery state. In laser engraving, not only the heat applied by an infrared laser during laser irradiation but also the heat generated by the photo-thermal conversion agent (D), which is an optional additive, can be transferred to the specific polymer (A) which resides in the vicinity thereof These heats bring about thermal decomposition and dissipation of the specific polymer (A) to cause thus engraved to form a recess.

In preferable embodiments, improvement of the engraving sensitivity can be enhanced by the efficient heat transfer to the specific polymer (A) to efficiently cause the thermal decomposition when the photo-thermal conversion agent (D) coexist in a condition in which the molecular motion of the specific polymer (A) corresponding to heat is suppressed

On the other hand, when the glass transition temperature of the specific polymer (A) is below room temperature, the polymer is a rubbery state in which the molecular motion of the polymer corresponding to heat is not suppressed. Herein, the intermolecular distance between the photo-thermal conversion agent (D) and the specific polymer (A) becomes larger (in other words, the intermolecular volume (space) extremely increases), due to the vigorous vibration of molecules (more specifically, the molecular motion corresponding to heat). As a result of this, the efficiency of heat transfer from the photo-thermal conversion agent (D) to the specific polymer (A) may decrease, and further, the heat thus transferred may contribute to active motion of the molecules to cause heat loss. Therefore, the degree of contribution of the transferred heat to efficient thermal decomposition can be decreased, so that the specific polymer (A) may hardly improve the engraving sensitivity.

Specific examples of polymers which are included in particularly preferable examples of the specific polymer (A) are shown below.

Polyvinyl butyral (PVB) and Compound obtained by modifying PVB

Preferable examples of the specific polymer (A) include PVB and a PVB compound obtained by modifying PVB.

The PVB may be either a homopolymer or a polyvinylbutyral compound.

The content of butyral in the PVB compound is preferably in the range of 30% to 90%, more preferably in the range of 50% to 80%, and particularly preferably in the range of 55% to 78% with respect to the total molar number of the material monomers defined as 100%.

In view of keeping the balance between engraving sensitivity and filming property of the relief forming layer, the molecular weight of PVB and the PVB compound is preferably in the range of 5,000 to 800,000, more preferably in the range of 8,000 to 500,000, and particularly preferably in the range of 10,000 to 300,000 in terms of weight-average molecular weight.

PVB and PVB compounds can be available as a commercial product. Specific examples thereof which are preferable in view of its solubility in alcohol (particularly ethanol) include “ESREC B” series and “ESREC K (KS)” series (both trade names, manufactured by Sekisui Chemical Co., Ltd.), and “DENKA BUTYRAL” series (trade name, manufactured by Denki Kagaku Kogyo). Specific examples which are more preferable in view of its solubility in alcohol (particularly ethanol) include “ESREC B” series (described above) and “DENKA BUTYRAL” series (described above). Further preferable examples include “BL-1”, “BL-1H”, “BL-2”, “BL-5”, “BL-S”, “BX-L”, “BM-S” and “BH-S” of “ESREC B” series (all trade names, manufactured by Sekisui Chemical Co., Ltd.) and “#3000-1”, “#3000-2”, “#3000-4”, “#4000-2”, “#6000-C”, “#6000-EP”, “#6000-CS” and “#6000-AS” of “DENKA BUTYRAL” series (all trade names, manufactured by Denki Kagaku Kogyo).

When PVB is used as the specific polymer (A) to form a film of the relief forming layer, the relief forming layer is preferably formed by a method including casting a solution in which PVB is dissolved in a solvent and drying the solution in view of improving the flatness and smoothness of the surface of the relief forming layer.

Alcohol-Soluble Polyamide

A polyamide obtained by introducing, into its main chain, a polar group such as polyethylene glycol or piperazine, has an improved solubility to alcohol due to the effect of the polar group, and can be thus preferably used as the specific polymer (A)

For example, a polyamide having a polyethylene glycol unit (, which is also called as a polyethylene oxide segment) can be obtained by reacting ε-caprolactam and/or adipic acid with a polyethylene glycol modified with amine at both chain ends. A hydrophilic polyamide having a piperazine skeleton is obtained by reacting ε-caprolactam and/or adipic acid with piperazine.

The polyamide containing a polyethylene glycol unit is usually a polyetheramide prepared by polycondensation or copolycondensation of diamine monomers containing at least α,ω-diaminopropylpoly(oxyethylene) under a known method (for example, JP-A No. 55-79437), or a polyether ester amide prepared by polycondensation or copolycondensation of diol components containing at least polyethylene glycol under a known method (for example, JP-A No. 50-159586). However, the polyamide is not particularly limited, and may be selected from a wide range of polymers having an amide bond in the main chain thereof.

The number average molecular weight of the polyethylene oxide segment is preferably from 150 to 5,000, and more preferably from 200 to 3,000 in view of maintaining the shape of the plate material. The number average molecular weight of the polyamide having the polyethylene oxide segment is preferably from 5,000 to 300,000, more preferably from 10,000 to 200,000, and particularly preferably from 10,000 to 50,000.

Preferable examples of the polyamide preferably include one which has, in the main chain thereof, a unit with high polarity such as polyethylene oxide. In this regard, a polyamide having, in a side chain thereof, a functional group with high polarity can also exhibit a performance similar to that of the polyamide having the high polarity-unit. Accordingly, the polyamide having the high polarity-functional group in a side chain thereof can be also preferably used as the specific binder polymer (A) in the invention.

From the viewpoint of engraving sensitivity, the polyamide having a high polarity-functional group in a side chain thereof can be more preferably used in the invention.

Specifically, preferable examples thereof include methoxymethylated polyamide and methoxymethylated nylon. Among commercial products of the polyamide compounds, methoxymethylated polyamides of “TORESIN” series (trade name, manufactured by Nagase ChemteX Corporation) are preferable, and methoxymethylated polyamides “TORESIN F-30K” and “TORESIN EF-30T” (both trade names, manufactured by Nagase ChemteX Corporation) are particularly preferable.

(3) Cellulose Compound

Normal cellulose is scarcely soluble in water and alcohols. However, the solubility of cellulose in water or a solvent is controllable through the modification of a residual —OH in a glucopyranose unit with a specific functional group. Therefore, a cellulose compound insoluble in water and soluble in an alcohol having 1 to 4 carbon atoms can be suitable as the specific binder polymer (A) used in the invention.

The cellulose compounds suitable for the invention are insoluble in water and soluble in lower alcohols, and examples thereof include alkyl cellulose such as ethyl cellulose or methyl cellulose, hydroxyethylene cellulose, hydroxypropylene cellulose, and cellulose acetate butylate.

Specific examples include METOLOSE series (trade name, manufactured by Shin-Etsu Chemical Co., Ltd.). The METOLOSE series provides cellulose compounds in which some hydrogen atoms in hydroxy groups thereof are respectively substituted with a methyl group (—CH₃), a hydroxypropyl (—CH₂CHOHCH₃) group, or a hydroxyethyl (—CH₂CH₂OH) group.

In view of achieving alcohol solubility and engraving sensitivity for the purpose of the invention, alkyl cellulose is preferable, and ethyl cellulose and methyl cellulose are particularly preferable.

(4) Epoxy Resin

Examples of the epoxy resin preferably used in view of achieving water insolubility in the invention, which is insoluble in water and soluble in alcohol, is a bisphenol A type-epoxy resin and a modified epoxy resin formed by polymerizing or functionalizing a bisphenol A type-epoxy resin with a modifier. Particularly preferable is the modified epoxy resin.

Specific examples of preferable modified epoxy resins include “ARAKYD 9201N”, “ARAKYD 9203N”, “ARAKYD 9205”, “ARAKYD 9208”, “KA-1439A”, “MODEPICS 401”, and “MODEPICS 402” (all trade names, manufactured by Arakawa Chemical Industries, Ltd.).

(5) Acrylic Resin

The water-insoluble and alcohol-soluble acrylic resin useful in the invention may be prepared from known acrylic monomers, and its solubility can be controlled so as to satisfy the above-described conditions. Preferable examples of the acrylic monomers used for the synthesis of the acrylic resin include (meth)acrylates, crotonates, and (meth)acrylamides. Specific examples of these monomers include the following compounds.

Examples of (meth)acrylates include methyl(meth)acrylate, ethyl(meth)acrylate, n-propyl(meth)acrylate, isopropyl(meth)acrylate, n-butyl(meth)acrylate, isobutyl(meth)acrylate, tert-butyl(meth)acrylate, n-hexyl(meth)acrylate, 2-ethylhexyl(meth)acrylate, acetoxyethyl(meth)acrylate, phenyl(meth)acrylate, 2-hydroxyethyl(meth)acrylate, 2-hydroxypropyl(meth)acrylate, 4-hydroxybutyl(meth)acrylate, 2-methoxyethyl(meth)acrylate, 2-ethoxyethyl(meth)acrylate, 2-(2-methoxyethoxy)ethyl(meth)acrylate, cyclohexyl(meth)acrylate, benzyl(meth)acrylate, diethylene glycol monomethyl ether(meth)acrylate, diethylene glycol monoethyl ether(meth)acrylate, diethylene glycol monophenyl ether(meth)acrylate, triethylene glycol monomethyl ether(meth)acrylate, triethylene glycol monoethyl ether(meth)acrylate, dipropyleneglycol monomethyl ether(meth)acrylate, polyethylene glycol monomethyl ether(meth)acrylate, polypropylene glycol monomethyl ether(meth)acrylate, monomethyl ether(meth)acrylates of copolymers formed of ethylene glycol and propylene glycol, N,N-dimethylaminoethyl(meth)acrylate, N,N-diethylaminoethyl(meth)acrylate, and N,N-dimethylaminopropyl(meth)acrylate.

Among them, from the viewpoint of solubility to alcohol, diethylene glycol monomethyl ether(meth)acrylate, diethylene glycol monoethyl ether(meth)acrylate, diethylene glycol monophenylether(meth)acrylate, triethylene glycol monomethyl ether(meth)acrylate, triethylene glycol monoethyl ether(meth)acrylate, dipropyleneglycol monomethyl ether(meth)acrylate, polyethylene glycol monomethyl ether(meth)acrylate, polypropylene glycol monomethyl ether(meth)acrylate, and monomethyl ether(meth)acrylates of copolymers formed of ethylene glycol and propylene glycol are preferable.

Examples of the crotonates include butyl crotonate and hexyl crotonate.

Examples of the (meth)acrylamides include (meth)acrylamide, N-methyl(meth)acrylamide, N-ethyl(meth)acrylamide, N-propyl(meth)acrylamide, N-n-butyl acryl(meth)amide, N-tert-butyl(meth)acrylamide, N-cyclohexyl(meth)acrylamide, N-(2-methoxyethyl)(meth)acrylamide, N,N-dimethyl(meth)acrylamide, N,N-diethyl(meth)acrylamide, N-phenyl(meth)acrylamide, N-benzyl(meth)acrylamide, and (meth)acryloyl morpholine.

Preferable examples of the acrylic resin further include modified acrylic resins composed of acrylic monomers having an urethane or urea group.

Specific examples of the acrylic monomer useful for the synthesis of the specific polymer (A) include the following exemplary monomers (AM-1) to (AM-22).

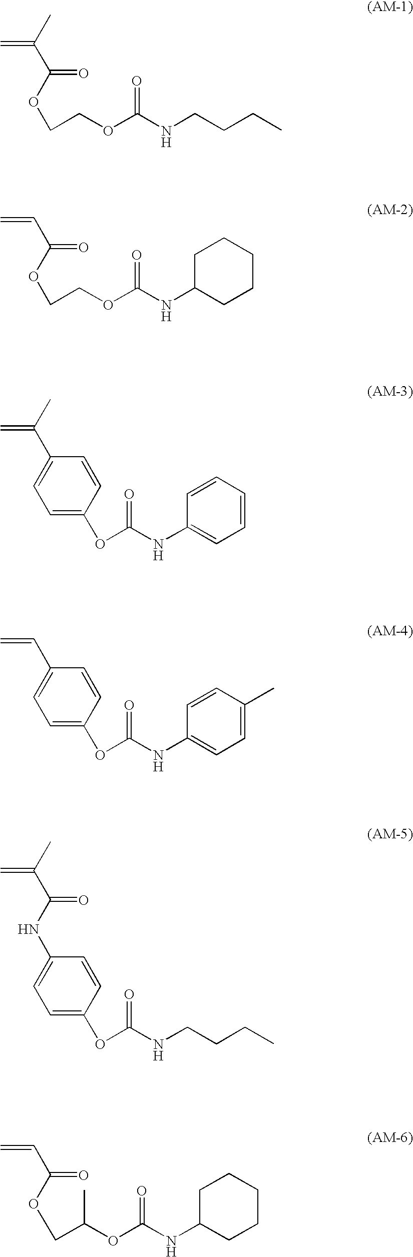

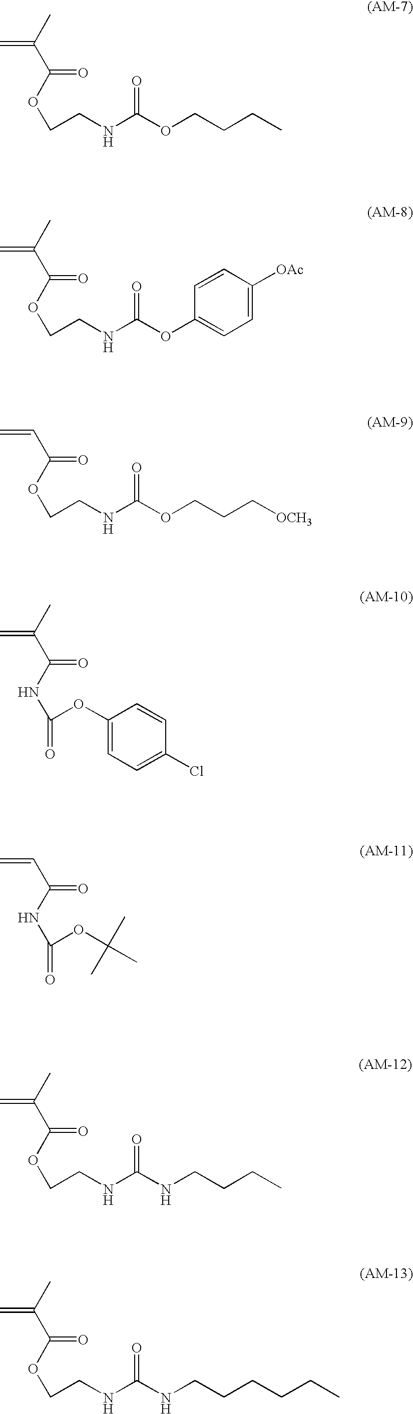

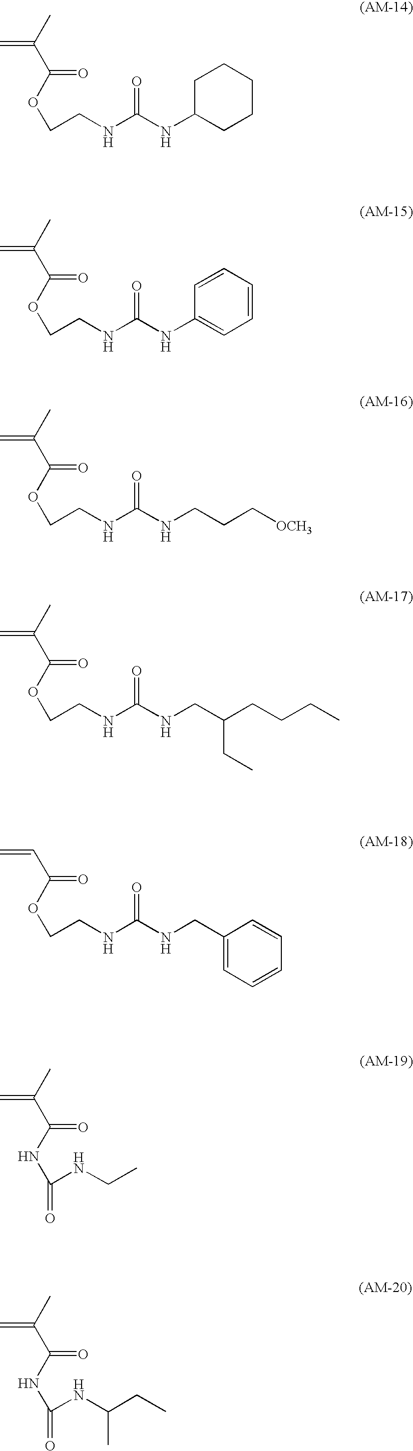

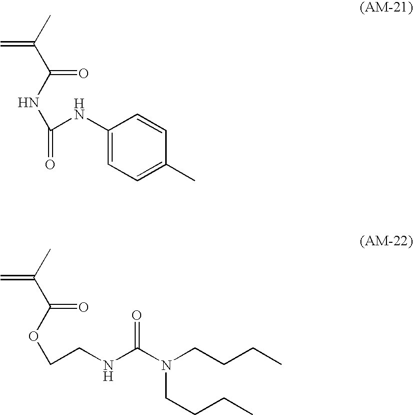

Specific examples of the acrylic resin suitable as the specific polymer (A) in the invention are listed below, accompanied by the weight average molecular weight measured by GPC [indicated with Mw (GPC)] thereof, while the acrylic resin which can be used in the invention is not limited to them, and any acrylic resin can be used as long as it achieves the above-described preferable properties.

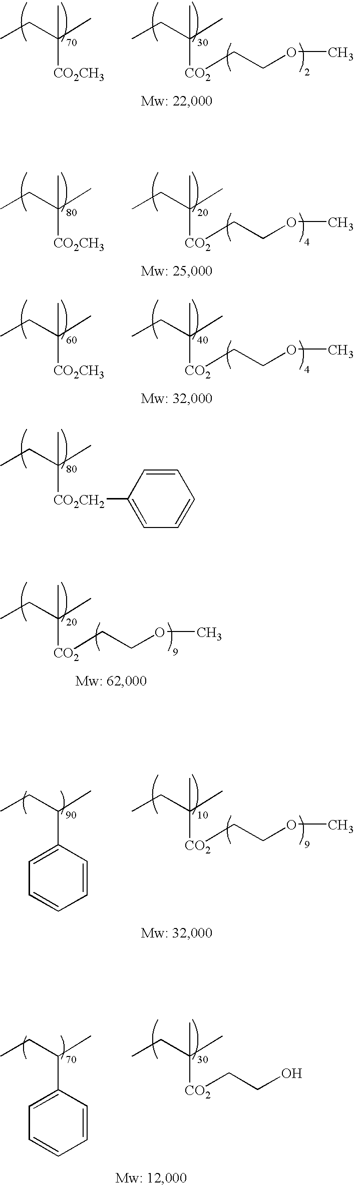

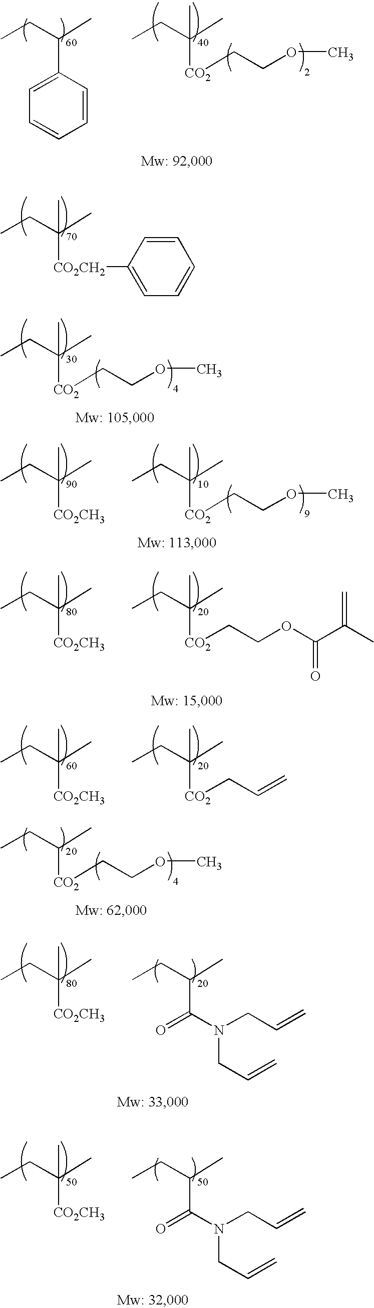

(6) Polyurethane Resin

In the invention, the polyurethane resin useful as the specific polymer (A) is that having a primary structure having a structural unit resulting from the reaction between at least one diisocyanate compound represented by the following Formula (U-1) and at least one diol compound represented by the following Formula (U-2). The polyurethane resin useful as the specific polymer (A) may be hereinafter referred to as a “specific polyurethane”.

OCN—X⁰—NCO (U-1)

HO—Y⁰—O—OH (U-2)

In Formulae (U-1) and (U-2), X⁰ and Y⁰ each independently represent a divalent organic residue. At least one of the organic residues represented by X⁰ and Y⁰ is linked to the NCO group or the OH group via an aromatic group.

(1) Diisocyanate Compound

In the diisocyanate compound represented by Formula (U-1), the organic residue represented by X⁰ preferably has an aromatic group directly linked to the NCO group.

The diisocyanate compound is preferably represented by Formula (U-3).

OCN-L¹-NCO (U-3)

In Formula (U-3), L¹ represents a divalent aromatic hydrocarbon group which may have a substitutent. Examples of the substituent include an alkyl group, an aralkyl group, an aryl group, an alkoxy group, an aryloxy group, and a halogen atom (—F, —Cl, —Br, and —I). As necessary, L¹ may have other functional group which will not react with an isocyanate group, such as an ester, urethane, amide, or ureido group.

Specific examples of the diisocyanate compound represented by Formula (U-3) include aromatic diisocyanate compounds such as 2,4-tolylene diisocyanate, a dimer of 2,4-tolylene diisocyanate, 2,6-tolylene diisocyanate, p-xylylene diisocyanate, m-xylylene diisocyanate, 4,4′-diphenylmethane diisocyanate, 1,5-naphthylene diisocyanate, and 3,3′-dimethylbiphenyl-4,4′-diisocyanate.

Among them, from the viewpoint of thermal decomposability, 4,4′-diphenylmethane diisocyanate and 1,5-naphthylene diisocyanate are preferable.

The polyurethane resin used as the specific polymer (A) may contain another diisocyanate compound which is different from the above ones for purposes such as improving the compatibility of the polyurethane resin with other components in the resin composition for laser engraving to improve the storage stability.

Examples of such another diisocyanate compound include: aliphatic diisocyanate compounds such as hexamethylene diisocyanate, trimethyl hexamethylene diisocyanate, lysine diisocyanate, or dimer acid diisocyanate; alicyclic diisocyanate compounds such as isophorone diisocyanate, 4,4′-methylene bis(cyclohexyl isocyanate), methyl cyclohexane-2,4(or 2,6)diisocyanate, or 1,3-(isocyanate methyl)cyclohexane; and diisocyanate compounds formed by the reaction between diol and diisocyanate, such as an adduct of 1 mole of 1,3-butyleneglycol and 2 moles of tolylene diisocyanate.

Examples thereof further include a diisocyanate formed by adding a monofunctional alcohol to one of three NCO groups of triisocyanate.

(2) Diol Compound

It is particularly preferable that the organic residue represented by Y⁰ in the diol compound has an aromatic group directly linked to an OH group.

Specifically, the diol compounds represented by the following Formulae (A-1) to (A-3) are preferable.

HO—Ar¹—OH Formula (A-1)

HO—(Ar¹—Ar²)m-OH Formula (A-2)

HO—Ar¹—X—Ar²—OH Formula (A-3)

In Formulae (A-1) to (A-3), Ar¹ and Ar² may be the same or different from each other, and each represent an aromatic ring. Examples of the aromatic ring include a benzene ring, a naphthalene ring, an anthracene ring, a pyrene ring, and a heterocycle. These aromatic rings may have a substitutent. Examples of the substituent include an alkyl group, an aralkyl group, an aryl group, an alkoxy group, an aryloxy group, and a halogen atom (—F, —Cl, —Br, and —I).

From the viewpoint of ease of availability of the raw material, Ar¹ and Ar² preferably each represent a benzene ring or a naphthalene ring. Further, in consideration of the film forming property, Ar¹ and Ar² particularly preferably respectively represent a benzene ring.

X is a divalent organic residue. From the viewpoint of the film forming property, m is preferably from 1 to 3, and particularly preferably 1.

Preferable examples of the diol compound represented by Formula (A-1) include 1,4-dihydroxybenzene and 1,8-dihydroxynaphthalene.

Preferable examples of the diol compound represented by Formula (A-2) include 4,4′-dihydroxybiphenyl and 2,2′-hydroxybinaphthyl.

Preferable examples of the diol compound represented by Formula (A-3) include bisphenol A and 4,4′-bis(hydroxyphenyl)methane.

The polyurethane resin used as the specific polymer (A) may contain another diisocyanate compound which is different from the above ones for purposes such as improving the compatibility of the polyurethane resin with other components in the resin composition for laser engraving to improve the storage stability.

Examples of such another diisocyanate compound include polyether diol compounds, polyester diol compounds, and polycarbonate diol compounds.

Examples of the polyether diol compounds include the compounds represented by any one of the following Formulae (U-4), (U-5), (U-6), (U-7), and (U-8), and an ethylene oxide-propylene oxide random copolymer having hydroxyl groups at the terminal thereof.

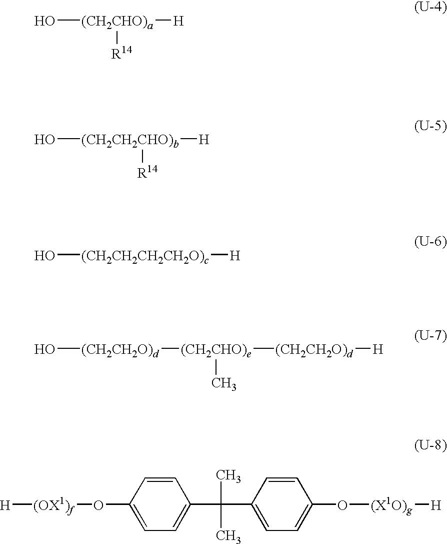

In Formulae (U-4) to (U-8), R¹⁴ represents a hydrogen atom or a methyl group. X¹ represents either one of the following groups. a, b, c, d, e, f, and g each independently represent an integer of 2 or more, preferably an integer of 2 to 100.

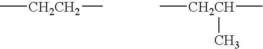

Specific examples of the polyether diol compound represented by Formula (U-4) or (U-5) include: diethylene glycol, triethylene glycol, tetraethylene glycol, pentaethylene glycol, hexaethylene glycol, heptaethylene glycol, octaethylene glycol, di-1,2-propylene glycol, tri-1,2-propylene glycol, tetra-1,2-propylene glycol, hexa-1,2-propylene glycol, di-1,3-propylene glycol, tri-1,3-propylene glycol, tetra-1,3-propylene glycol, di-1,3-butylene glycol, tri-1,3-butylene glycol, hexa-1,3-butylene glycol, polyethylene glycol having a mass average molecular weight of 1000, polyethylene glycol having a mass average molecular weight of 1500, polyethylene glycol having a mass average molecular weight of 2000, polyethylene glycol having a mass average molecular weight of 3000, polyethylene glycol having a mass average molecular weight of 7500, polypropylene glycol having a mass average molecular weight of 400, polypropylene glycol having a mass average molecular weight of 700, polypropylene glycol having a mass average molecular weight of 1000, polypropylene glycol having a mass average molecular weight of 2000, polypropylene glycol having a mass average molecular weight of 3000, and polypropylene glycol having a mass average molecular weight of 4000.

Specific examples of the polyether diol compound represented by Formula (U-6) include: PTMG650, PTMG1000, PTMG2000, and PTMG3000 (all trade names, manufactured by Sanyo Chemical Industries, Ltd.).

Specific examples of the polyether diol compound represented by Formula (U-7) include: NEWPOL PE-61, NEWPOL PE-62, NEWPOL PE-64, NEWPOL PE-68, NEWPOL PE-71, NEWPOL PE-74, NEWPOL PE-75, NEWPOL PE-78, NEWPOL PE-108, NEWPOL PE-128, and NEWPOL PE-61 (all trade names, manufactured by Sanyo Chemical Industries, Ltd.).

Specific examples of the polyether diol compound represented by Formula (U-8) include: NEWPOL BPE-20, NEWPOL BPE-20F, NEWPOL BPE-20NK, NEWPOL BPE-20T, NEWPOL BPE-20G, NEWPOL BPE-40, NEWPOL BPE-60, NEWPOL BPE-100, NEWPOL BPE-180, NEWPOL BPE-2P, NEWPOL BPE-23P, NEWPOL BPE-324P, and NEWPOL BPE-5P (all trade names, manufactured by Sanyo Chemical Industries, Ltd.).

Specific examples of the ethylene oxide-propylene oxide random copolymer having a hydroxyl group at the terminal thereof include: NEWPOL 50HB-100, NEWPOL 50HB-260, NEWPOL 50HB-400, NEWPOL 50HB-660, NEWPOL 50HB-2000, and NEWPOL 50HB-5 100 (trade names, manufactured by Sanyo Chemical Industries, Ltd.).

Examples of the polyester diol compound include a compound represented by the following Formula (U-9) or (U-10).

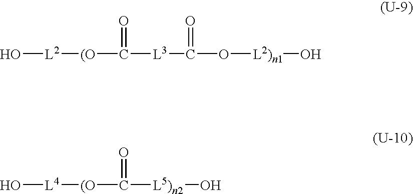

In Formulae (U-9) and (U-10), L², L³, and L⁴ may be the same or different from each other, and each represent a divalent aliphatic group or a divalent aromatic hydrocarbon group, and L⁵ represents a divalent aliphatic hydrocarbon group. Preferably, L² to L⁴ each represent an alkylene group, an alkenylene group, an alkynylene group, or an arylene group, and L⁵ represents an alkylene group. L² to L⁵ may contain another functional group which will not react with an isocyanate group, such as an ether group, a carbonyl group, an ester group, a cyano group, an olefin group, an urethane group, an amide group, an ureido group, or a halogen atom. n1 and n2 each represent an integer of 2 or more, and preferably an integer of 2 to 100.

Examples of the polycarbonate diol compound include the compound represented by Formula (U-11).

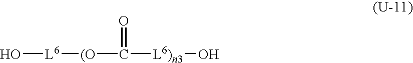

In Formula (U-12), L⁶s may be the same or different from each other, and each represent a divalent aliphatic hydrocarbon group or a divalent aromatic hydrocarbon group, preferably an alkylene group, an alkenylene group, an alkynylene group, or an arylene group. The L⁶ may contain other functional group which will not react with an isocyanate group, for example, an ether group, a carbonyl group, an ester group, a cyano group, an olefin group, an urethane group, an amide group, an ureido group, or a halogen atom. n3 is an integer of 2 or more, preferably an integer of 2 to 100.

Specific examples of the diol compound represented by any one of Formula (U-9), (U-10), and (U-11) include the exemplary compounds No. 1 to No. 18 shown below. In the exemplary compounds, n represents an integer of 2 or more.

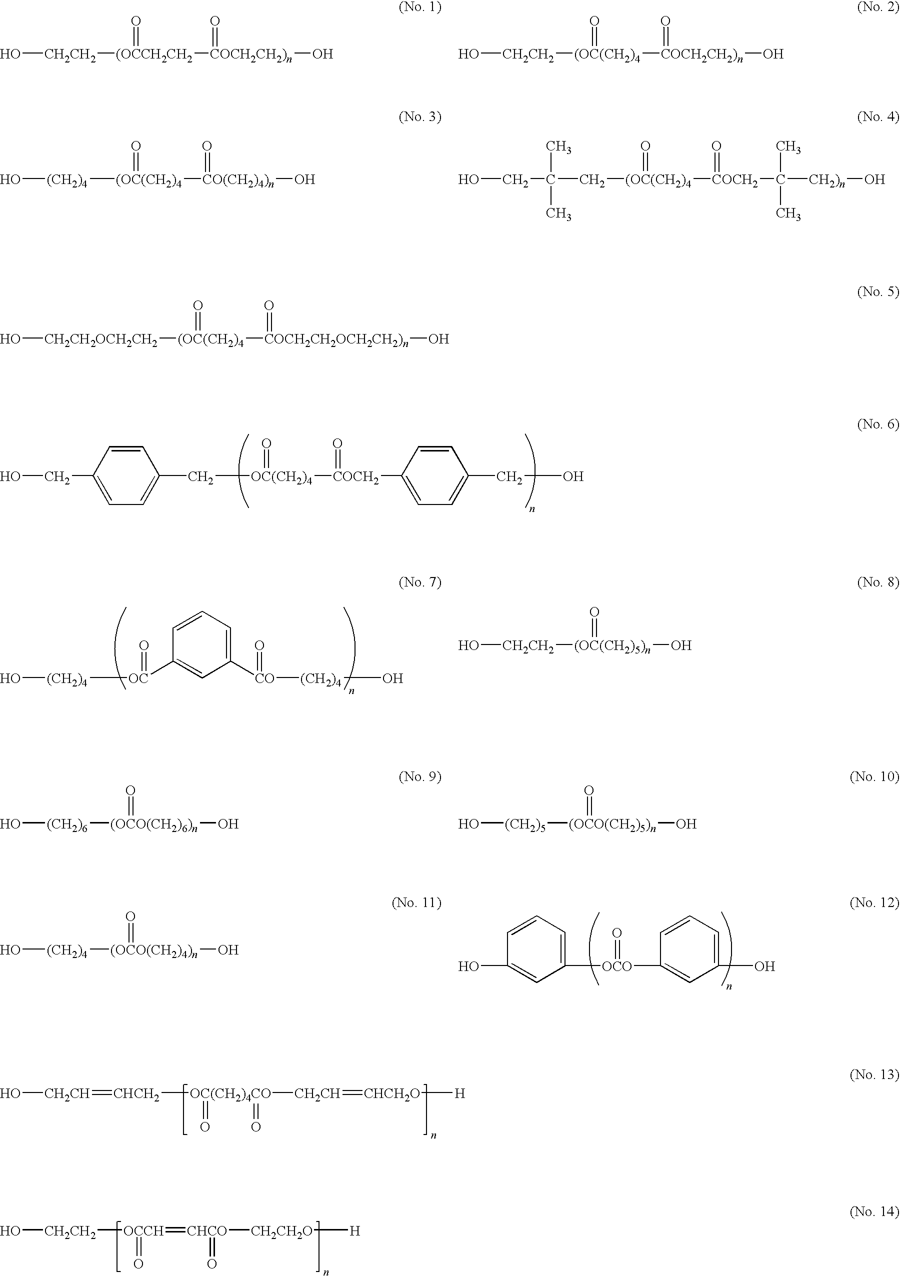

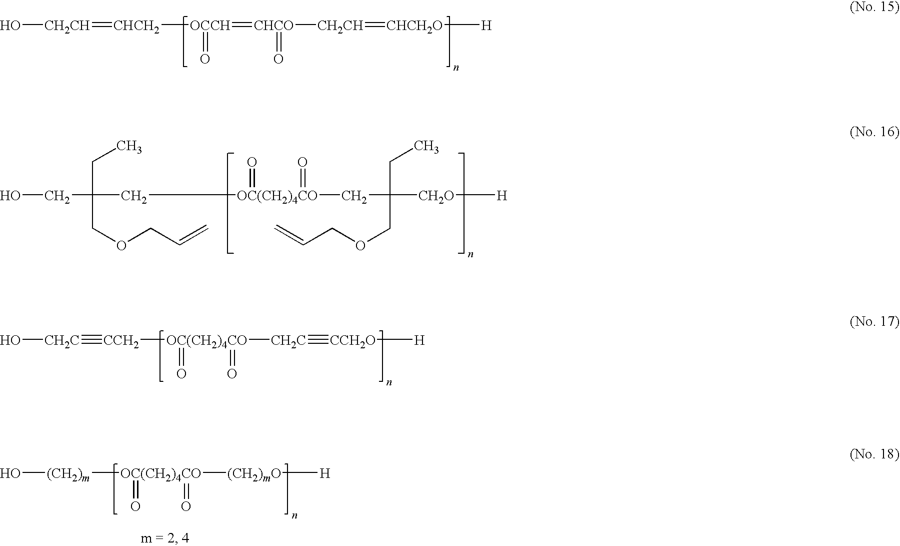

In addition to the above-described diol compound, other diol compound having a substituent which will not react with an isocyanate group may be used in the synthesis of the polyurethane resin. Examples of such a diol compound include the followings.

HO-L⁷-O—CO-L⁸-CO—O-L⁷-OH (U-12)

HO-L⁸-CO—O-L⁷-OH (U-13)

In Formulae (U-12) and (U-13), L⁷ and L⁸ may be the same or different from each other, and each represent a divalent aliphatic hydrocarbon group, a divalent aromatic hydrocarbon group, or a divalent heterocyclic group which may have a substitutent. Examples of the substituent include an alkyl group, an aralkyl group, an aryl group, an alkoxy group, an aryloxy group, and a halogen atom (—F, —Cl, —Br, and —I). As necessary, L⁷ and/or L⁸ may contain other functional group which will not react with an isocyanate group, such as a carbonyl group, an ester group, an urethane group, an amide group, or an ureido group. L⁷ and L⁸ may be linked together to form a ring.

For the synthesis of the specific polyurethane resin, a diol compound having an acid group such as a carboxyl group, a sulfone group, and/or a phosphate group may be used. In particular, a diol compound having a carboxylic group is preferable from the viewpoint of improvement of the film strength and the resistance to water caused by a hydrogen bond. Examples of the diol compound having a carboxylic group include those represented by any one of the following Formulae (U-14) to (U-16).

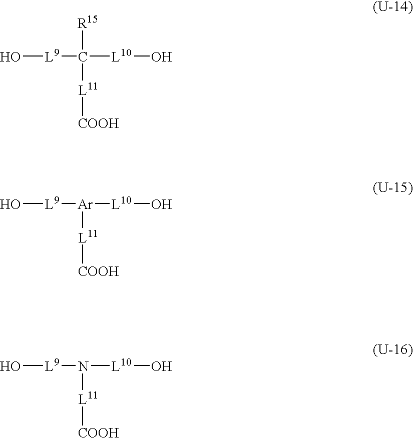

In Formulae (U-14) to (U-16), R¹⁵ represents: a hydrogen atom; or an alkyl group, an aralkyl group, an aryl group, an alkoxy group, or an aryloxy group, each of which may have a substituent. Examples of the substituent include a cyano group, a nitro group, a halogen atom such as —F, —Cl, —Br, or —I, —CONH₂, —COOR¹⁶, —OR¹⁶, —NHCONHR¹⁶, —NHCOOR¹⁶, —NHCOR¹⁶, or —OCONHR¹⁶, wherein R¹⁶ represents an alkyl group having 1 to 10 carbon atoms or an aralkyl group having 7 to 15 carbon atoms. R¹⁵ preferably represents a hydrogen atom, an alkyl group having 1 to 8 carbon atoms, or an aryl group having 6 to 15 carbon atoms. L⁹, L¹⁰, and L¹¹ may the same or different from each other, and each independently represent a single bond, a divalent aliphatic hydrocarbon or divalent aromatic hydrocarbon group which may have a substituent. Preferable examples of the substituent include an alkyl group, an aralkyl group, an aryl group, an alkoxy group, or a halogeno group. L⁹, L¹⁰, and L¹¹ each independently preferably represent an arylene group having 1 to 20 carbon atoms or an alkylene group having 6 to 15 carbon atoms, and more preferably represent an alkylene group having 1 to 8 carbon atoms. As necessary, L⁹ to L¹¹ may contain other functional group which will not react with an isocyanate group such as a carbonyl group, an ester group, an urethane group, an amide group, an ureido group, or an ether group. Two or three of R¹⁵, L⁷, L⁸, and L⁹ may be linked together to form a ring.

Ar represents a trivalent aromatic hydrocarbon group which may have a substitutent, and preferably represents an aromatic group having 6 to 15 carbon atoms.

Specific examples of the diol compound having a carboxylic group represented by any one of Formulae (U-14) to (U-16) include 3,5-dihydroxybenzoic acid, 2,2-bis(hydroxymethyl)propionic acid, 2,2-bis(2-hydroxyethyl)propionic acid, 2,2-bis(3-hydroxypropyl)propionic acid, bis(hydroxymethyl)acetic acid, bis(4-hydroxyphenyl)acetic acid, 2,2-bis(hydroxymethyl)butyric acid, 4,4-bis(4-hydroxyphenyl)pentanoic acid, tartaric acid, N,N-dihydroxyethyl glycine, and N,N-bis(2-hydroxyethyl)-3-carboxy-propionamide.

A compound obtained by decyclization of a tetracarboxylic dianhydride represented by any of the following Formulae (U-17) to (U-19) with a diol compound may be used for the synthesis of the specific polyurethane resin.

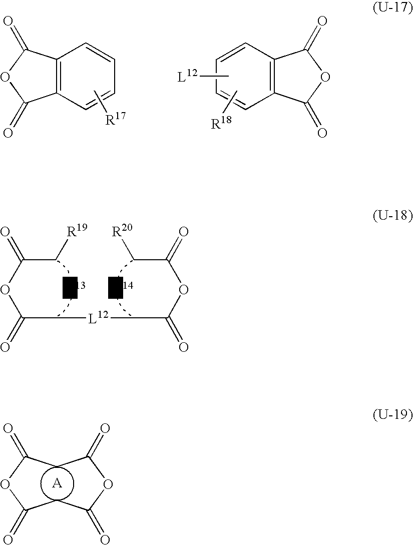

In Formulae (U-17) to (U-19), L¹² represents a single bond, a divalent aliphatic hydrocarbon or a divalent aromatic hydrocarbon group which may have a substituent (preferable examples of the substituent include an alkyl group, an aralkyl group, an aryl group, an alkoxy group, a halogeno group, an ester group, and an amide group), —CO—, —SO—, —SO₂—, —O—, or —S—, and preferably represents a single bond, a divalent aliphatic hydrocarbon group having 1 to 15 carbon atoms, —CO—, —SO₂—, —O—, or S—. R¹⁷ and R¹⁸ may be may be the same or different from each other, and each represent a hydrogen atom, an alkyl group, an aralkyl group, an aryl group, an alkoxy group, or a halogeno group, and preferably represent a hydrogen atom, an alkyl group having 1 to 8 carbon atoms, an aryl group having 6 to 15 carbon atoms, an alkoxy group having 1 to 8 carbon atoms, or a halogeno group. Two of L¹², R¹⁷, and R¹⁸ may be linked together to form a ring. R¹⁹ and R²⁰ may be the same or different from each other, and each represent a hydrogen atom, an alkyl group, an aralkyl group, an aryl group, or a halogeno group, and preferably represent a hydrogen atom, an alkyl group having 1 to 8 carbon atoms, or an aryl group having 6 to 15 carbon atoms. Two of L¹², R¹⁹, and R²⁰ may be linked together to form a ring. L¹³ and L¹⁴ may be the same or different from each other, each represent a single bond, a double bond, or a divalent aliphatic hydrocarbon group, and preferably represents a single bond, a double bond, or a methylene group. A represents a mononuclear or polynuclear aromatic ring, and preferably represents an aromatic ring having 6 to 18 carbon atoms.

Specific examples of the compound represented by Formula (U-17), (U-18), or (U-19) include: aromatic tetracarboxylic dianhydrides such as pyromellitic dianhydride, 3,3′,4,4′-benzophenonetetracarboxylic dianhydride, 3,3′,4,4′-diphenyltetracarboxylic dianhydride, 2,3,6,7-naphthalenetetracarboxylic dianhydride, 1,4,5,8-naphthalenetetracarboxylic dianhydride, 4,4′-sulfonyldiphthalic dianhydride, 2,2-bis(3,4-dicarboxyphenyl)propane dianhydride, bis(3,4-dicarboxyphenyl)ether dianhydride, 4,4′-[3,3′-(alkylphosphoryldiphenylene)-bis(iminocarbonyl)]diphthalic dianhydride, an adduct of hydroquinone diacetate and trimellitic anhydride, or an adduct of diacetyldiamine and trimellitic anhydride; alicyclic tetracarboxylic dianhydrides such as 5-(2,5-dioxotetrahydrofuril)-3-methyl-3-cyclohexene-1,2-dicarboxylic anhydride (trade name: EPICLON B-4400, manufactured by Dainippon Ink And Chemicals, Incorporated), 1,2,3,4-cyclopentanetetracarboxylic dianhydride, 1,2,4,5-cyclohexanetetracarboxylic dianhydride, or tetrahydrofurantetracarboxylic dianhydride; and aliphatic tetracarboxylic dianhydrides such as 1,2,3,4-butanetetracarboxylic dianhydride or 1,2,4,5-pentanetetracarboxylic dianhydride.

Examples of a method to introduce the compound obtained by decyclization of any of these tetracarboxylic dianhydrides into a polyurethane resin include:

a) a method including reacting a diisocyanate compound with a compound having an alcohol terminal obtained by the decyclization of a tetracarboxylic dianhydride with a diol compound; and

b) a method including reacting a tetracarboxylic dianhydride with an urethane compound having an alcohol terminal obtained by the reaction of a diisocyanate compound with an excessive amount of a diol compound.

Specific examples of the diol compound used for the decyclization reaction include ethylene glycol, diethylene glycol, triethylene glycol, tetraethylene glycol, propylene glycol, dipropylene glycol, polyethylene glycol, polypropylene glycol, neopentyl glycol, 1,3-butylene glycol, 1,6-hexanediol, 2-butene-1,4-diol, 2,2,4-trimethyl-1,3-pentanediol, 1,4-bis-β-hydroxyethoxycyclohexane, cyclohexane dimethanol, tricyclodecane dimethanol, hydrogenated bisphenol A, hydrogenated bisphenol F, an ethylene oxide adduct of bisphenol A, a propylene oxide adduct of bisphenol A, an ethylene oxide adduct of bisphenol F, a propylene oxide adduct of bisphenol F, an ethylene oxide adduct of hydrogenated bisphenol A, a propylene oxide adduct of hydrogenated bisphenol A, hydroquinone dihydroxyethyl ether, p-xylylene glycol, dihydroxyethylsulfone, bis(2-hydroxyethyl)-2,4-tolylenedicarbamate, 2,4-tolylene-bis(2-hydroxyethylcarbamide), bis(2-hydroxyethyl)-m-xylylenedicarbamate, and bis(2-hydroxyethyl)isophthalate.

(3) Other Copolymerization Components

The specific polyurethane resin used in the invention may further contain, in addition to the urethane bond represented by Formula (5), an organic group as a functional group, the organic group containing at least one selected from the group consisting of an ether bond, an amide bond, an urea bond, an ester bond, an urethane bond, a biuret bond, and an allophanate bond.

The specific polyurethane resin used in the invention preferably further contains a unit having an ethylenically unsaturated bond. The polyurethane resin containing a unit having an ethylenically unsaturated bond preferably has at least one functional group represented by any one of the following Formulae (E1) to (E3) in a side chain of the resin. The functional group represented by any one of Formulae (E1) to (E3) is described below.

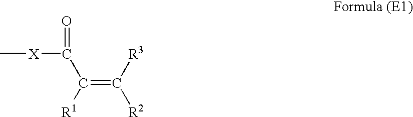

In Formula (E1), R¹ to R³ each independently represent a hydrogen atom or a monovalent organic group. Preferable examples of R¹ include a hydrogen atom and a alkyl group which may have a substituent. Among them, a hydrogen atom and a methyl group are particularly preferable due to their high radical reactivity. Examples of each of R² and R³ respectively include a hydrogen atom, a halogen atom, an amino group, a carboxyl group, an alkoxy carbonyl group, a sulfo group, a nitro group, a cyano group, an alkyl group which may have a substituent, an aryl group which may have a substituent, an alkoxy group which may have a substituent, an aryloxy group which may have a substituent, an alkylamino group which may have a substituent, an arylamino group which may have a substituent, an alkylsulfonyl group which may have a substituent, and an arylsulfonyl group which may have a substituent. Among them, a hydrogen atom, a carboxyl group, an alkoxycarbonyl group, an alkyl group which may have a substituent, and an aryl group which may have a substituent are preferable due to their high radical reactivity.

X represents an oxygen atom, a sulfur atom, or —N(R¹²), and R¹² represents a hydrogen atom or a monovalent organic group. Examples of the monovalent organic group include an alkyl group which may have a substituent. Among them, R¹² is preferably a hydrogen atom, a methyl group, an ethyl group, or an isopropyl group due to their high radical reactivity.

Examples of the substituent which may be introduced to the alkyl group include an alkyl group, an alkenyl group, an alkynyl group, an aryl group, an alkoxy group, an aryloxy group, a halogen atom, an amino group, an alkylamino group, an arylamino group, a carboxyl group, an alkoxycarbonyl group, a sulfo group, a nitro group, a cyano group, an amide group, an alkylsulfonyl group, and an arylsulfonyl group.

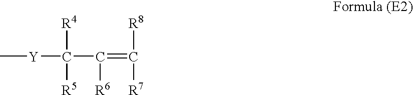

In Formula (E2), R⁴ to R⁸ each independently represent a hydrogen atom or a monovalent organic group. Preferable examples of each of R⁴ to R⁸ respectively include a hydrogen atom, a halogen atom, an amino group, a dialkylamino group, a carboxyl group, an alkoxycarbonyl group, a sulfo group, a nitro group, a cyano group, an alkyl group which may have a substituent, an aryl group which may have a substituent, an alkoxy group which may have a substituent, an aryloxy group which may have a substituent, an alkylamino group which may have a substituent, an arylamino group which may have a substituent, an alkylsulfonyl group which may have a substituent, and an arylsulfonyl group which may have a substituent. Among them, a hydrogen atom, a carboxyl group, an alkoxycarbonyl group, an alkyl group which may have a substituent, and an aryl group which may have a substituent are more preferable.

Examples of the substituent which may be introduced to the organic group are the same as those for Formula (E1). Y represents an oxygen atom, a sulfur atom, or —N(R¹²)—. R¹² is equivalent to the R¹² in Formula (E1), and preferable examples thereof are the same as those for Formula (E1).

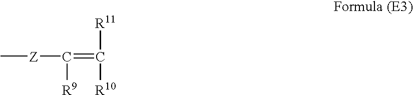

In Formula (E3), R⁹ to R¹¹ each independently represent a hydrogen atom or a monovalent organic group. Preferable examples of R⁹ include a hydrogen atom and an alkyl group which may have a substituent, and more preferable examples thereof include a hydrogen atom and a methyl group due to their high radical reactivity. Examples of each of R¹⁰ and R¹¹ respectively include a hydrogen atom, a halogen atom, an amino group, a dialkylamino group, a carboxyl group, an alkoxycarbonyl group, a sulfo group, a nitro group, a cyano group, an alkyl group which may have a substituent, an aryl group which may have a substituent, an alkoxy group which may have a substituent, an aryloxy group which may have a substituent, an alkylamino group which may have a substituent, an arylamino group which may have a substituent, an alkylsulfonyl group which may have a substituent, and an arylsulfonyl group which may have a substituent. Among them, a hydrogen atom, a carboxyl group, an alkoxycarbonyl group, an alkyl group which may have a substituent, and an aryl group which may have a substituent are more preferable due to their high radical reactivity.

Examples of the substituent which may be introduced to the organic group are the same as those for Formula (E1). Z represents an oxygen atom, a sulfur atom, —N(R¹³)—, or a phenylene group which may have a substituent. R¹³ may represent an alkyl group which may have a substituent, and preferable examples thereof include a methyl group, an ethyl group, and an isopropyl group due to their high radical reactivity.

Examples of a method to introduce an ethylenically unsaturated bond to a side chain of the specific polyurethane resin include a method using, as a raw material of the specific polyurethane resin, a diol compound having an ethylenically unsaturated bond in a side chain thereof. The diol compound may be a commercial product such as trimethylolpropane monoallyl ether, or a compound readily produced by the reaction between a halogenated diol compound, a triol compound, or an aminodiol compound with a compound having an ethylenically unsaturated bond, such as carboxylic acid, acid chloride, isocyanate, alcohol, amine, thiol, or alkyl halide. Specific examples of the diol compound include the following compounds, while the scope thereof is not limited thereto.

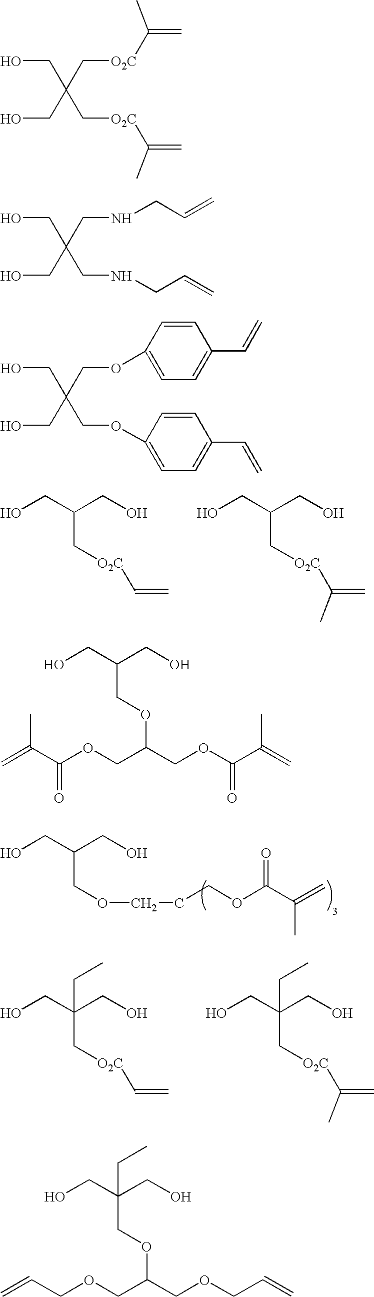

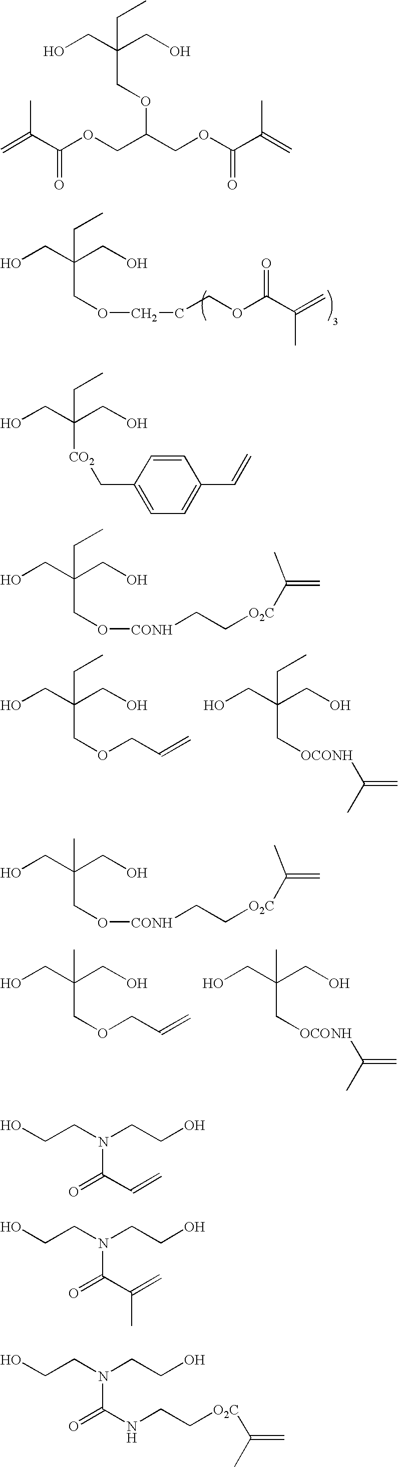

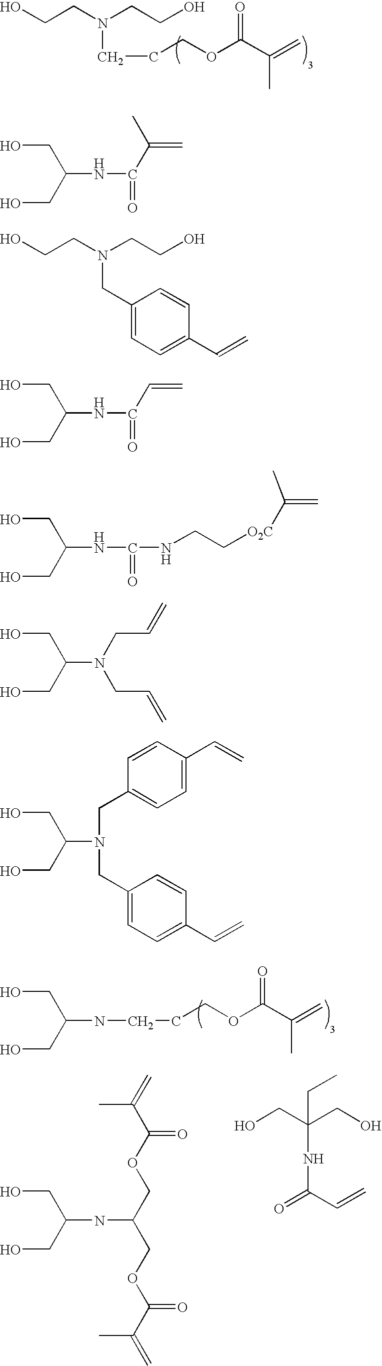

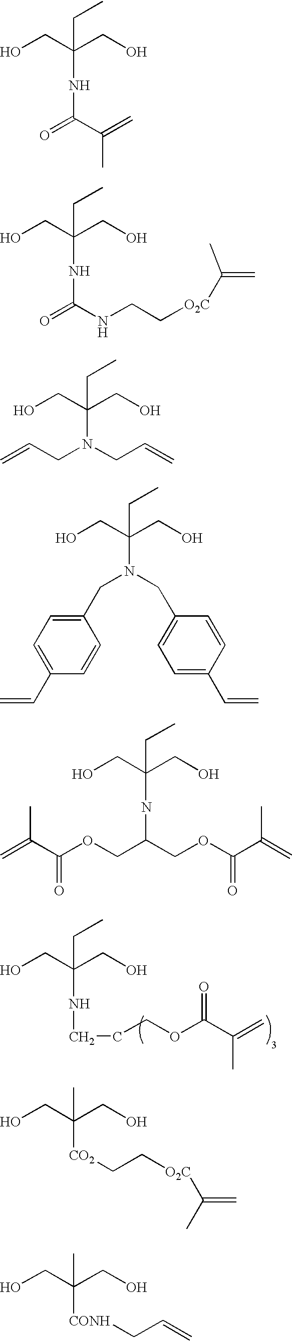

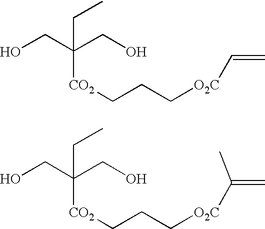

More preferable examples of the specific polyurethane resin include polyurethane resins synthesized from the diol compound represented by the following Formula (G) as at least one diol compound having an ethylenically unsaturated bond.

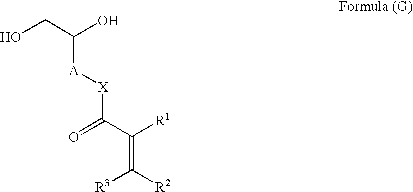

In Formula (G), R¹ to R³ each independently represent a hydrogen atom or a monovalent organic group. A represents a divalent organic group. X represents an oxygen atom, a sulfur atom, or —N(R¹²)—. R¹² represent a hydrogen atom or a monovalent organic group.

R¹ to R³ and X in Formula (G) are equivalent to the R¹ to R³ and X in Formula (E1), and preferable examples thereof are the same as those for Formula (E1).

Through the use of a polyurethane resin prepared from the diol compound, the excessive molecular motion of the polymer main chain due to the secondary alcohol with the large steric hindrance can be suppressed, which may contribute to the improvement of the film strength.

Specific examples of the diol compound represented by Formula (G) preferable for the synthesis of the specific polyurethane resin are shown below.

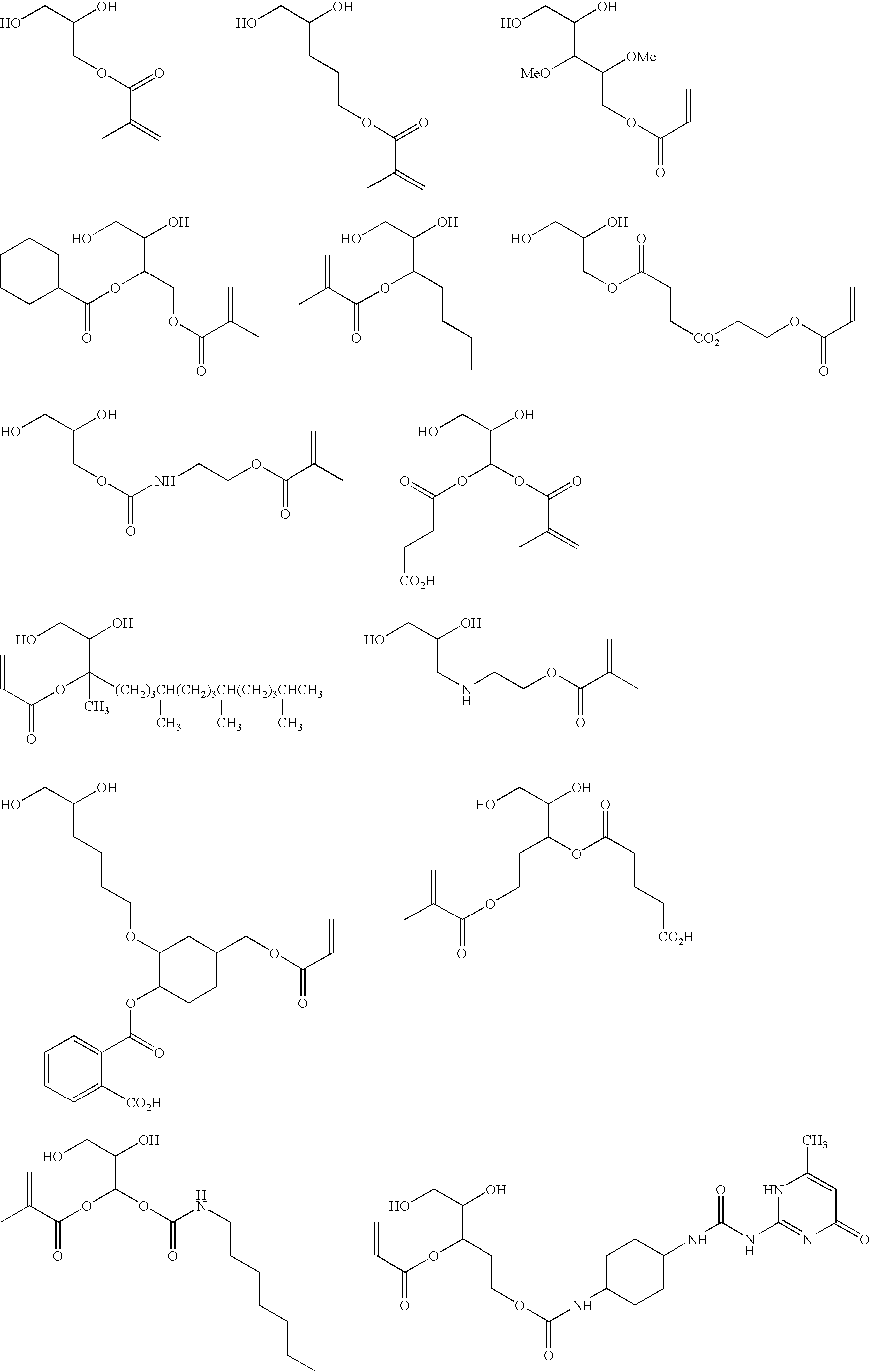

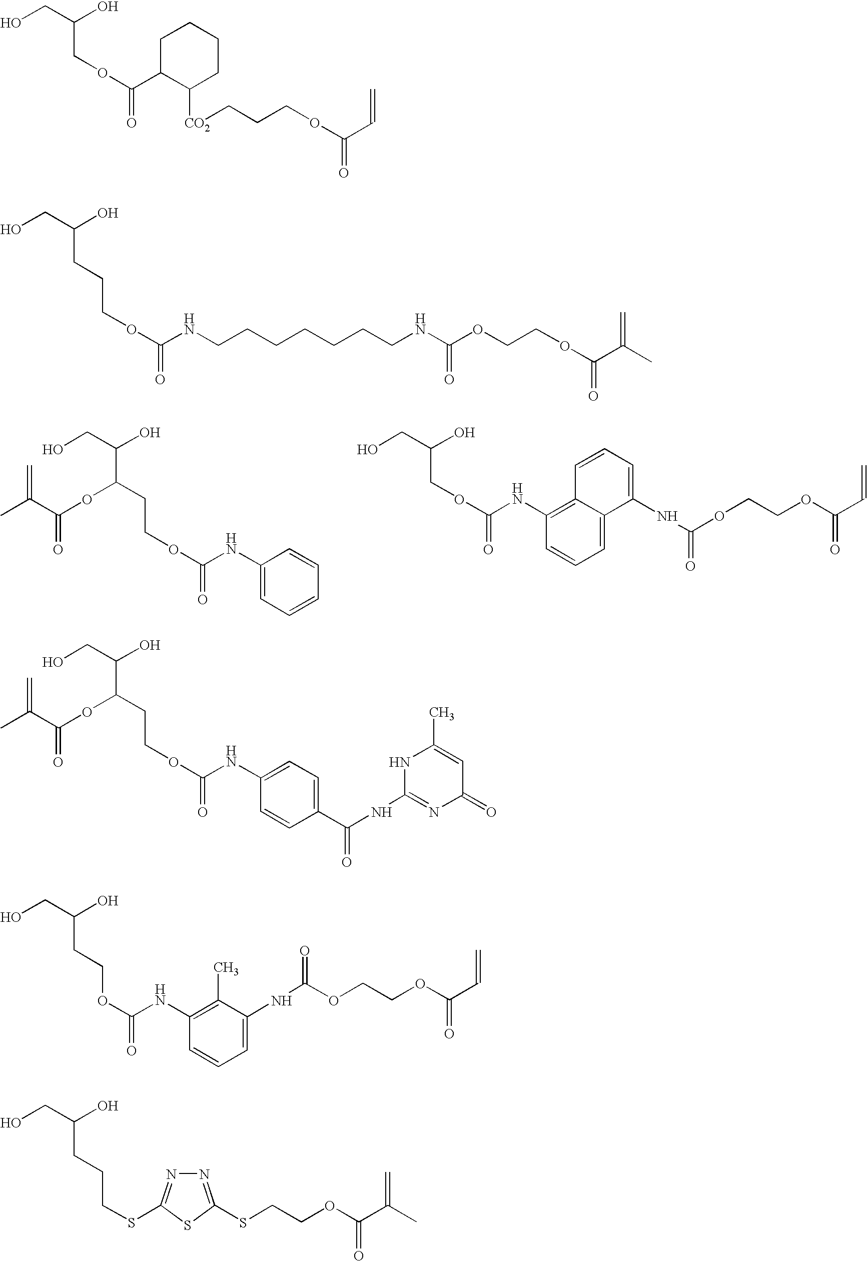

When the specific polyurethane resin is synthesized using an excessive amount of NCO groups by employing a condition in which the ratio of the number of moles of the NCO substructure to that of OH groups (NCO/OH ratio) contained in the diol compound used for the synthesis of the specific polyurethane resin is 1 or more, the main chain has NCO groups at its terminal, to which an alcohol having an ethylenically unsaturated bond (for example, 2-hydroxyethyl(meth)acrylate or BLEMMER PME200 (trade name, manufactured by NOF Corporation)) may be added to introduce an ethylenically unsaturated bond to the terminal of the main chain of the specific polyurethane. The specific polyurethane resin may have an ethylenically unsaturated group at the terminal of its main chain and/or its side chain.

The polyurethane resin which can be used as the specific polymer (A) in the invention can be synthesized by heating the diisocyanate compound and the diol compound in an aprotic solvent in the presence of a known catalyst having activity suitable for the reactivity of these compounds. The ratio between the number of moles of the diisocyanate (Mₐ) and that of the diol compound (M_{b}) used for the synthesis (Mₐ:M_{b}) is preferably from 1:1 to 1.2:1. A resultant of the synthesis can be treated with an alcohol or amine to provide a final product having desired properties (for example, molecular weight and viscosity) and no isocyanate group.

For the synthesis of the polyurethane resin, a synthetic method with a bismuth catalyst can be preferable as compared to known synthetic methods with a tin catalyst from the viewpoint of the reduction of environmental loads and the improvement of polymerization rate. Particularly preferable examples of the bismuth catalyst include NEOSTAN U-600 (trade name, manufactured by NITTO KASEI CO., LTD).

A polyurethane resin having an ethylenically unsaturated bond at a terminal and/or within the main chain of the polymer can be also preferably used as the polyurethane resin according to the invention.

Examples of the method to introduce unsaturated groups into a terminal of the polymer include using an alcohol or an amine having an unsaturated group at the treating of the residual isocyanate groups on the terminal of the polymer with an alcohol or an amine during the process for synthesis of the polyurethane resin

Examples of a method to introduce an unsaturated group into the main chain of the polymer include using a diol compound having an unsaturated group within its chain structure linking hydroxy groups as a starting material for the synthesis of the polyurethane resin. Specific examples of the diol compound having an unsaturated group within the chain structure linking hydroxy groups include cis-2-butene-1,4-diol, trans-2-butene-1,4-diol, and polybutadienediol.

In view of the easiness to control and increase the amount of the ethylenically unsaturated bond to be introduced and the improvement of the crosslinking reaction efficiency, the ethylenically unsaturated bond is preferably introduced into a side chain of the polyurethane rather than a terminal of the main chain thereof.

Examples of the ethylenically unsaturated bond group to be introduced which are preferable from the viewpoint of crosslinking cured film forming property include a methacryloyl group, an acryloyl group, and a styryl group, and more preferable examples thereof include a methacryloyl group and an acryloyl group. In order to achieve both the film forming property to form a crosslinked (cured) layer and the storage stability, a methacryloyl group is further preferable.

According to the invention, the amount (equivalent amount) of the ethylenically unsaturated bond (group) contained in a side chain of the specific polyurethane resin is preferably 0.3 meq/g or more, and more preferably from 0.35 meq/g to 1.50 meq/g. More specifically, the polyurethane resin contain 0.35 meq/g to 1.50 meq/g of methacroyl groups in a side chain thereof is particularly preferable.

According to the invention, the molecular weight of the polyurethane resin as the specific polymer (A) is preferably 10,000 or more, and more preferably from 40,000 to 200,000 in terms of mass average molecular weight. In particular, when the resin composition for laser engraving of the invention is used to form a recording layer of a pattern forming material, the strength of the image areas formed on the recording layer may be high when the mass average molecular weight of the specific polymer (A) is within the above-described range.

Specific examples of the specific polyurethane resin (PU) useful in the invention are listed below, while the invention is not limited thereto. Diisocyanate compound(s) and Diol compound(s) from which the specific polyurethane resins are formed are shown together with the weight-average molecular weight (Mw) respectively. The number accompanied with respective compounds indicate a percentage in terms of mole (mol %) used in the specific polyurethane resin.

| PU | Diisocyanate compound | |
|---|---|---|
| P-1 | 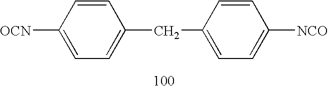 | |
| P-2 | 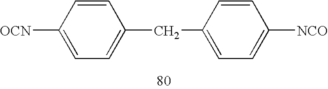 | |
| | 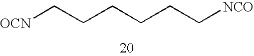 | |
| P-3 | 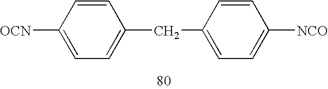 | |
| | 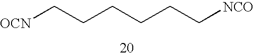 | |
| P-4 | 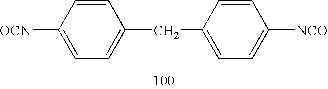 | |
| P-5 | 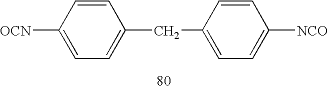 | |
| | 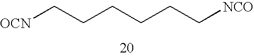 | |
| P-6 | 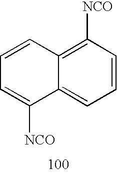 | |
| P-7 | 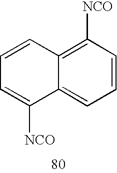 | |
| | 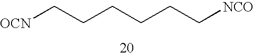 | |
| P-8 | 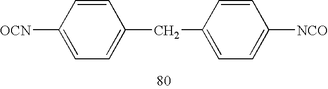 | |
| | 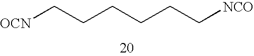 | |
| P-9 | 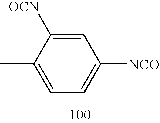 | |
| P-10 | 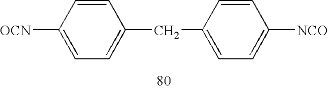 | |
| | 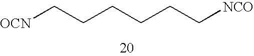 | |
| P-11 | 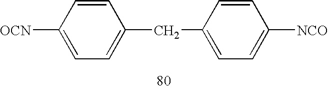 | |
| | 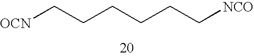 | |
| P-12 | 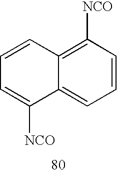 | |
| | 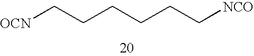 | |
| P-13 | 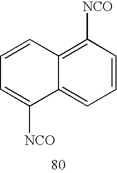 | |
| | 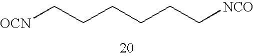 | |
| P-14 | 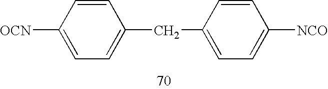 | |
| | 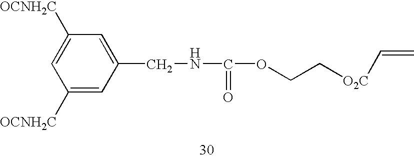 | |
| P-15 | 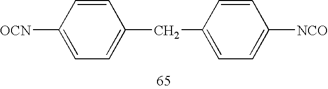 | |
| | 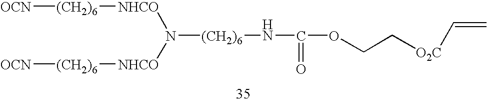 | |
| P-16 | 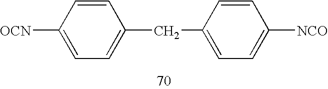 | |
| | 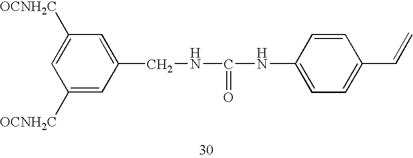 | |
| P-17 | 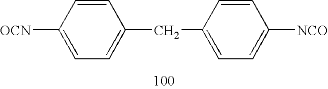 | |
| P-18 | 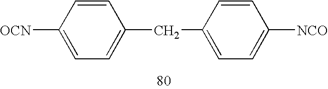 | |
| | 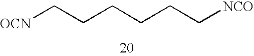 | |
| P-19 | 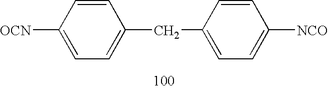 | |
| P-20 | 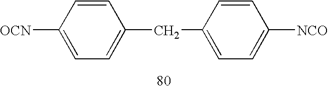 | |
| | 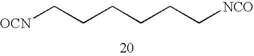 | |
| P-21 | 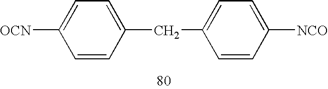 | |
| | 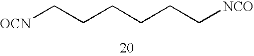 | |
| P-22 | 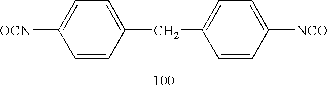 | |
| P-23 | 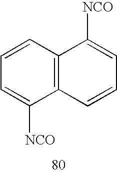 | |
| | 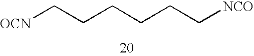 | |
| P-24 | 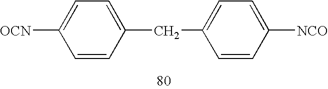 | |
| | 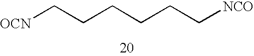 | |
| P-25 | 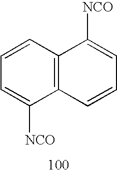 | |
| P-26 | 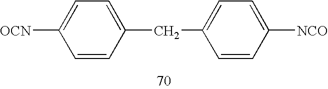 | |
| | 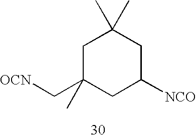 | |
| P-27 | 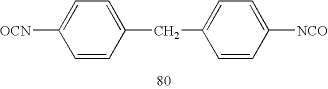 | |
| | 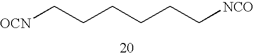 | |
| P-28 | 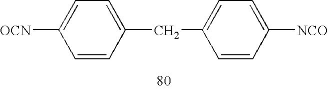 | |
| | 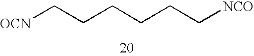 | |
| P-29 | 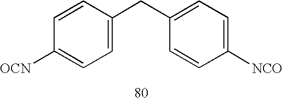 | |
| | 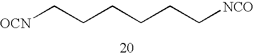 | |
| P-30 | 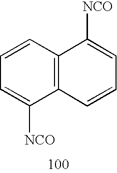 | |
| P-31 | 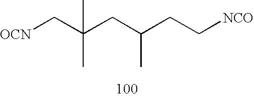 | |
| P-32 | 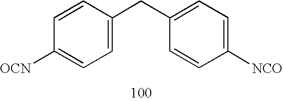 | |
| P-33 | 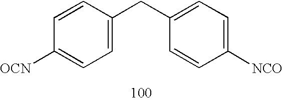 | |
| PU | Diol compound | Mw |
| P-1 | 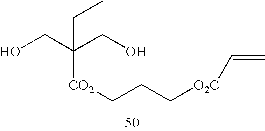 | 95,000 |
| | 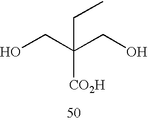 | |
| P-2 | 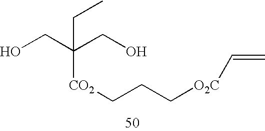 | 98,000 |
| | 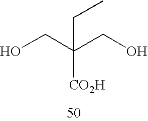 | |
| P-3 | 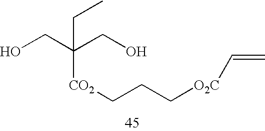 | 103,000 |
| | 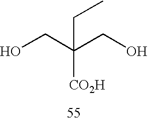 | |
| P-4 | 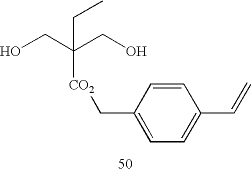 | 108,000 |
| | 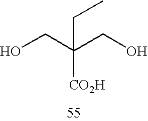 | |
| P-5 | 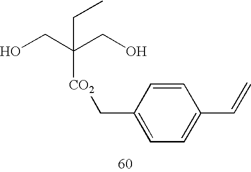 | 99,000 |
| | 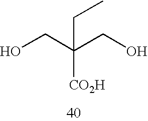 | |
| P-6 | 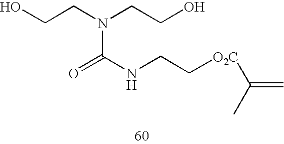 | 96,000 |
| | 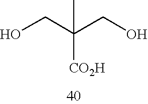 | |
| P-7 | 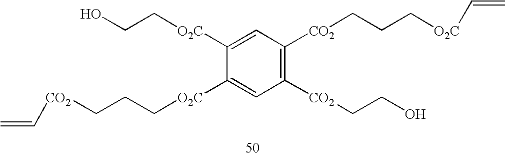 | 68,000 |
| | 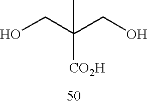 | |
| P-8 | 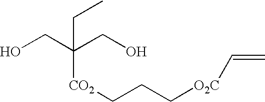 | 96,000 |
| | 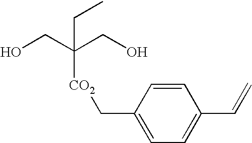 | |
| | 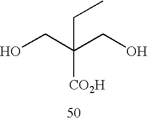 | |
| P-9 | 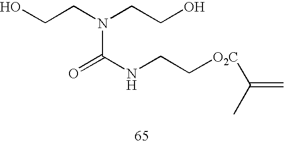 | 100,000 |
| | 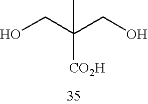 | |
| P-10 | 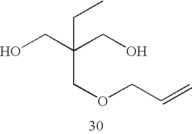 | 69,000 |
| | 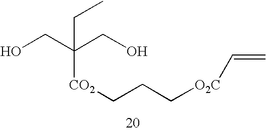 | |
| | 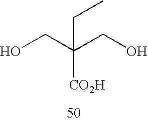 | |
| P-11 | 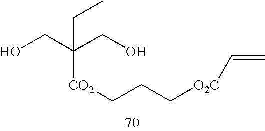 | 120,000 |
| | 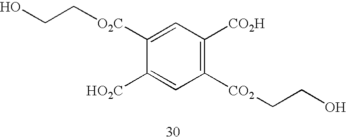 | |
| P-12 | 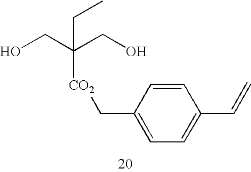 | 78,000 |
| | 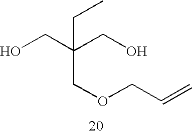 | |
| | 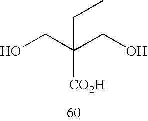 | |
| P-13 | 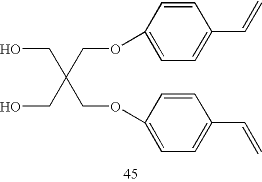 | 103,000 |
| | 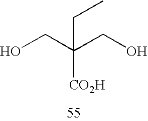 | |
| P-14 | 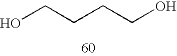 | 65,000 |
| | 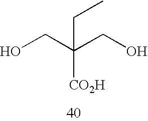 | |
| P-15 | 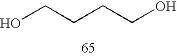 | 78,000 |
| | 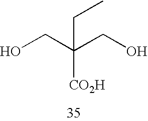 | |
| P-16 | 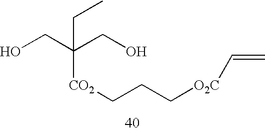 | 69,000 |
| | 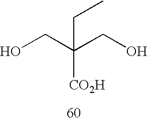 | |
| P-17 | 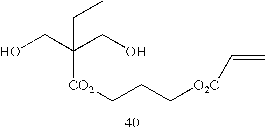 | 99,000 |
| | 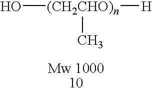 | |
| | 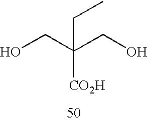 | |
| P-18 | 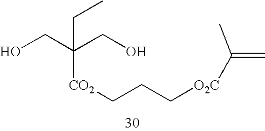 | 87,000 |
| | 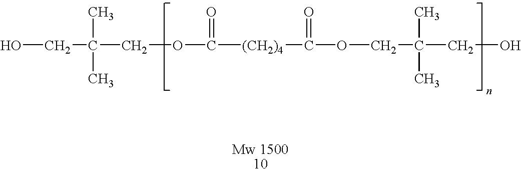 | |
| | 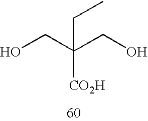 | |
| P-19 | 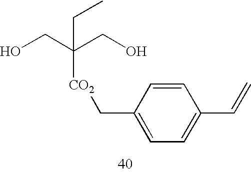 | 97,000 |
| | 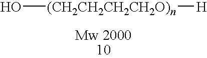 | |
| | 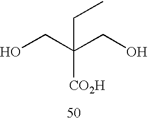 | |
| P-20 | 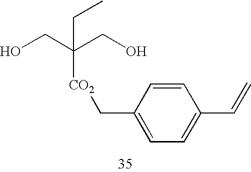 | 103,000 |
| | 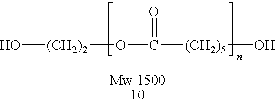 | |
| | 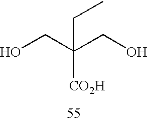 | |
| P-21 | 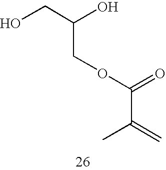 | 60,000 |
| | 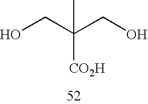 | |
| | 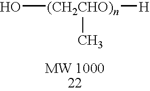 | |
| P-22 | 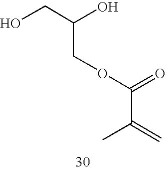 | 70,000 |
| | 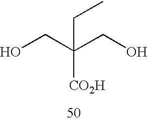 | |
| | 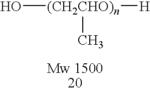 | |
| P-23 | 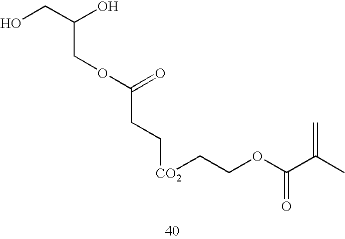 | 50,000 |
| | 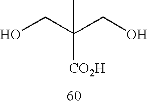 | |
| P-24 | 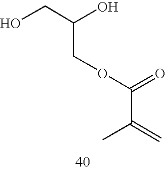 | 75,000 |
| | 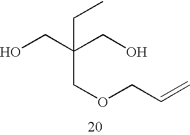 | |
| | 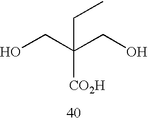 | |
| P-25 | 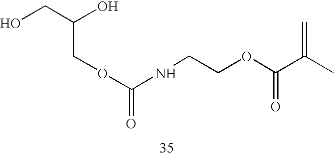 | 80,000 |
| | 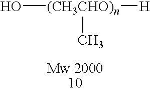 | |
| | 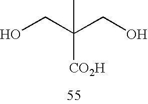 | |
| P-26 | 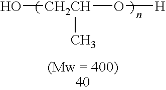 | 50,000 |
| | 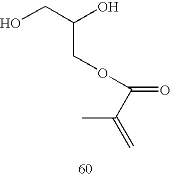 | |
| P-27 | 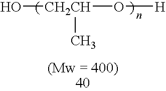 | 60,000 |
| | 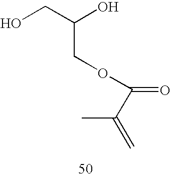 | |
| | 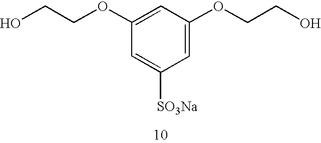 | |
| P-28 | 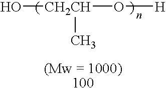 | 59,000 |
| P-29 | 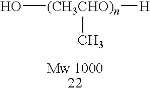 | 63,000 |
| | 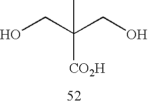 | |
| | 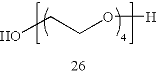 | |
| P-30 | 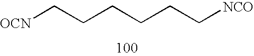 | 32,000 |
| P-31 | 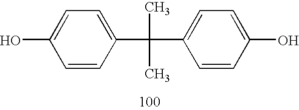 | 21,000 |
| P-32 | 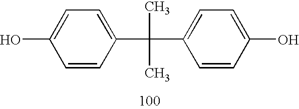 | 29,000 |
| P-33 | 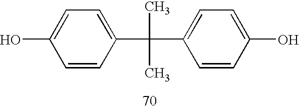 | 41,000 |
| | 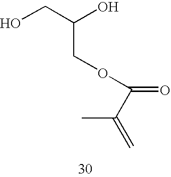 | |

The polyurethane resin as the specific polymer (A) according to the invention is thermally decomposed at a lower temperature (below 250° C.) than binder polymers composing known resin compositions for laser engraving. (Most commercial general-purpose resins are thermally decomposed at high temperatures from 300° C. to 400° C.) Accordingly, the resin composition for laser engraving of the invention containing the polyurethane resin can be highly sensitive to laser to cause decomposition.

In a system containing the polyurethane resin as the specific polymer (A) and the auxiliary binder polymer (B) described below, the polyurethane resin can be decomposed by heat generated by laser irradiation even when these polymers are not uniformly mixed but in a phase-separated state. Consequently, gases (for example, nitrogen) generated during thermal decomposition and vaporization of the polyurethane resin may assist and accelerate the vaporization of the coexisting auxiliary binder polymer (B). Therefore, the resin composition for laser engraving obtained using the polyurethane resin as the specific polymer (A) may offer high laser decomposability and high sensitivity even when of the coexistence of the auxiliary binder polymer (B).

The content of the specific polymer (A) in the resin composition in the invention is preferably from 2% by mass to 95% by mass, more preferably from 5% by mass to 80% by mass, and particularly preferably from 10% by mass to 65% by mass with respect to the total solid content of the resin composition, in view of well balancing the morphological stability, the resistance to water, and the engraving sensitivity of the relief forming layer.

(B) Auxiliary Binder Polymer

The relief forming layer of the printing plate precursor for laser engraving of the invention may further contain, in addition to the specific polymer (A), a known binder polymer which are outside the scope of the specific polymer (A) (namely, binder polymer which are soluble to water and/or are insoluble to an alcohol having 1 to 4 carbon atoms). Hereinafter, such a binder polymer which can be used in combination with the specific polymer (A) is referred as an “auxiliary binder polymer (B)”.

The auxiliary binder polymer is generally contained in a resin composition for laser engraving in combination with the specific polymer (A) as main ingredients of the resin composition. Usually, thermoplastic resins, thermoplastic elastomers, or the like are used as the binder polymer depending on the purpose with a viewpoint of improving recording sensitivity to laser.

The auxiliary binder polymer can be used in combination with the specific polymer (A) to provide a desired property to the relief forming layer. For example, in the case of using the resin composition for laser engraving for the purpose of curing thereof by heating or exposure to enhance its strength, a polymer having carbon-carbon unsaturated bonds in the molecule can be selected as the auxiliary binder polymer (B). In the case of using the resin composition for laser engraving for the purpose of forming a pliable film having flexibility, a soft resin or a thermoplastic elastomer can be selected as the auxiliary binder polymer (B).

It is preferable to use a hydrophilic or alcoholphilic polymer as the auxiliary binder polymer (B) from the viewpoints of the ease of preparation of a composition for relief forming layer and/or improvement in the resistance to oily ink in a relief printing plate obtained from the resin composition.

Also, from the viewpoint of the laser engraving sensitivity, a polymer having a partial structure which thermally degrades by exposure or heating can be preferable as the auxiliary binder polymer (B).

As such, binder polymers may be selected as the auxiliary binder polymer (B) in this invention in accordance with the purpose, while taking into consideration of the properties according to the applications of the resin composition for laser engraving, and one species or a combination of two or more species of such binder polymers may be used in combination with the specific polymer (A).

The total amount of binder polymers (the amount of the sum of the amount of the specific polymer (A) and the amount of the auxiliary binder polymer (B)) is preferably in a range of 2% by mass to 99% by mass, and is more preferably in a range of 5% by mass to 80% by mass, relative to the total solid content of the resin composition for laser engraving of the invention.

Hereinafter, various polymers that may be used as the auxiliary binder polymer (B) in the invention will be described.

Polymer Having Carbon-Carbon Unsaturated Bond

A polymer having carbon-carbon unsaturated bonds in the molecule may be suitably used as the auxiliary binder polymer (B). The carbon-carbon unsaturated bonds may be present in either the main chain or the side chains, or may also be present in both of the chains. Hereinafter, the carbon-carbon unsaturated bond may also be simply referred to as an “unsaturated bond”, and a carbon-carbon unsaturated bond present at an end of the main chain or side chain may also be referred to as a “polymerizable group”.

In the case where the polymer has carbon-carbon unsaturated bonds in the main chain thereof, the polymer may have the unsaturated bonds at one terminal therof, at both terminals therof, and/or within the main chain therof. Furthermore, in the case where the polymer has carbon-carbon unsaturated bonds in a side chain thereof, the unsaturated bonds may be directly attached to the main chain, and/or may be attached to the main chain via an appropriate linking group.

Examples of the polymer containing carbon-carbon unsaturated bonds in the main chain include SB (polystyrene-polybutadiene), SBS (polystyrene-polybutadiene-polystyrene), SIS (polystyrene-polyisoprene-polystyrene), SEBS (polystyrene-polyethylene/polybutylene-polystyrene), and the like.

In the case of using a polymer having a highly reactive polymerizable unsaturated group such as a methacryloyl group as the polymer having carbon-carbon unsaturated bonds in the side chain, a film having very high mechanical strength may be produced. Particularly, highly reactive polymerizable unsaturated groups may be relatively easily introduced into the molecule into polyurethane thermoplastic elastomers and polyester thermoplastic elastomers.

Any known method may be employed when introduce unsaturated bonds or polymerizable groups into the binder polymer. Examples of the method include: a method of copolymerizing the polymer with a structural unit having a polymerizable group precursor which is formed by attaching a protective group to the polymerizable group, and eliminating the protective group to restore the polymerizable group; and a method of producing a polymer compound having a plurality of reactive groups such as a hydroxyl group, an amino group, an epoxy group, a carboxyl group, an acid anhydride group, a ketone group, a hydrazine residue, an isocyanate group, an isothiacyanate group, a cyclic carbonate group or an ester group, subsequently reacting the polymer compound with a binding agent which has a plurality of groups capable of binding with the reactive group (for example, polyisocyanate and the like for the case of a hydroxyl group or an amino group), to thereby carry out adjustment of the molecular weight and conversion to a bindable group at the chain end, and then reacting this group which is capable of reacting with the terminal bindable group, with an organic compound having a polymerizable unsaturated group, to thus introduce a polymerizable group by means of a polymer reaction. When these methods are used, the amount of introduction of the unsaturated bond or the polymerizable group into the polymer compound may be controlled.

It is also preferable to use the polymer having an unsaturated bond in combination with a polymer which does not have an unsaturated bond. That is, since a polymer obtainable by adding hydrogen to the olefin moiety of the polymer having carbon-carbon unsaturated bonds, or a polymer obtainable by forming a polymer using as a raw material a monomer in which an olefin moiety has been hydrogenated, such as a monomer resulting from hydrogenation of butadiene, isoprene or the like, has excellent compatibility, the polymer may be used in combination with the polymer having unsaturated bonds, so as to regulate the amount of unsaturated bonds possessed by the binder polymer. In the case of using these in combination, the polymer which does not have unsaturated bonds may be used in a proportion of generally 1 parts by mass to 90 parts by mass, and preferably 5 parts by mass to 80 parts by mass, relative to 100 parts by mass of the polymer having unsaturated bonds.

As will be discussed later, in aspects where curability is not required for the binder polymer, such as in the case of using another polymerizable compound in combination, the binder polymer does not necessarily contain an unsaturated bond, and a variety of polymers which do not have unsaturated bonds may be solely used as the binder polymer in the relief forming layer. Examples of the polymer which does not have unsaturated bonds and can be used in such a case include polyesters, polyamides, polystyrene, acrylic resins, acetal resins, polycarbonates and the like.

The binder polymer suitable for the use in the invention, which may or may not have unsaturated bonds, has a number average molecular weight preferably in the range of from 1,000 to 1,000,000, and more preferably in the range of from 5,000 to 500,000. When the number average molecular weight of the binder polymer is in the range of 1,000 to 1,000,000, the mechanical strength of the film to be formed may be secured. Here, the number average molecular weight is a value measured using gel permeation chromatography (GPC), and reduced with respect to polystyrene standard products with known molecular weights.

Thermoplastic Polymer and Polymer Having Decomposability

Examples of the auxiliary binder polymer (B) which may be preferably used from the viewpoint of assuring laser engraving sensitivity include a thermoplastic polymer which can be liquefied by being imparted with energy by means of exposure and/or heating, and a polymer having a partial structure which can be decomposed by being imparted with energy by means of exposure and/or heating.

Examples of the polymer having decomposability include those polymers containing, as a monomer unit having in the molecular chain a partial structure which is likely to be decomposed and cleaved, styrene, α-methylstyrene, α-methoxystyrene, acryl esters, methacryl esters, ester compounds other than those described above, ether compounds, nitro compounds, carbonate compounds, carbamoyl compounds, hemiacetal ester compounds, oxyethylene compounds, aliphatic cyclic compounds, and the like.

In view of the reasons similar to those for the specific polymer (A), the auxiliary binder polymer (B) can be preferably selected from those having a glass transition temperature (Tg) of 20° C. or more and less than 200° C., more preferably from those having a Tg being in a range from 20° C. to 170° C., and particuarly preferably from those having a Tg being in a range from 25° C. to 150° C.

Among these, polyethers such as polyethylene glycol, polypropylene glycol and polytetraethylene glycol, aliphatic polycarbonates, aliphatic carbamates, polymethyl methacrylate, polystyrene, nitrocellulose, polyoxyethylene, polynorbornene, polycyclohexadiene hydrogenation products, or a polymer having a molecular structure having many branched structures such as dendrimers, may be particularly preferably exemplified in terms of decomposability.

A polymer containing a number of oxygen atoms in the molecular chain is preferable from the viewpoint of decomposability. From this point of view, compounds having a carbonate group, a carbamate group or a methacryl group in the polymer main chain, may be suitably exemplified.

For example, a polyester or polyurethane synthesized from a (poly)carbonate diol or a (poly)carbonate dicarboxylic acid as the raw material, a polyamide synthesized from a (poly)carbonate diamine as the raw material, and the like may be exemplified as the examples of polymers having good thermal decomposability. These polymers may also be those containing a polymerizable unsaturated group in the main chain or the side chains. Particularly, in the case of a polymer having a reactive functional group such as a hydroxyl group, an amino group or a carboxyl group, it is also easy to introduce a polymerizable unsaturated group into such a thermally decomposable polymer.

The thermoplastic polymer may be an elastomer or a non-elastomer resin, and may be selected according to the purpose of the resin composition for laser engraving of the invention, while it can be preferably a non-elastomer resin, namely a polymer having a Tg of 20° C. or more and less than 200° C., more preferably those having a Tg being in a range from 20° C. to 170° C., and particuarly preferably those having a Tg being in a range from 25° C. to 150° C.

Examples of the thermoplastic elastomer include urethane thermoplastic elastomers, ester thermoplastic elastomers, amide thermoplastic elastomers, silicone thermoplastic elastomers and the like. For the purpose of enhancing the laser engraving sensitivity of such a thermoplastic elastomer, an elastomer in which an easily decomposable functional group such as a carbamoyl group or a carbonate group has been introduced into the main chain, may also be used. A thermoplastic polymer may also be used as a mixture with the thermally decomposable polymer.

The thermoplastic elastomer is a material showing rubber elasticity at normal temperature, and the molecular structure includes a soft segment such as polyether or a rubber molecule, and a hard segment which prevents plastic deformation near normal temperature, as vulcanized rubber does. There exist various types of hard segments, such as frozen state, crystalline state, hydrogen bonding and ion bridging. Such thermoplastic elastomers may be suitable in the case of applying the resin composition for laser engraving of the invention to the production of, for example, relief printing plates requiring plasticity, such as flexo plates.

The kind of the thermoplastic elastomer can be selected according to the purpose. For example, in the case where solvent resistance is required, urethane thermoplastic elastomers, ester thermoplastic elastomers, amide thermoplastic elastomers and fluorine thermoplastic elastomers are preferable. In the case where thermal resistance is required, urethane thermoplastic elastomers, olefin thermoplastic elastomers, ester thermoplastic elastomers and fluorine thermoplastic elastomers are preferable. The hardness of a film formed from the resin composition can be largely varied according to the selection of the kind of the thermoplastic elastomer. The use of the thermoplastic elastomer can be effective to provide flexibility to a film formed from the resin composition to provide a so-called flexo printing plate. The content of the thermoplastic elastomer compounded in the resin composition should be in a certain range so as not to adversely affect functions derived from the specific polymer (A). Specifically, the content of the thermoplastic elastomer is 30% by mass or less with respect to the total amount of the specific polymer (A).

Examples of the non-elastomeric resin include polyester resins include unsaturated polyester resins, polyamide resins, polyamideimide resins, polyurethane resins, unsaturated polyurethane resins, polysulfone resins, polyethersulfone resins, polyimide resins, polycarbonate resins, all aromatic polyester resins, and hydrophilic polymers containing hydroxyethylene units (for example, polyvinyl alcohol compounds).

In order to well balancing the suitability for an aqueous ink and the suitability for a UV ink, the content ratio of the specific polymer (A) with respect to the total amount of binder polymers including the auxiliary binder polymer (B) [the ratio of the amount of the specific polymer (A) to the sum of the amounts of the specific polymer (A) the auxiliary binder polymer (B)], namely (A)/[(A)+(B)], is preferably from 0.3 to 1.0, more preferably from 0.5 to 1.0, and particularly preferably from 0.7 to 1.0. In embodiments, all of the binder polymers can be within the scope of the specific polymer (A).

The resin composition for laser engraving of the invention preferably contains, together with the specific binder polymer (A) as the essential ingredient and the auxiliary binder polymer (B) which can be used if desired, arbitrary ingredients such as a polymerizable compound, a photo-thermal conversing agent, a polymerization initiator or a plasticizer. Each of the ingredients is more specifically explained below.

(C) Polymerizable Compound

The resin composition for laser engraving according to the invention can contain a polymerizable compound (C) if desired. The property to be hardened (cured) by crosslinking can be provided to the resin composition when the polymerizable compound is contained in the resin composition.

The “polymerizable compound” in the invention means a compound having at least one carbon-carbon unsaturated bond capable of radical polymerization triggered by the generation of a starting radical derived from a polymerization initiator. More specific explanation will be given with taking an example of using an addition polymerizable compound as the polymerizable compound.

Examples of the polymerizable compound that can be preferably used in the invention include an addition polymerizable compound having at least one ethylenic unsaturated double bond. This addition polymerizable compound is preferably selected from compounds having at least one, preferably two or more, terminal ethylenic unsaturated bonds.

The family of such compounds is widely known in the pertinent industrial field, and these compounds may be used in the invention without any particular limitations. These compounds respectively have a chemical form such as a monomer, a prepolymer such as a dimer or a trimer, an oligomer, a copolymer thereof, or a mixture of any of these.

Examples of the monomer include unsaturated carboxylic acids (for example, acrylic acid, methacrylic acid, itaconic acid, crotonic acid, isocrotonic acid, maleic acid, and the like), esters thereof, and amides thereof. Preferable examples thereof include esters of an unsaturated carboxylic acid and an aliphatic polyhydric alcohol compound and amides of an unsaturated carboxylic acid and an aliphatic polyvalent amine compound. Further, unsaturated carboxylic acid esters having a nucleophilic substituent such as a hydroxyl group, an amino group or a mercapto group; adducts of an amide with a monofunctional or polyfunctional isocyanate or an epoxy compound; dehydration condensation reaction products of an amide with a monofunctional or polyfunctional carboxylic acid, and the like may also be suitably used. Unsaturated carboxylic acid esters having an electrophilic substituent such as an isocyanate group or an epoxy group; adducts of an amide with a monofunctional or polyfunctional alcohol, an amine or a thiol; unsaturated carboxylic acid esters having a detachable substituent such as a halogen group or a tosyloxy group; substitution reaction products of an amide with a monofunctional or polyfunctional alcohol, an amine or a thiol, are also suitable. A family of compounds formed by modifying the above-described compounds by introducing an unsaturated phosphonic acid, styrene, vinyl ether or the like in place of the unsaturated carboxylic acid may also be used.

Specific examples of the ester monomer formed of an aliphatic polyhydric alcohol compound and an unsaturated carboxylic acid include, as acrylic acid esters, ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethyelne glycol diacrylate, pentaerythritol diacrylate, pentaerythritol triacrylate, pentaerythritol tetraacrylate, dipentaerythritol diacrylate, dipentaerythritol hexaacrylate, sorbitol triacrylate, sorbitol tetraacrylate, sorbitol pentaacrylate, sorbitol hexaacrylate, tri(acryloyloxyethyl)isocyanurate, polyester acrylate oligomers, and the like.

Specific examples of the ester monomer further include, as methacrylic acid esters, tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl]dimethylmethane, bis[p-(methacryloxyethoxy)phenyl]dimethylmethane, and the like.

Specific examples of the ester monomer further include, as itaconic acid esters, ethylene glycol diitaconate, propylene glycol diitaconate, 1,3-butanediol diitaconate, 1,4-butanediol diitaconate, tetramethylene glycol diitaconate, pentaerythritol diitaconate, sorbitol tetraitaconate, and the like.

Specific examples of the ester monomer further include, as crotonic acid esters, ethylene glycol dicrotonate, tetramethylene glycol dicrotonate, pentaerythritol dicrotonate, sorbitol tetracrotonate, and the like.

Specific examples of the ester monomer further include, as isocrotonic acid esters, e ethylene glycol diisocrotonate, pentaerythritol diisocrotonate, sorbitol tetraisocrotonate, and the like.

Specific examples of the ester monomer further include, as maleic acid esters, ethylene glycol dimaleate, triethylene glycol dimaleate, pentaerythritol dimaleate, sorbitol tetramaleate, and the like.

Specific examples of the ester monomer further include the aliphatic alcohol esters as described in Japanese Patent Application Publication (JP-B) Nos. 46-27926 and 51-47334, and JP-A No. 57-196231; the esters having an aromatic skeleton as described in JP-A Nos. 59-5240, 59-5241 and 2-226149; the esters containing an amino group as described in JP-A No. 1-165613; and the like.

Any of the ester monomers may also be used in combination as a mixture.

Specific examples of the amide monomer formed of an aliphatic polyvalent amine compound and an unsaturated carboxylic acid include methylenebisacrylamide, methylenebismethacrylamide, 1,6-hexamethylenebisacrylamide, 1,6-hexamethylenebismethacrylamide, diethylenetriamine trisacrylamide, xylenebisacrylamide, xylenebismethacrylamide, and the like.

Specific examples of the amide monomer further include the amides having a cyclohexylene structure as described in JP-B No. 54-21726.

Examples of the addition polymerizable compound which can be preferably used in the invention further include urethane-based addition polymerizable compounds that are produced using an addition reaction of an isocyanate and a hydroxyl group. Specific examples thereof include the vinylurethane compound containing two or more polymerizable vinyl groups in one molecule as described in JP-B No. 48-41708, which is obtained by adding a vinyl monomer containing a hydroxyl group represented by following Formula (V), to a polyisocyanate compound having two or more isocyanate groups in one molecule, and the like.

CH₂═C(R)COOCH₂CH(R′)OH (V)

In Formula (V), R and R′ each independently represent H or CH₃.

The urethane acrylates described in JP-A No. 51-37193, JP-B Nos. 2-32293 and 2-16765; and the urethane compounds having an ethylene oxide skeleton as described in JP-B Nos. 58-49860, 56-17654, 62-39417 and 62-39418 are also suitable as the addition polymerizable compound.

When the addition polymerizable compounds having an amino structure or a sulfide structure in the molecule as described in JP-A Nos. 63-277653, 63-260909 and 1-105238, are used, a curable composition may be obtained in a short time.

Examples of the addition polymerizable compound further include polyester acrylates such as those described in JP-A No. 48-64183, and JP-B Nos. 49-43191 and 52-30490; and polyfunctional acrylates or methacrylates such as epoxy acrylates obtained by reacting an epoxy resin and (meth)acrylic acid. Examples of the addition polymerizable compound further include the specific unsaturated compounds described in JP-B Nos. 46-43946, 1-40337 and 1-40336; the vinylphosphonic acid compounds described in JP-A No. 2-25493; and the like. In certain cases, the structure containing a perfluoroalkyl group as described in JP-A No. 61-22048 can be suitably used. The compounds introduced in Journal of the Adhesion Society of Japan, Vol. 20, No. 7, pp. 300-308 (1984) as photocurable monomers and oligomers, may also be used as the addition polymerizable compound.

From the viewpoint of photosensitization speed, the addition polymerizable compound preferably has a structure having a high content of unsaturated groups per molecule, and in many cases, a bi- or higher functional structure is preferable. In order to enhance the strength of the image parts (that is, the strength of the cured film), the addition polymerizable compound preferably has a tri- or higher functional structure. A method of controlling both photosensitivity and strength by using plural compounds having different functionalities and different polymerizable groups (for example, acrylic acid esters, methacrylic acid esters, styrene compounds, or vinyl ether compounds) in combination can be also effective. The addition polymerizable compound can be used in a proportion in the range of preferably 10% by mass to 60% by mass, and more preferably 15% by mass to 40% by mass, based on the non-volatile components in the composition. The addition polymerizable compound may be used individually alone, or may also be used in combination of two or more species thereof. By using the polymerizable compound, the film properties such as brittleness and flexibility of the relief forming layer may also be adjusted.

The resin composition for laser engraving containing the polymerizable compound can be polymerized and cured by energy such as light or heat before and/or after decomposition by laser. A sharp (well-defined) convexes and concaves (relief) can be formed when the relief forming layer is formed as a hard relief forming layer by being subjected to crosslinking before being subjected to engraving. The hardness of the image formed in a relief layer formed by engraving the relief forming layer can be improved when the relief layer is hardened by being subjected to post-crosslinking after the engraving. Either one or both of the crosslinking before the engraving and the post-crosslinking can be performed in the invention.

Preferable specific examples of the polymerizable compound usable in the resin composition for laser engraving of the invention are shown below, while the invention is not limited thereby.

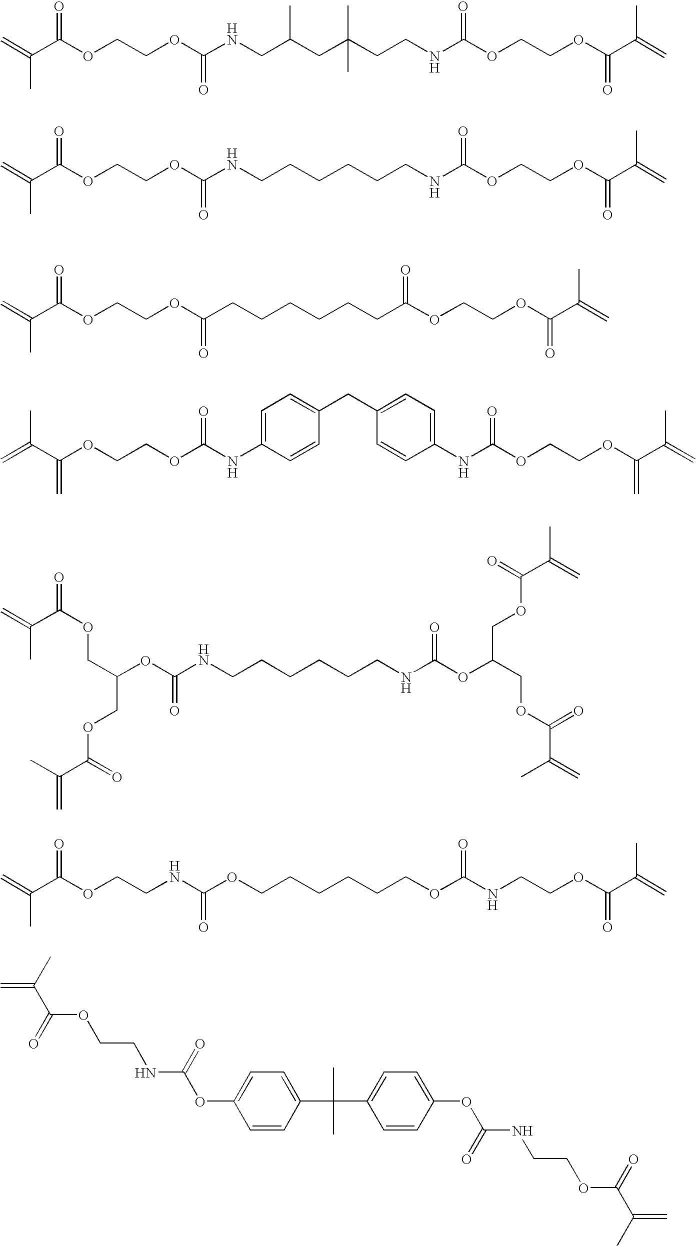

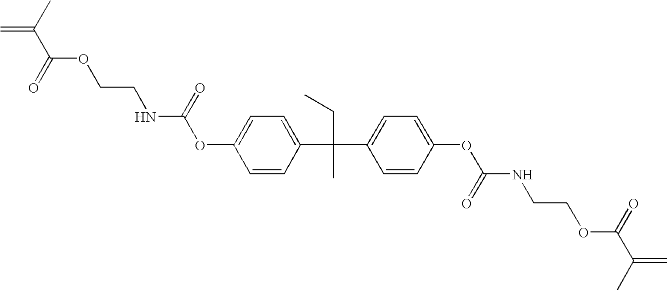

When the resin composition for laser engraving of the invention containing the polymerizable compound is used for a relief forming layer of a printing plate precursor for laser engraving, the polymerizable compound (C) is particularly preferably that containing a sulfur (S) atom from the viewpoint that edge fusion of a relief formed from a relief forming layer containing thereof may hardly occur and thus provide sharp (well-defined) relief can be easily obtained. That is, the relief forming layer formed from the resin composition preferably contains a sulfur atom in a crosslinked network therein.

While a polymerizable compound which contains a sulfur atom and a polymerizable compound which does not contain a sulfur atom may also be used in combination, it is preferable to use the polymerizable compound containing a sulfur is singly used from the viewpoint that edge fusion of a relief formed from the relief forming layer containing thereof may hardly occur. A use of plural sulfur-containing polymerizable compounds having different characteristics in combination may contribute to the control of the film flexibility and the like.

Examples of the polymerizable compound containing a sulfur atom include the following compounds.

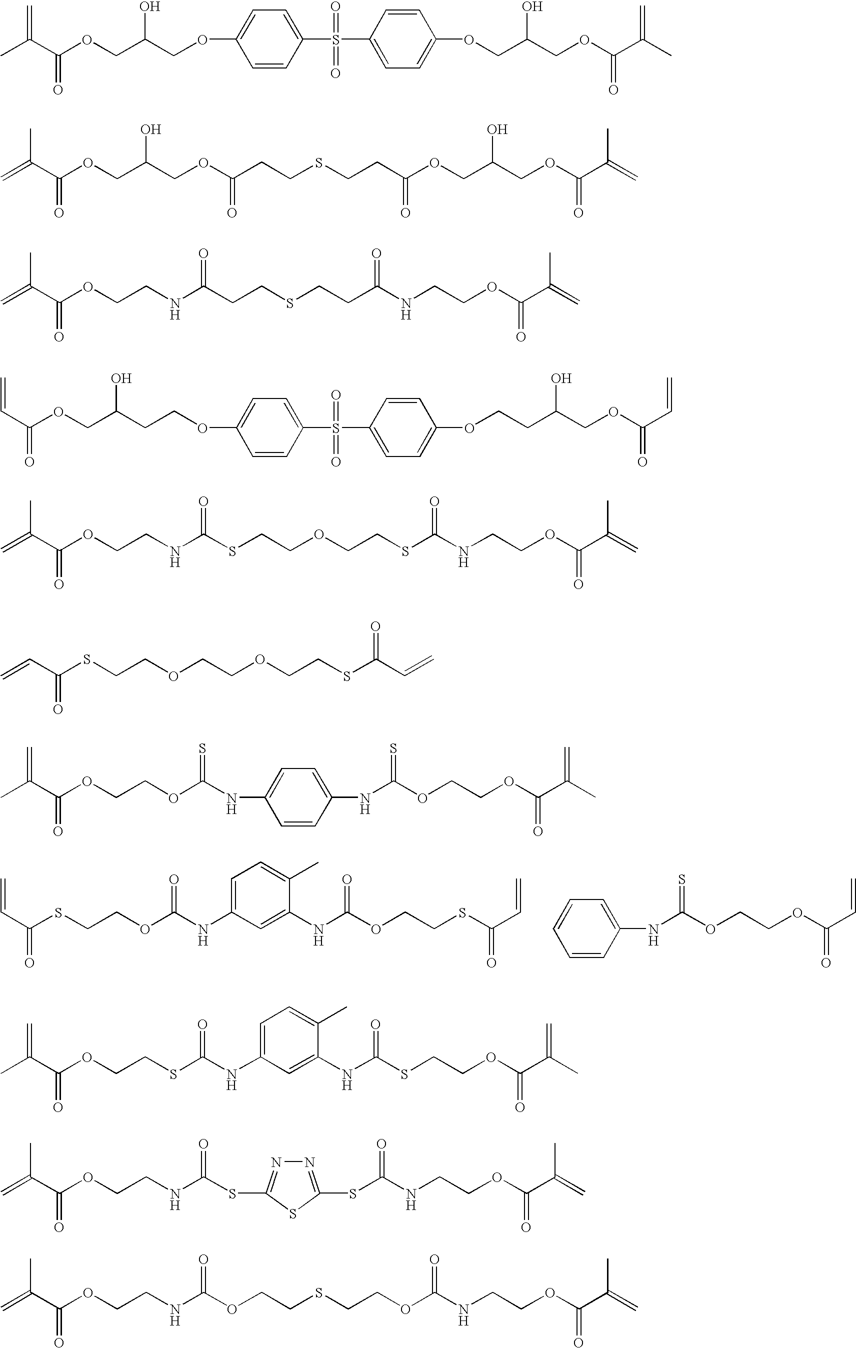

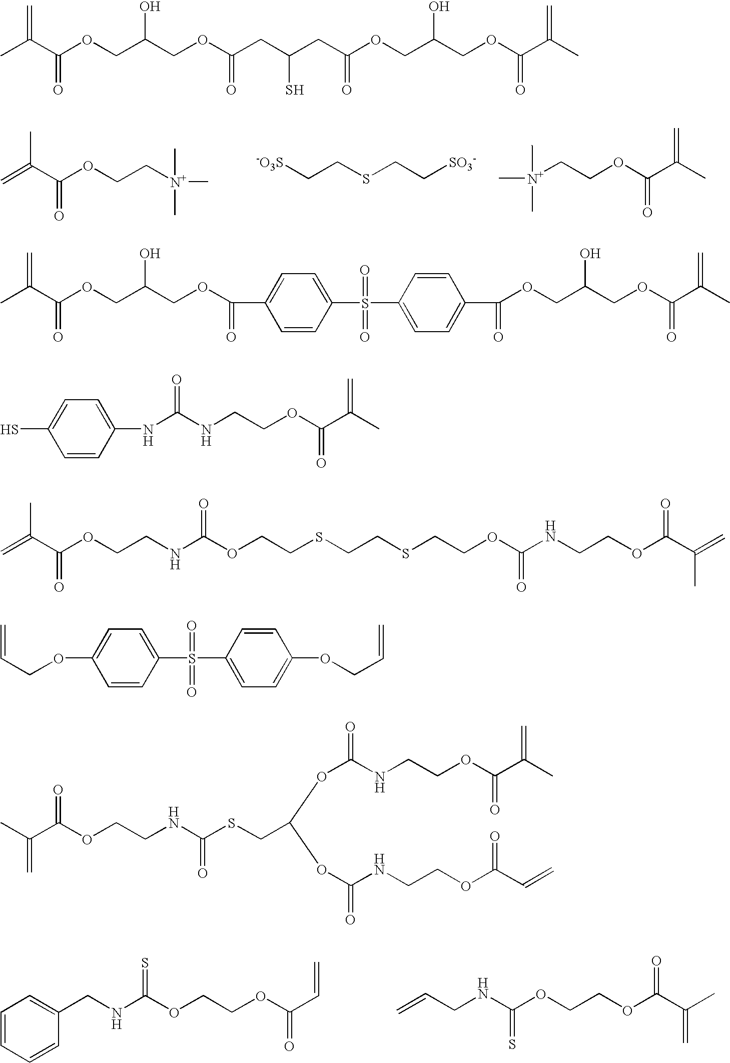

(D) Polymerization Initiator

The resin composition for laser engraving of the invention preferably contains a polymerization initiator. Any polymerization initiator that is known to those having ordinary skill in the art may be used in the invention without particular limitation. Specific examples thereof are extensively described in Bruce M. Monroe, et al., Chemical Revue, 93 435 (1993) or R. S. Davidson, Journal of Photochemistry and Biology A: Chemistry, 73, 81(1993); J. P. Faussier, “Photoinitiated Polymerization-Theory and Applications”: Rapra Review Vol. 9, Report, Rapra Technology (1998); M. Tsunooka et al., Prog. Polym. Sci., 21, 1 (1996); and the like. Also known is a family of compounds which oxidatively or reductively cause bond cleavage, such as those described in F. D. Saeva, Topics in Current Chemistry, 156, 59 (1990); G G Maslak, Topics in Current Chemistry, 168, 1 (1993); H. B. Shuster et al., JACS, 112, 6329 (1990); I. D. F. Eaton et al., JACS, 102, 3298 (1980); and the like.

Hereinafter, specific examples of preferable polymerization initiators will be discussed in detail, particularly with regard to a radical polymerization initiator which is a compound capable of generating a radical by the action of photo and/or thermal energy, and initiating and accelerating a polymerization reaction with a polymerizable compound, while the invention is not intended to be restricted thereby.

According to the invention, preferable examples of the radical polymerization initiator include (a) aromatic ketone, (b) onium salt compound, (c) organic peroxide, (d) thio compound, (e) hexaarylbiimidazole compound, (f) keto oxime ester compound, (g) borate compound, (h) azinium compound, (i) metallocene compound, (j) active ester compound, (k) compound having a carbon-halogen bond, (l) azo compound, and the like. Specific examples of the compounds of (a) to (l) will be shown in the followings, while the invention is not limited thereto.

(a) Aromatic Ketone

Examples of the (a) aromatic ketone which is preferable as the radical polymerization initiator usable in the invention include the compounds having a benzophenone skeleton and a thioxanthone skeleton as described in “RADIATION CURING IN POLYMER SCIENCE AND TECHNOLOGY”, J. P. Fouassier and J. F. Rabek (1993), p. 77-117. For example, the following compounds may be mentioned.

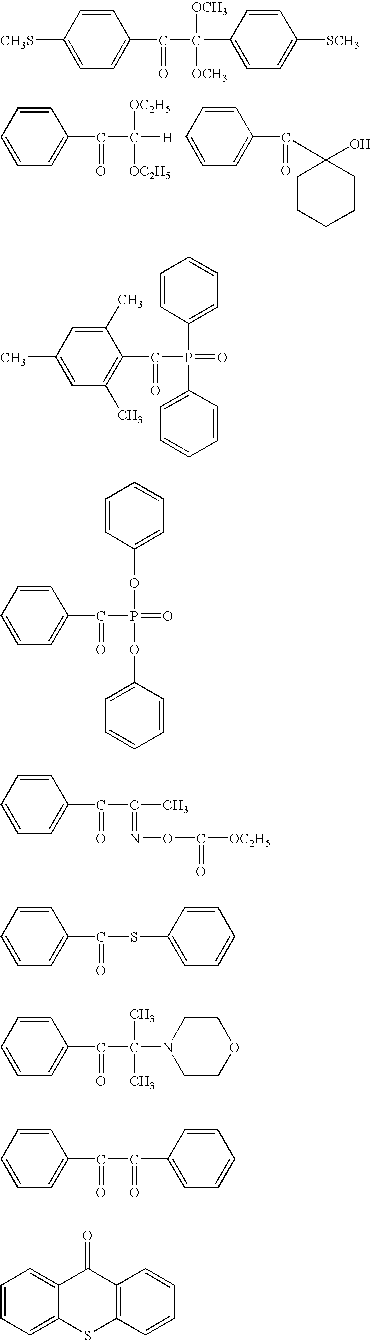

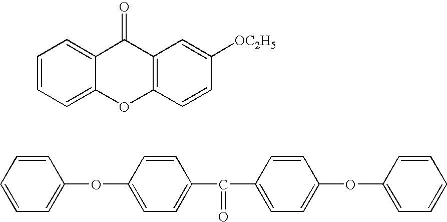

Among them, particularly preferable examples of the (a) aromatic ketone include the following compounds.

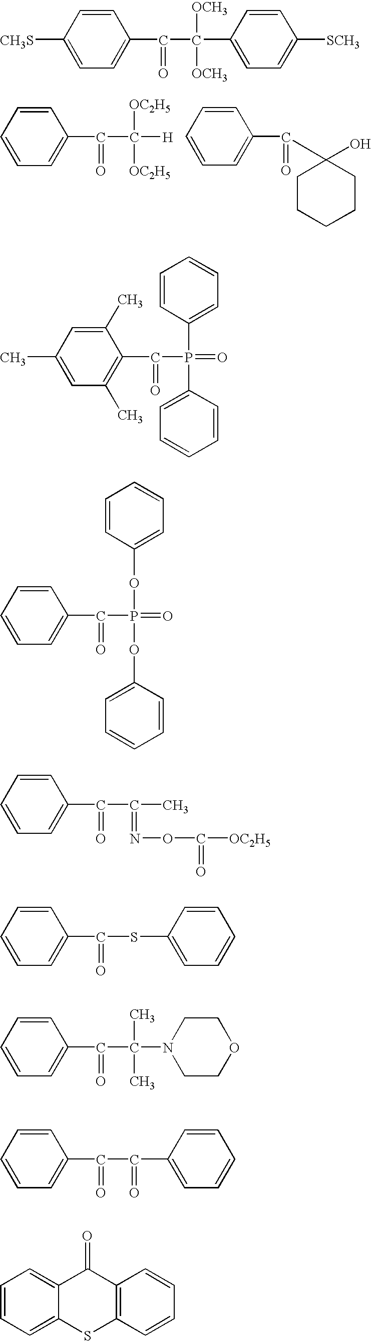

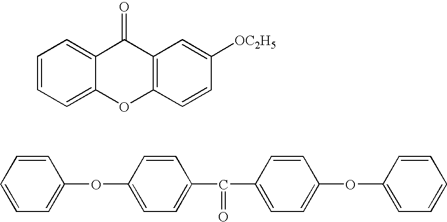

(b) Onium Salt Compound

Examples of the (b) onium salt compound which is preferable as the radical polymerization initiator usable in the invention include compounds represented by any one of the following Formulae (1) to (3).

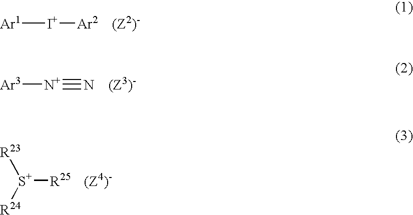

In Formula (1), Ar¹ and Ar² each independently represent an aryl group having up to 20 carbon atoms, which may be substituted; and (Z²)⁻ represents a counterion selected from the group consisting of a halogen ion, a perchlorate ion, a carboxylate ion, a tetrafluoroborate ion, a hexafluorophosphate ion and a sulfonate ion, and is preferably a perchlorate ion, a hexafluorophosphate ion or an arylsulfonate ion.

In Formula (2), Ar³ represents an aryl group having up to 20 carbon atoms, which may be substituted; and (Z³)⁻ represents a counter ion which is defined in the same manner as (Z²)⁻.

In Formula (3), R²³, R²⁴ and R²⁵, which may be the same or different from each other, each represent a hydrocarbon group having up to 20 carbon atoms, which may be substituted; and (Z⁴)⁻ represents a counter ion which is defined in the same manner as (Z²)⁻.

Specific examples of the onium salt which may be suitably used in the invention include those described in paragraphs [0030] to [0033] of JP-A No. 2001-133969 or those described in paragraphs [0015] to [0046] of JP-A No. 2001-343742, which have been previously suggested by the Applicant, and the specific aromatic sulfonium salt compounds described in JP-A Nos. 2002-148790, 2001-343742, 2002-6482, 2002-116539 and 2004-102031.

(c) Organic Peroxide

Examples of the (c) organic peroxide which is preferable as the radical polymerization initiator usable in the invention include nearly all of organic compounds having one or more oxygen-oxygen bonds in the molecule. Specific examples thereof include t-butyl peroxy benzoate, methyl ethyl ketone peroxide, cyclohexanone peroxide, 3,3,5-trimethylcyclohexanon peroxide, methylcyclohexanone peroxide, acetylacetone peroxide, 1,1-bis(tertiary-butylperoxy)-3,3,5-trimethylcyclohexane, 1,1-bis(tertiary-butylperoxy)cyclohexane, 2,2-bis(tertiary-butylperoxy)butane, tertiary-butyl hydroperoxide, cumene hydroperoxide, diisopropylbenzene hydroperoxide, paramethane hydroperoxide, 2,5-dimethylhexane-2,5-dihydroperoxide, 1,1,3,3-tetramethylbutyl hydroperoxide, di-tertiary-butyl peroxide, tertiary-butylcumyl peroxide, dicumyl peroxide, bis(tertiary-butylperoxyisopropyl)benzene, 2,5-dimethyl-2,5-di(tertiary-butylperoxy)hexane, 2,5-xanoyl peroxide, succinic acid peroxide, benzoyl peroxide, 2,4-dichlorobenzoyl peroxide,

meta-toluoyl peroxide, diisopropyl peroxydicarbonate, di-2-ethylhexyl peroxydicarbonate, di-2-ethoxyethyl peroxydicarbonate, dimethoxyisopropyl peroxycarbonate, di(3-methyl-3-methoxybutyl) peroxydicarbonate, tertiary-butyl peroxyacetate, tertiary-butyl peroxypivalate, tertiary-butyl peroxyneodecanoate, tertiary-butyl peroxyoctanoate, tertiary-butyl peroxy-3,5,5-trimethylhexanoate, tertiary-butyl peroxylaurate, tertiary-carbonate, 3,3′,4,4′-tetra(t-butlperoxycarbonyl)benzophenone, 3,3′,4,4′-tetra(t-amylperoxycarbonyl)benzophenone, 3,3′4,4′-tetra(t-hexylperoxycarbonyl)benzophenone, 3,3′4,4′-tetra-(t-octylperoxycarbonyl)benzophenone, 3,3′,4,4′-tetra-(cumylperoxycarbonyl)benzophenone, 3,3′4,4′-tetra-(p-isopropylcumylperoxycarbonyl)benzophenone, carbonyl di(t-butylperoxy dihydrogen diphthalate), carbonyl di(t-hexylperoxy dihydrogen diphthalate), and t-butyl hydroperoxide.

Among them, 3,3′,4,4′-tetra(t-butylperoxycarbonyl)benzophenone, 3,3′4,4′-tetra-(t-amylperoxycarbonyl)benzophenone, 3,3′,4,4′-tetra-(t-hexylperoxycarbonyl)benzophenone, 3,3′4,4′-tetra-(t-octylperoxycarbonyl)benzophenone, t-butyl peroxy benzoate, dicumyl peroxide, t-butyl hydroperoxide, 3,3′,4,4′-tetra-(cumylperoxycarbonyl)benzophenone, 3,3′4,4′-tetra-(p-isopropylcumylperoxycarbonyl)benzophenone, and di-t-butyl diperoxyisophthalate are preferable, and t-butyl peroxy benzoate, dicumyl peroxide, and t-butyl hydroperoxide are more preferable.

The (c) organic peroxide is found as being preferable as the polymerization initiator usable in the invention in view of improving crosslinking property of the relief forming layer as well as obtaining unexpected effect of improving the engraving sensitivity.

In view of improving the engraving sensitivity, it is particularly preferable that the (c) organic peroxide is combined in combination with the specific polymer (A) and a polymer having a glass transition temperature not lower than normal temperature as the auxiliary binder polymer (B).

More specifically, when the relief forming layer is cured by thermal crosslinking with the organic peroxide, unreacted portions of the organic peroxide uninvolved with radical generation may remain. The remaining organic peroxide may serve as an autoreactive additive, which may be exothermically decomposed during laser engraving. Consequently, the generated heat can be added to the laser energy, which can result in the increase in the engraving sensitivity.

In particular, when the glass transition temperature of the specific polymer (A) is not lower than the room temperature, the heat generated by the decomposition of the organic peroxide can be efficiently transferred to the binder polymer, and effectively used for the thermal decomposition of the specific polymer (A) and the auxiliary binder polymer (B), which may result in the further increase in the engraving sensitivity.

These effects can be markedly achieved when carbon black is used as the photo-thermal conversion agent, details about which will be given in the explanation of the photo-thermal conversion agent. This is likely due to that heat released from carbon black is transferred to the organic peroxide (c) to cause heat generation of the organic peroxide, which results in synergistic generation of thermal energy to be used for the decomposition of the specific polymer (A) and others.

(d) Thio Compound

Examples of the (d) thio compound which is preferable as the radical polymerization initiator usable in the invention include compounds having a structure represented by following Formula (4).

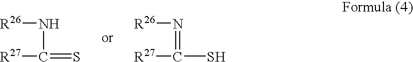

In Formula (4), R²⁶ represents an alkyl group, an aryl group or a substituted aryl group; R²⁷ represents a hydrogen atom or an alkyl group; and R²⁶ and R²⁷ may be bound to each other to represent a non-metallic atomic group necessary for forming a 5- to 7-membered ring which may contain a heteroatom selected from an oxygen atom, a sulfur atom and a nitrogen atom.

Specific examples of the thio compound represented by Formula (4) include the compounds shown below.

| No. | R²⁶ | R²⁷ |
|---|---|---|
| 1 | —H | —H |
| 2 | —H | —CH₃ |
| 3 | —CH₃ | —H |
| 4 | —CH₃ | —CH₃ |
| 5 | —C₆H₅ | —C₂H₅ |
| 6 | —C₆H₅ | —C₄H₉ |
| 7 | —C₆H₄Cl | —CH₃ |
| 8 | —C₆H₄Cl | —C₄H₉ |
| 9 | —C₆H₄—CH₃ | —C₄H₉ |
| 10 | —C₆H₄—OCH₃ | —CH₃ |
| 11 | —C₆H₄—OCH₃ | —C₂H₅ |
| 12 | —C₆H₄—OC₂H₅ | —CH₃ |
| 13 | —C₆H₄—OC₂H₅ | —C₂H₅ |
| 14 | —C₆H₄—OCH₃ | —C₄H₉ |

| | |
|---|---|
| 15 | —(CH₂)₂— |
| 16 | —(CH₂)₂—S— |
| 17 | —CH(CH₃)—CH₂—S— |
| 18 | —CH₂—CH(CH₃)—S— |
| 19 | —C(CH₃)₂—CH₂—S— |
| 20 | —CH₂—C(CH₃)₂—S— |
| 21 | —(CH₂)₂—O— |
| 22 | —CH(CH₃)—CH₂—O— |
| 23 | —C(CH₃)₂—CH₂—O— |
| 24 | —CH═CH—N(CH₃)— |
| 25 | —(CH₂)₃—S— |
| 26 | —(CH₂)₂—CH(CH₃)—S— |
| 27 | —(CH₂)₃—O— |
| 28 | —(CH₂)₅— |
| 29 | —C₆H₄—O— |
| 30 | —N═C(SCH₃)—S— |
| 31 | —C₆H₄—NH— |
| 32 | 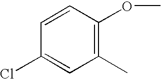 |

(e) Hexaarylbiimidazole Compound

Examples of the (e) Hexaarylbiimidazole compound which is preferable as the radical polymerization initiator usable in the invention include the rofin dimers described in JP-B Nos. 45-37377 and 44-86516. Specific examples thereof include 2,2′-bis(o-chlorophenyl)-4,4′,5,5′-tetraphenylbiimidazole, 2,2′-bis(o-bromophenyl)-4,4′,5,5′-tetraphenylbiimidazole, 2,2′-bis(o,p-dichlorophenyl)-4,4′,5,5′-tetraphenylbiimidazole, 2,2′-bis(o-chlorophenyl)-4,4′,5,5′-tetra(m-methoxyphenyl)biimidazole, 2,2′-bis(o,o′-dichlorophenyl)-4,4′,5,5′-tetraphenylbiimidazole, 2,2′-bis(o-nitrophenyl)-4,4′,5,5′-tetraphenylbiimidazole, 2,2′-bis(o-methylphenyl)-4,4′,5,5′-tetraphenylbiimidazole, 2,2′-bis(o-triflourophenyl)-4,4′,5,5′-tetraphenylbiimidazole, and the like.

(f) Keto Oxime Ester Compounds

Examples of the (f) keto oxime ester compound which is preferable as the radical polymerization initiator in the invention include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-p-toluenesulfonyloxyiminobutan-2-one, 2-ethoxycarbonyloxyimino-1-phenylpropan-1-one, and the like.

(g) Borate Compounds

Examples of the (g) Borate compounds which is preferable as the radical polymerization initiator usable in the invention include compounds represented by following Formula (5).

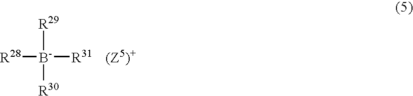

In Formula (5), R²⁸, R²⁹, R³⁰ and R³¹, which may be the same or different from each other, each represent a substituted or unsubstituted alkyl group, a substituted or unsubstituted aryl group, a substituted or unsubstituted alkenyl group, a substituted or unsubstituted alkynyl group, or a substituted or unsubstituted heterocyclic group, and two or more groups among R²⁸, R²⁹, R³⁰ and R³¹ may be bound with each other to form a cyclic structure, with the proviso that at least one among R²⁸, R²⁹, R³⁰ and R³¹ is a substituted or unsubstituted alkyl group; and (Z⁵)⁺ represents an alkali metal cation or a quaternary ammonium cation.

Specific examples of the compound represented by Formula (5) include the compounds described in U.S. Pat. Nos. 3,567,453 and 4,343,891, and European Patent Nos. 109,772 and 109,773, and the compounds shown below.

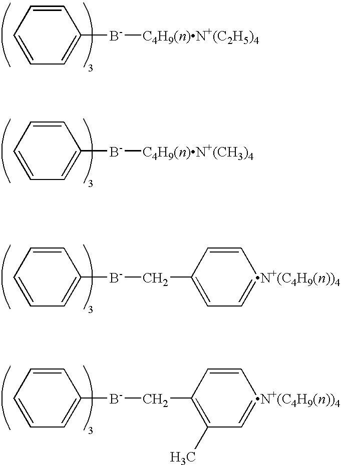

(h) Azinium Compounds

Examples of the (h) azinium salt compound which is preferable as the radical polymerization initiator usable in the invention include the compounds having an N—O bond as described in JP-A Nos. 63-138345, 63-142345, 63-142346 and 63-143537, and JP-B No. 46-42363.

(i) Metallocene Compounds

Examples of the (i) Metallocene compounds which is preferable as the radical polymerization initiator usable in the invention include the titanocene compounds described in JP-A Nos. 59-152396, 61-151197, 63-41484, 2-249 and 2-4705, and the iron arene complexes described in JP-A Nos. 1-304453 and 1-152109.

Specific examples of the titanocene compounds include dicyclopentadienyl-Ti-dichloride, dicyclopentadienyl-Ti-bisphenyl, dicyclopentadienyl-Ti-bis-2,3,4,5,6-pentafluorophen-1-yl, dicyclopentadienyl-Ti-bis-2,3,5,6-tetrafluorophen-1-yl, dicyclopentadienyl-Ti-bis-2,4,6-trifluorophen-1-yl, dicyclopentadienyl-Ti-2,6-difluorophen-1-yl, dicyclopentadienyl-Ti-bis-2,4-difluorophen-1-yl, dimethylcyclopentadienyl-Ti-bis-2,3,4,5,6-pentafluorophen-1-yl, dimethylcyclopentadienyl-Ti-bis-2,3,5,6-tetrafluorophen-1-yl, dimethylcyclopentadienyl-Ti-bis-2,4-difluorophen-1-yl, bis(cyclopentadienyl)-bis(2,6-difluoro-3-(pyrr-1-yl)phenyltitaniumbis(cyclopentadienyl) bis[2,6-difluoro-3-(methylsulfonamido)phenyl]titanium, bis(cyclopentadienyl)bis[2,6-difluoro-3-(N-butylbiaroylamino)phenyl]titanium, bis(cyclopentadienyl)bis[2,6-difluoro-3-(N-butyl-(4-chloropbenzoyl)amino)phenyl]titanium, bis(cyclopentadienyl)bis[2,6-difluoro-3-(N-benzyl-2,2-dimehylpentanoylamino)phenyl]titanium,

bis(cyclopentadienyl)bis[2,6-difluoro-3-(N-(2-ethylhexyl-4-tolylsulfonyl)amino)phenyl]titanium, bis(cyclopentadienyl)bis[2,6-difluoro-3-(N-(3-oxaheptyl)benzoylamino)phenyl]titanium, bis(cyclopentadienyl)bis[2,6-difluoro-3-(N-(3,6-dioxadecyl)benzoylamino)phenyl]titanium, bis(cyclopentadienyl)bis[2,6-difluoro-3-(trifluoromethylsulfonylamino)phenyl]titanium, bis(cyclopentadienyl)bis[2,6-difluoro-3-(trifluoroacetylamino)phenyl]titanium, bis(cyclopentadienyl)bis[2,6-difluoro-3-(2-chlorobenzoylamino)phenyl]titanium, bis(cyclopentadienyl)bis[2,6-difluoro-3-(4-chlorobenzoylamino)phenyl]titanium, bis(cyclopentadienyl)bis[2,6-difluoro-3-(N-(3,6-dioxadecyl)-2,2-dimethylpentanoylamino)phenyl]titanium, bis(cyclopentadienyl)bis[2,6-difluoro-3-(N-(3,7-dimethyl-7-methoxyoctyl)benzoylamino)phenyl]titanium, bis(cyclopentadienyl)bis[2,6-difluoro-3-(N-cyclohexylbenzoylamino)phenyl]titanium, and the like.

(j) Active Ester Compounds

Examples of the (j) active ester compound which is preferable as the radical polymerization initiator usable in the invention include the imidosulfonate compounds described in JP-A No. 62-6223, and the active sulfonates described in JP-B No. 63-14340 and JP-A No. 59-174831.

(k) Compounds Having Carbon-Halogen Bond

Examples of the (k) compound having a carbon-halogen bond which is preferable as the radical polymerization initiator usable in the invention include compounds represented by any one of the following Formulae (6) to (12).

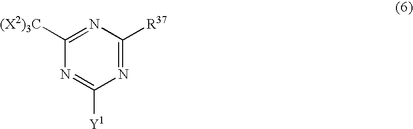

In Formula (6), X² represents a halogen atom; Y¹ represents —C(X²)₃, —NH₂, —NHR³⁸, —NR³⁸, or —OR³⁸; R³⁸ represents an alkyl group, a substituted alkyl group, an aryl group or a substituted aryl group; and R³⁷ represents —C(X²)₃, an alkyl group, a substituted alkyl group, an aryl group, a substituted aryl group, or a substituted alkenyl group.

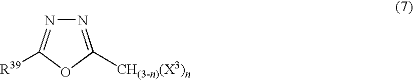

In Formula (7), R³⁹ represents an alkyl group, a substituted alkyl group, an alkenyl group, a substituted alkenyl group, an aryl group, a substituted aryl group, a halogen atom, an alkoxy group, a substituted alkoxy group, a nitro group, or a cyano group; X³ represents a halogen atom; and n represents an integer from 1 to 3.

R⁴⁰-Z⁶-CH₍₂₋ₘ₎(X³)ₘR⁴¹ (8)

In Formula (8), R⁴⁰ represents an aryl group or a substituted aryl group; R⁴¹ represents any one of the groups shown below, or a halogen atom; Z⁶ represents —C(═O)—, —C(═S)— or —SO₂—; X³ represents a halogen atom; and m represents 1 or 2.

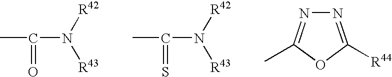

wherein R⁴² and R⁴³ are each an alkyl group, a substituted alkyl group, an alkenyl group, a substituted alkenyl group, an aryl group or a substituted aryl group; and R⁴⁴ has the same meaning as defined for R³⁸ in Formula (6).

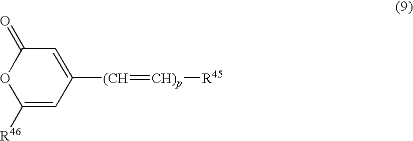

In Formula (9), R⁴⁵ represents an aryl group or a heterocyclic group, each of which may be substituted; R⁴⁶ represents a trihaloalkyl group or a trihaloalkenyl group, each having 1 to 3 carbon atoms; and p represents 1, 2 or 3.

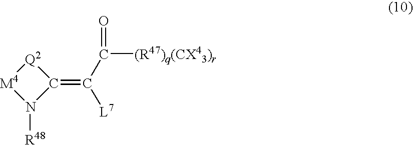

Formula (10) represents a carbonylmethylene heterocyclic compound having a trihalogenomethyl group. In Formula (10), L⁷ represents a hydrogen atom or a substituent of formula: CO—(R⁴⁷)_{q}(C(X⁴)₃)ᵣ; Q² represents a sulfur atom, a selenium atom, an oxygen atom, a dialkylmethylene group, an alken-1,2-ylene group, a 1,2-phenylene group, or an N—R group, in which R represents an alkyl group having 1 to 6 carbon atoms; M⁴ represents a substituted or unsubstituted alkylene or alkenylene group, or represents a 1,2-arylene group; R³⁸ represents an alkyl group, an aralkyl group or an alkoxyalkyl group; R⁴⁷ represents a carbocyclic or heterocyclic divalent aromatic group; X⁴ represents a chlorine atom, a bromine atom or an iodine atom; and either q=0 and r=1, or q=1 and r=1 or 2.

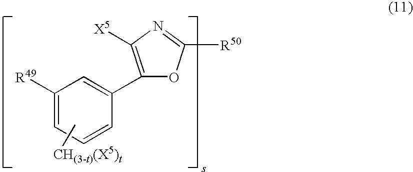

Formula (11) represents a 4-halogeno-5-(halogenomethylphenyl)oxazole compound. In Formula (11), X⁵ represents a halogen atom; t represents an integer from 1 to 3; s represents an integer from 1 to 4; R⁴⁹ represents a hydrogen atom or a CH₃₋ₜX⁵ₜ group; R⁵⁰ represents an unsaturated organic group which has a valency of s and may be substituted.

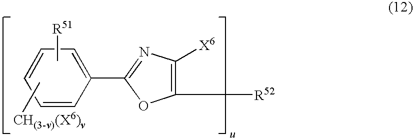

Formula (12) represents a 2-(halogenomethylphenyl)-4-halogeno-oxazole derivative. In Formula (12), X⁶ represents a halogen atom; v represents an integer from 1 to 3; u represents an integer from 1 to 4; R⁵¹ represents a hydrogen atom or a CH₃₋ᵥX⁶ᵥ group; and R⁵² represents an unsaturated organic group which has a valency of u and may be substituted.

Specific examples of the compounds having a carbon-halogen bond include the compounds described in Wakabayashi, et al., Bull. Chem. Soc. Japan, 42, 2924 (1969), for example, 2-phenyl-4,6-bis(trichlormethyl)-S-triazine, 2-(p-chlorphenyl)-4,6-bis(trichlormethyl)-S-triazine, 2-(p-tolyl)-4,6-bis(trichlormethyl)-3-triazine, 2-(p-methoxyphenyl)-4,6-bis(trichlormethyl)-S-triazine, 2-(2′,4′-dichlorphenyl)-4,6-bis(trichlormethyl)-S-triazine, 2,4,6-tris(trichlormethyl)-S-triazine, 2-methyl-4,6-bis(trichlormethyl)-S-triazine, 2-n-nonyl-4,6-bis(trichlormethyl)-S-triazine, 2-(α,α,β-trichlorethyl)-4,6-bis(trichlormethyl)-S-triazine, and the like. In addition, the compounds described in U.K. Patent No. 1388492, for example, 2-styryl-4,6-bis(trichlormethyl)-S-triazine, 2-(p-methylstyryl)-4,6-bis(trichlormethyl)-S-triazine, 2-(p-methoxystyryl)-4,6-bis(trichlormethyl)-S-triazine, 2-(p-methoxystyryl)-4-amino-6-trichlormethyl-S-triazine, and the like; the compounds described in JP-A No. 53-133428, for example, 2-(4-methoxy-naphth-1-yl)-4,6-bis-trichlormethyl-S-triazine, 2-(4-ethoxy-naphth-1-yl)-4,6-bis-trichlormethyl-S-triazine, 2-[4-(2-ethoxyethyl)-naphth-1-yl]-4,6-bis-trichlormethyl-S-triazine, 2-(4,7-dimethoxy-naphth-1-yl)-4,6-bis-trichlormethyl-S-triazine, 2-(acenaphth-5-yl)-4,6-bis-trichlormethyl-S-triazine, and the like; the compounds described in German Patent No. 3337024, for example, the compounds shown below; and the like may also be mentioned. Furthermore, there may be mentioned a family of compounds as shown below, which can be easily synthesized by a person having ordinary skill in the art according to the synthesis method described in M. P. Hutt, E. F. Elslager and L. M. Herbel, “Journal of Heterocyclic Chemistry”, Vol. 7, No. 3, p. 511-(1970), for example, the following compounds.

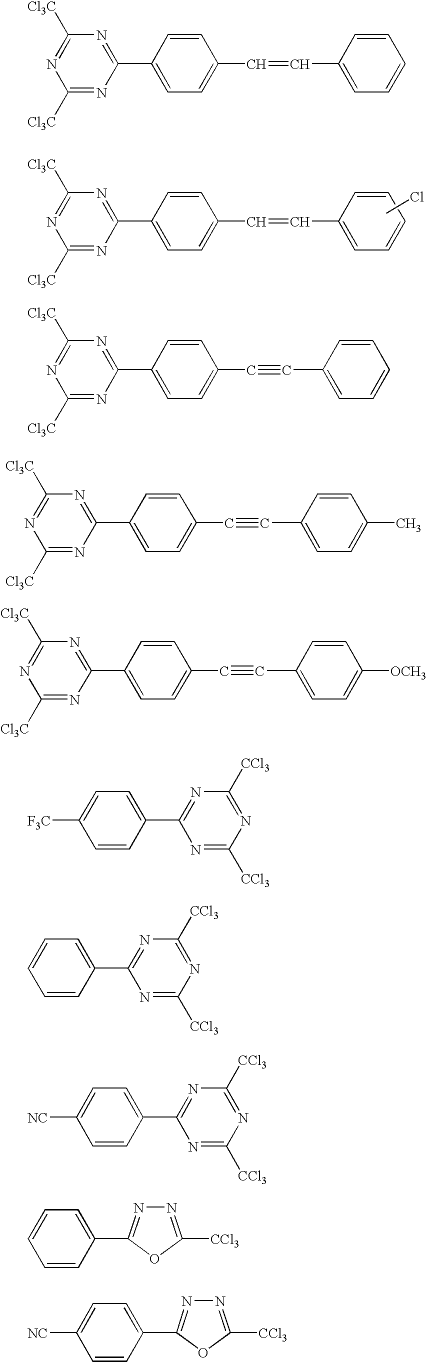

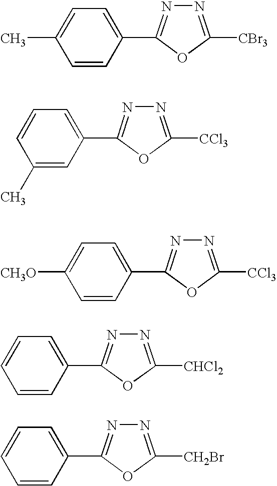

(l) Azo Compound

Examples of the (1) azo compound which is preferable as the radical polymerization initiator usable in the invention include 2,2′-azobisisobutyronitrile, 2,2′-azobispropionitrile, 1,1′-azobis(cyclohexane-1-carbonitrile), 2,2′-azobis(2-methylbutyronitrile), 2,2′-azobis(2,4-dimethylvaleronitrile), 2,2′-azobis(4-methoxy-2,4-dimethylvaleronitrile), 4,4′-azobis(4-cyanovaleric acid), dimethyl 2,2′-azobisisobutyrate, 2,2′-azobis(2-methylpropionamideoxime), 2,2′-azobis[2-(2-imidazolin-2-yl)propane], 2,2′-azobis {2-methyl-N-[1,1-bis(hydroxymethyl)-2-hydroxyethyl]propionamide}, 2,2′-azobis[2-methyl-N-(2-hydroxyethyl)propionamide], 2,2′-azobis(N-butyl-2-methylpropionamide), 2,2′-azobis(N-cyclohexyl-2-methylpropionamide), 2,2′-azobis[N-(2-propenyl)-2-methylpropionamide], 2,2′-azobis(2,4,4-trimethylpentane), and the like.

More preferable examples of the radical polymerization initiator for the invention include the (a) aromatic ketone, (b) onium salt compound, (c) organic peroxide, (e) hexaarylbiimidazole compound, (i) metallocene compound, and (k) compound having a carbon-halogen bond, and most preferable examples thereof include an aromatic iodonium salt, an aromatic sulfonium salt, a titanocene compound, and a trihalomethyl-S-triazine compound represented by Formula (6).

The amount of the polymerization initiator (D) used in the invention may be preferably 0.01% by mass to 10% by mass, and more preferably 0.1% by mass to 3% by mass, relative to the total solid content of the resin composition for laser engraving containing the polymerizable compound (C). The polymerization initiators are suitably used by using them individually alone, or in combination of two or more species.

(E) Photo-Thermal Conversion Agent

The composition for laser engraving of the invention preferably contains a photo-thermal conversion agent which absorbs light having a wavelength which is in a range of 700 nm to 1,300 nm. Namely, the photo-thermal conversion agent which can be used in the invention has a maximum absorption wavelength of 700 nm to 1,300 nm.

The photo-thermal conversion agent can be used as an infrared-ray absorbing agent when the composition for laser engraving of the invention is applied to laser engraving which uses a laser which emits light having a wavelength of 700 nm to 1,300 nm (such as a YAG laser, a fiber laser or a surface emitting laser) as a light source. The photo-thermal conversion agent absorbs laser light to generate heat, which enhances thermal decomposition of the resin composition. The photo-thermal conversion agent which can be used in the invention is preferably a dye or a pigment, the maximum absorption wavelength of which being in the range of 700 nm to 1,300 nm.

Commercially available dyes and known dyes that are described in literatures such as “Handbook of Dyes” (edited by the Society of Synthetic Organic Chemistry, Japan, 1970), may be used as for the dye. Specific examples thereof include azo dyes, metal complex azo dyes, pyrazolone azo dyes, naphthoquinone dyes, anthraquinone dyes, phthalocyanine dyes, carbonium dyes, diimmonium compounds, quinonimine dyes, methine dyes, cyanine dyes, squarylium colorants, pyrylium salts, and metal thiolate complexes.

Preferable examples of the dye include the cyanine dyes described in JP-A Nos. 58-125246, 59-84356, 59-202829, 60-78787 and the like; the methine dyes described in JP-A Nos. 58-173696, 58-181690, 58-194595, and the like; the naphthoquinone dyes described in JP-A Nos. 58-112793, 58-224793, 59-48187, 59-73996, 60-52940, 60-63744 and the like; the squarylium colorants described in JP-A No. 58-112792 and the like; the cyanine dyes described in U.K. Patent No. 434,875; and the like

Preferable examples of the dye further include the near-infrared absorption sensitizers described in U.S. Pat. No. 5,156,938, the substituted arylbenzo(thio)pyrylium salts described in U.S. Pat. No. 3,881,924; the trimethinethiapyrylium salts described in JP-A No. 57-142645 (U.S. Pat. No. 4,327,169); the pyrylium-compounds described in JP-A Nos. 58-181051, 58-220143, 59-41363, 59-84248, 59-84249, 59-146063 and 59-146061; the cyanine dyes described in JP-A No. 59-216146; the pentamethinethiopyrylium salts and the like described in U.S. Pat. No. 4,283,475; and the pyrylium compounds described in JP-B Nos. 5-13514 and 5-19702. Preferable examples of the dye furthermore include the near-infrared absorption dyes represented by formulae (I) and (II) in U.S. Pat. No. 4,756,993.

Preferable examples of the photo-thermal conversion agent of the invention include the specific indolenine cyanine colorants described in JP-A No. 2002-278057.

Particularly preferable examples among these dyes include cyanine colorants, squarylium colorants, pyrylium salts, nickel thiolate complexes, and indolenine cyanine colorants. Cyanine colorants or indolenine cyanine colorants are even more preferable.

Specific examples of the cyanine colorants which may be suitably used in the invention include those described in paragraphs 0017 to 0019 of JP-A No. 2001-133969, paragraphs 0012 to 0038 of JP-A No. 2002-40638, and paragraphs 0012 to 0134 of JP-A No. 2002-23360.

The colorants represented by following Formula (d) or Formula (e) are preferable from the viewpoint of photo-thermal conversion property.

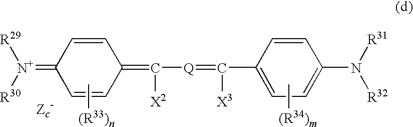

In Formula (d), R²⁹ to R³¹ each independently represent a hydrogen atom, an alkyl group or an aryl group; R³³ and R³⁴ each independently represent an alkyl group, a substituted oxy group, or a halogen atom; n and m each independently represent an integer from 0 to 4; R²⁹ and R³⁰, or R³¹ and R³² may be respectively be bound to each other to form a ring, and R²⁹ and/or R³⁰ may be bound to R³³, and R³¹ and/or R³² may be bound to R³⁴, to respectively form a ring; if a plurality of R³³ are present, the R³³s may be bound to each other to form a ring; if a plurality of R³⁴ are present, the R³⁴s may be bound to each other to form a ring; X² and X³ each independently represent a hydrogen atom, an alkyl group or an aryl group, and at least one of X² and X³ represents a hydrogen atom or an alkyl group; Q represents a trimethine group or pentamethine group which may be substituted, and may form a cyclic structure together with a divalent organic group; and Zc⁻ represents a counter-anion. However, if the colorant represented by formula (d) has an anionic substituent in the structure and does not require charge neutralization, Zc⁻ is not necessary. Preferably, Zc⁻ is a halogen ion, a perchloric acid ion, a tetrafluoroborate ion, a hexafluorophosphate ion or a sulfonic acid ion, from the viewpoint of the storage stability of the photosensitive layer coating solution, and particularly preferably, Zc⁻ is a perchloric acid ion, a hexafluorophosphate ion or an arylsulfonic acid ion.

Specific examples of the dyes represented by Formula (d), which may be suitably used in the invention, include those shown below.

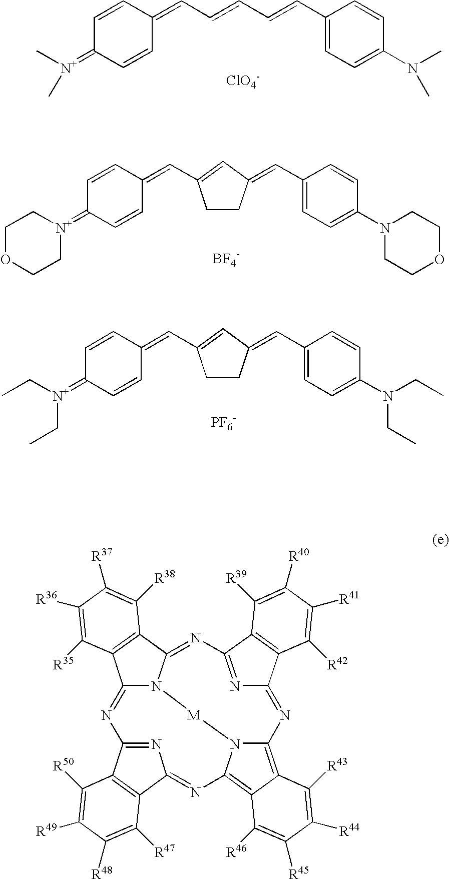

In Formula (e), R³⁵ to R⁵⁰ each independently represent a hydrogen atom, a halogen atom, a cyano group, an alkyl group, an aryl group, an alkenyl group, an alkynyl group, a hydroxyl group, a carbonyl group, a thio group, a sulfonyl group, a sulfinyl group, an oxy group, an amino group, or an onium salt structure, and if it is possible to introduce substituents to these groups, the groups may be substituted; M represents two hydrogen atoms or metal atoms, a halo-metal group, or an oxy-metal group, and as the metal atoms included therein, there may be mentioned the atoms of Groups IA, IIA, IIIB and IVB of the Period Table of Elements, the first-row, second-row and third-row transition metals, and lanthanoid elements. Among them, copper, magnesium, iron, zinc, cobalt, aluminum, titanium and vanadium are preferable.

Specific examples of the dyes represented by Formula (e), which may be suitably used in the invention, include those shown below.

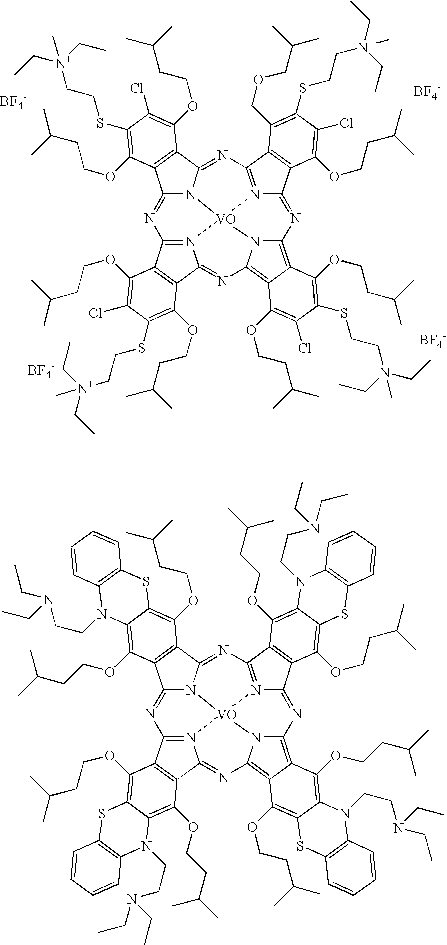

Examples of the pigment which may be used in the invention include commercially available pigments, and the pigments described in the Color Index (C.I.) Handbook, “Handbook of New Pigments” (edited by Japan Association of Pigment Technology, 1977), “New Pigment Application Technology” (published by CMC, Inc., 1986), and “Printing Ink Technology” (published by CMC, 1984).

Examples of the pigments include black pigments, yellow pigments, orange pigments, brown pigments, red pigments, magenta pigments, blue pigments, green pigments, fluorescent pigments, metal powder pigments, and other polymer-bound pigments. Specifically, insoluble azo pigments, azo lake pigments, condensed azo pigments, chelate azo pigments, phthalocyanine pigments, anthraquinone pigments, perylene- and perinone pigments, thio indigo pigments, quinacridone pigments, dioxazine pigments, isoindolinone pigments, quinophthalone pigments, dyed lake pigments, azine pigments, nitroso pigments, nitro pigments, natural pigments, fluorescent pigments, inorganic pigments, carbon black, and the like may be used. Among these pigments, carbon black is preferable.

These pigments may be used without being subjected to a surface treatment, or may be used after being subjected to a surface treatment. Examples of a method of the surface treatment include a method of coating the pigment surface with resin or wax, a method of adhering surfactants to the pigment surface, a method of binding a reactive substance (for example, a silane coupling agent, an epoxy compound, polyisocyanate, or the like) to the pigment surface, and the like. These surface treatment methods are described in “Properties and Applications of Metal Soaps” (published by Saiwai Shobo Co., Ltd.), “Printing Ink Technology” (published by CMC, Inc., 1984), and “New Pigment Application Technology” (published by CMC, Inc., 1986).

The particle size of the pigment is preferably in the range of 0.01 μm to 10 μm, more preferably in the range of 0.05 μm to 1 μm, and particularly preferably in the range of 0.1 μm to 1 μm. When the particle size of the pigment is 0.01 μm or larger, the dispersion stability of the pigment in the coating solution can be increased. Also, when the particle size is 10 μm or less, the uniformity of the layer formed from the resin composition can be improved.

Any known dispersing technologies that are used in the production of ink or in the production of toner may be used as the method for dispersing the pigment. Examples of the dispersing instrument used in the dispersing include an ultrasonic dispersing machine, a sand mill, an attritor, a pearl mill, a super mill, a ball mill, an impeller, a disperser, a KD mill, a colloid mill, Dynatron, a triple-roll mill, a pressurized kneader, and the like. Details are described in “New Pigment Application Technology” (published by CMC, Inc., 1986).

In embodiments, the photo-thermal conversion agent used in the invention can be at least one selected from cyanine compounds and phthalocyanine compounds, which are preferable from the viewpoint of high engraving sensitivity. The engraving sensitivity tends to be further increased and is thus preferable when at least one of these photo-thermal conversion agents are used in a combination under a condition that the thermal decomposition temperature of the photo-thermal conversion agent is equal to or higher than the thermal decomposition temperature of a hydrophilic polymer which is suitable as the binder polymer.

Specific examples of the photo-thermal conversion agent that may be used in the invention include a colorant which have a maximum absorption wavelength in the range of 700 nm to 1,300 nm and is selected from cyanine colorants such as heptamethine cyanine colorants, oxonol colorants such as pentamethine oxonol colorants, indolium colorants, benzindolium colorants, benzothiazolium colorants, quinolinium colorants, phthalide compounds reacted with a color developing agent, and the like. Photo-absorption properties of colorants greatly vary depending on the type and the intramolecular position of the substituent, the number of conjugate bonds, the type of counterion, the surrounding environment around the colorant molecule, or the like.

Commercially available laser colorants, hypersaturated absorption colorants, and near-infrared absorption colorants may also be used. Examples of the laser colorants include “ADS740PP”, “ADS745HT”, “ADS760MP”, “ADS740WS”, “ADS765WS”, “ADS745HO”, “ADS790NH” and “ADS800NH” (all trade names, manufactured by American Dye Source, Inc. (Canada)); and “NK-3555”, “NK-3509” and “NK-3519” (all trade names, manufactured by Hayashibara Biochemical Labs, Inc.). Examples of the near-infrared absorption colorants include “ADS775MI”, “ADS775MP”, “ADS775HI”, “ADS775PI”, “ADS775PP”, “ADS780MT”, “ADS780BP”, “ADS793EI”, “ADS798MI”, “ADS798MP”, “ADS800AT”, “ADS805PI”, “ADS805PP”, “ADS805PA”, “ADS805PF”, “ADS812MI”, “ADS815EI”, “ADS818HI”, “ADS818HT”, “ADS822MT”, “ADS830AT”, “ADS838MT”, “ADS840MT”, “ADS845BI”, “ADS905AM”, “ADS956BI”, “ADS1040T”, “ADS1040P”, “ADS1045P”, “ADS1050P”, “ADS1060A”, “ADS1065A”, “ADS1065P”, “ADS1100T”, “ADS1120F”, “ADS1120P”, “ADS780WS”, “ADS785WS”, “ADS790WS”, “ADS805WS”, “ADS820WS”, “ADS830WS”, “ADS850WS”, “ADS780HO”, “ADS810CO”, “ADS820HO”, “ADS821NH”, “ADS840NH”, “ADS880MC”, “ADS890MC” and “ADS920MC” (all trade names, manufactured by American Dye Source, Inc. (Canada)); “YKR-2200”, “YKR-2081”, “YKR-2900”, “YKR-2100” and “YKR-3071” (all trade names, manufactured by Yamamoto Chemical Industry Co., Ltd.); “SDO-1000B” (trade name, manufactured by Arimoto Chemical Co., Ltd.); and “NK-3508” and “NKX-114” (both trade names, manufactured by Hayashibara Biochemical Labs, Inc.), while the examples are not intended to be limited to these.

Those described in Japanese Patent No. 3271226 may be used as the phthalide compound reacted with a color developing agent. Phosphoric acid ester metal compounds, for example, the complexes of a phosphoric acid ester and a copper salt described in JP-A No. 6-345820 and WO 99/10354, may also be used as the photo-thermal conversion agent. Further, ultramicroparticles having light absorption characteristics in the near-infrared region, and having a number average particle size of preferably 0.3 μm or less, more preferably 0.1 μm or less, and even more preferably 0.08 μm or less, may also be used as the photo-thermal conversion agent. Examples thereof include metal oxides such as yttrium oxide, tin oxide and/or indium oxide, copper oxide or iron oxide, and metals such as gold, silver, palladium or platinum. Also, compounds obtained by adding metal ions such as the ions of copper, tin, indium, yttrium, chromium, cobalt, titanium, nickel, vanadium and rare earth elements, into microparticles made of glass or the like, which have a number average particle size of 5 μm or less, and more preferably 1 μm or less, may also be used as the photo-thermal conversion agent.

In the case that the colorant may react with a component contained in the resin composition of the invention and causes a change in its maximum absorption wavelength of light absorption, the colorant may be encapsulated in microcapsules. In that case, the number average particle size of the capsules is preferably 10 μm or less, more preferably 5 μm or less, and even more preferably 1 mm or less. Compounds obtained by adsorbing metal ions of copper, tin, indium, yttrium, rare earth elements or the like on ion-exchanged microparticles, may also be used as the photo-thermal conversion agent. The ion-exchanged microparticles may be any of organic resin microparticles or inorganic microparticles. Examples of the inorganic microparticles include amorphous zirconium phosphate, amorphous zirconium phosphosilicate, amorphous zirconium hexametaphosphate, lamellar zirconium phosphate, reticulated zirconium phosphate, zirconium tungstate, zeolites and the like. Examples of the organic resin microparticles include generally used ion-exchange resins, ion-exchange celluloses, and the like.

Most preferably, the photo-thermal conversion agent in the invention can be a carbon black with a viewpoint of providing high engraving sensitivity. It is estimated that since the carbon black has higher heat resistance compared with organic dye or organic pigment, it is scarcely self-decomposed by the heat generated by photo-thermal conversion of its own during laser irradiation and can stably generate heat during laser irradiation. On the other hand, an organic dye or a organic pigment may have lower heat resistance in view of the nature that this is an organic compound and is self-decomposed by the heat generated by photo-thermal conversion of its own during laser irradiation and may be somewhat inferior when compared with the carbon black in view of stable heat generation during laser irradiation. Accordingly, the heat sensitivity is considered as particularly high when a carbon black is used.

Any kind of the carbon black may be used as long as the carbon black has stable dispersibility or the like in the resin composition. The carbon black may be a product classified according to American Society for Testing and Materials (ASTM) standard or may be those usually used in various applications such as coloring, rubber making, or batteries.

Examples of the carbon black include furnace black, thermal black, channel black, lamp black, acetylene black, and the like. In addition, black-colored colorants such as carbon black may be used in the form of color chips or color pastes, in which the colorants have been dispersed in advance in nitrocellulose, a binder or the like, to prepare the resin composition, using a dispersant which facilitates dispersing the ships or pastes in the resin composition if necessary. Such chips or pastes can be easily obtained as commercially available products.

When carbon black is used as the photo-thermal conversion agent, it is more preferable that the resin composition for laser engraving of the invention is subjected to thermal crosslinking rather than photocrosslinking with UV light in view of achieving better curability of the film composed of the composition. Further, it is more preferable that carbon black is used in combination with the organic peroxide as the polymerization initiator (D) in view of achieving remarkably high engraving sensitivity.

In particularly preferable embodiments of the invention, the specific polymer (A), the auxiliary binder polymer (B) having a glass transition temperature not lower than room temperature, the organic peroxide as the polymerization initiator (D), and carbon black as the photo-thermal conversion agent (E) are used in combination.

When the film (relief forming layer) is subjected to thermal crosslinking with the organic peroxide (c) used as the polymerization initiator (D), unreacted portions of the organic peroxide remain in the film. The remaining portions of the organic peroxide serve as an autoreactive additive, and are exothermically decomposed during laser engraving. Consequently, the heat generated therefrom can be added to the laser energy, which results in the increase in the engraving sensitivity. When the carbon black coexists in the system, heat generated by the photo-thermal conversion function of the carbon black can be transferred to the organic peroxide (C) as well as the specific polymer (A). As a result of this, heat can be generated not only from the carbon black but also from the organic peroxide, which results in synergistic generation of thermal energy to be used for the decomposition of the specific polymer (A) and the auxiliary binder polymer (B). In this regard, organic dyes and pigments other than carbon black may also act in the same manner. However, organic dyes and pigments, which have low heat resistance, may be not endure the above-described synergetic heat generation, and may be thus decomposed. Accordingly, uses of organic dyes and pigments other than carbon black may not achieve as high sensitivity as that achieved by carbon black.

When the glass transition temperature of the specific polymer (A) is not lower than room temperature, the heat generated by the decomposition of the organic peroxide and released from the carbon black can be efficiently transferred to the specific polymer (A) and the optionally-used auxiliary binder polymer (B), and the heat can be effectively used for the thermal decomposition of the specific polymer (A) and the auxiliary binder polymer (B), which may result in the achievement of the above-described effects.

While the content of the photo-thermal conversion agent in the resin composition for laser engraving may greatly vary depending on the magnitude of the molecular absorption coefficient thereof, it is preferably in a range from 0.01 mass % to 20 mass %, more preferably in a range from 0.05 mass % to 10 mass %, and particularly preferably in a range from 0.1 mass % to 5 mass %, based on the total solid content of the resin composition.

(F) Plasticizer

The resin composition for laser engraving of the invention preferably contains a plasticizer.

Examples of the plasticizer include dioctyl phthalate, didodecyl phthalate, triethylene glycol dicaprylate, methyl glycol phthalate, tricresyl phosphate, dioctyl adipate, dibutyl sebacate, triacetylglycerin, and the like. Examples of the plasticizer further include polyethylene glycols, polypropylene glycol (mono-ol type, diol type and the like), and polypropylene glycol (mono-ol type, diol type and the like).

Since the plasticizer is expected to have an effect to soften the relief forming layer, the plasticizer is desired to have good compatibility with the binder polymer. In general, a highly hydrophilic compound has good compatibility with the binder polymer. Among highly hydrophilic compounds, an ether compound containing a heteroatom in a straight chain, or a compound having a structure in which a hydrophilic group such as secondary amine and a hydrophobic group are alternately repeated, can be preferably used. The presence of the hydrophilic group such as —O— or —NH— achieves the compatibility of such compounds with PVA compounds, and the other hydrophobic group weakens the intermolecular force of PVA compounds, to thereby contribute to the softening.

A compound having fewer hydroxyl groups which are capable of forming hydrogen bonding between PVA compounds can be also preferably used as the plasticizer. Examples of such compound include ethylene glycol, propylene glycol, and dimers, trimers, and homo-oligomers or co-oligomers such as tetramer or higher-mers of ethylene glycol and propylene glycol, and secondary amines such as diethanolamine and dimethylolamine. Among these, ethylene glycols (monomers, dimers, trimers and oligomers) having small steric hindrance, excellent compatibility and low toxicity, are particularly preferably used as the plasticizer.

Ethylene glycols are roughly classified into three types according to the molecular weight. The first group includes ethylene glycol, which is a monomer; the second group includes diethylene glycol, which is a dimer, and triethylene glycol, which is a trimer; and the third group includes polyethylene glycol, which is a tetramer or higher one. Polyethylene glycol is roughly classified into liquid polyethylene glycol having a molecular weight in the range of 200 to 700, and solid polyethylene glycol having a molecular weight of 1000 or greater, and those are commercially available under names followed by the average molecular weight in many cases.

As a result of intensive search, the present inventors have found that the lower molecular weight of the plasticizer is, the effect of the plasticizer to soften a resin is enhanced. In consideration of this, compounds which may be particularly preferably used as the plasticizer are ethylene glycol which belongs to the first group, diethylene glycol and triethylene glycol which belong to the second group, and tetraethylene glycol (tetramer) which belongs to the third group. Among them, diethylene glycol, triethylene glycol and tetraethylene glycol can be more preferably used as the plasticizer from the viewpoints of low toxicity, absence of extraction from the resin composition, and excellent handling property thereof. Mixtures of two or more of the plasticizers can be also preferably used.

The plasticizer may be added in a proportion of 10% by mass or less with respect to the total mass of the solid content of the resin composition for laser engraving.

Additives for enhancing engraving sensitivity Nitrocellulose

Examples of an additive for enhancing engraving sensitivity include nitrocellulose.

Nitrocellulose, that is a self-reactive compound, generates heat at the time of laser engraving to assist thermal decomposition of the co-existing hydrophilic polymer. The engraving sensitivity is assumed to be enhanced as a result thereof.

Any nitrocellulose can be used in the invention as long as it can be thermally decomposed, and can be any one of RS (regular soluble) nitrocellulose, SS (spirit soluble) nitrocellulose and AS (alcohol soluble) nitrocellulose. The content of nitrogen in the nitrocellulose is usually about 10% by mass to 14% by mass, preferably 11% by mass to 12.5% by mass, and more preferably about 11.5% by mass to 12.2% by mass. The degree of polymerization of the nitrocellulose may also be selected from a wide range of about 10 to 1500. The polymerization degree of the nitrocellulose is typically 10 to 900, and preferably about 15 to about 150. Preferable examples of the nitrocellulose include those having a solution viscosity of 20 seconds to 1/10 seconds, more preferably about 10 seconds to ⅛ seconds, measured according to the method of viscosity indication provided by Hercules Powder Company, that is also known as JIS K6703 “Nitrocelluloses for Industrial Use”. The nitrocellulose which can be used in the invention typically has a solution viscosity of 5 seconds to ⅛ seconds, which is preferably about 1 second to ⅛ seconds.

The RS nitrocellulose (for example, a nitrocellulose having a nitrogen content of about 11.7% to 12.2%), which is soluble in a ester such as ethyl acetate, a ketone such as methyl ethyl ketone or methyl isobutyl ketone, or an ether such as cellosolve, can be used as a nitrocellulose which can be contained in the resin composition for laser engraving

The nitrocellulose may be used singly or in combination of two or more thereof as necessary.

The content of nitrocellulose may be selected as long as decrease in the engraving sensitivity of the resin composition for laser engraving can be avoided, and the content is typically 5 parts by mass to 300 parts by mass, preferably 20 parts by mass to 250 parts by mass, more preferably 50 parts by mass to 200 parts by mass, and particularly preferably 40 parts by mass to 200 parts by mass, relative to 100 parts by mass of the binder polymer and the polymerizable compound.

Highly Thermally Conductive Substance

In view of improving the engraving sensitivity of the resin composition of the invention, a highly thermally conductive substance can be added to the resin composition as an additive for assisting heat transfer in the resin composition.

Examples of the highly thermally conductive substance include an inorganic compound such as a metal particle and an organic compound such as an electrically conductive polymer.

Preferable examples of the metal particle include gold microparticles, silver microparticles and copper microparticles, each having a particle size in the order of micrometers to a few nanometers.

Preferable examples of the electrically conductive polymers include polyaniline, polythiophene, polyisothianaphthene, polypyrrole, polyethylene dioxythiophene, polyacetylene and modified compounds thereof. From the viewpoint of being highly sensitive, polyaniline, polythiophene, polyethylene dioxythiophene and modified compounds thereof are further preferable, and polyaniline is paricularly preferable. While the polyaniline can be either in an emeraldine base form or in an emeraldine salt form when added to the resin composition, it can be preferably in an emeraldine salt form in view of higher heat transfer efficiency.

Specific examples of the metal particle and the electrically conductive polymer include commercially available products supplied by Sigma Aldrich Corp., Wako Pure Chemical Industries, Ltd., Tokyo Chemical Industry Co., Ltd., Mitsubishi Rayon Co.,Ltd., Panipol Oy and the like. Specific examples which are particularly preferable in view of improving the heat transfer efficiency include AQUAPASS-01x (trade name, manufactured by Mitsubishi Rayon Co., Ltd.), and PANIPOL W and PANIPOL F (both trade names, manufactured by Panipol Oy).

It is preferable that the electrically conductive polymer is added to the resin composition in a form of an aqueous dispersion or an aqueous solution. As described above, the solvent used in preparing the resin composition for laser engraving is water or an alcoholic solvent in the case where a hydrophilic polymer and/or an alcohol-philic polymer, which are preferable embodiments of the binder polymer in the invention, are used. Accordingly, when the electrically conductive polymer is added to the resin composition in a form of an aqueous dispersion or an aqueous solution, miscibility of the electrically conductive polymer with a hydrophilic or an alcohol-philic polymer may become good, which may further result in increasing in the strength of a film formed by the resin composition for laser engraving and also in increasing the engraving sensitivity of the film due to an improvement in its heat transfer efficiency.

Co-Sensitizer

The sensitivity required for photo-curing of the resin composition for laser engraving may be further enhanced by using a co-sensitizer. While the operating mechanism is not clear, it is thought to be largely based on the following chemical process. Namely, it is presumed that various intermediate active species (radicals and cations) generated in the course of a photoreaction initiated by a polymerization initiator and an addition polymerization reaction subsequent thereto, react with the co-sensitizer to generate new active radicals. These intermediate active species may be roughly classified into (a) compounds which are reduced and can generate active radicals; (b) compounds which are oxidized and can generate active radicals; and (c) compounds which react with less active radicals, and are converted to more active radicals or act as a chain transfer agent. However, in many cases, there is no general theory applicable on which individual compound belongs to which class.

Examples of the co-sensitizer which may be applied in the invention include the following compounds.

(a) Compounds Which Generate Active Radicals Upon Being Reduced

Compounds having a carbon-halogen bond are classified in this group. It is presumed that an active radical is generated when the carbon-halogen bond is reductively cleaved. Specific preferable examples of the compound include trihalomethyl-s-triazines and trihalomethyloxadiazoles.

Compounds having a nitrogen-nitrogen bond are also classified in this group. It is presumed that an active radical is generated when the nitrogen-nitrogen bond is reductively cleaved. Specific preferable examples of the compound include hexaarylbiimidazoles.

Compounds having an oxygen-oxygen bond are also classified in this group. It is presumed that an active radical is generated when the oxygen-oxygen bond is reductively cleaved. Specific preferable examples of the compound include organic peroxides.

Onium compounds are also classified in this group. It is presumed that an active radical is generated when a carbon-heteroatom bond or an oxygen-nitrogen bond in an onium compound is reductively cleaved. Specific preferable examples of the compound include diaryliodonium salts, triarylsulfonium salts, N-alkoxypyridinium salts (azinium) salts, and the like.

Ferrocenes and iron arene complexes are also classified in this group. It is presumed that an active radical is reductively generated therefrom.

(b) Compounds Which Generate Active Radicals Upon Being Oxidized

Alkylate complexes can be classified in this group. It is presumed that an active radical is generated when a carbon-heteroatom bond therein is oxidatively cleaved. Specific preferable examples thereof include triarylalkylborates.

Alkylamine compounds can be also classified in this group. It is presumed that an active radical is generated when a C—X bond on a carbon atom which is adjacent to a nitrogen atom therein is cleaved through oxidation. Preferable examples of the X include a hydrogen atom, a carboxyl group, a trimethylsilyl group, a benzyl group and the like. Specific preferable examples of the alkylamine compound include ethanolamines, N-phenylglycine, and N-trimethylsilylmethylanilines.

Sulfur-containing or tin-containing compounds, which are obtained by substituting the nitrogen atom of the above-mentioned alkylamine compounds by a sulfur atom or a tin atom, can be also classified in this group and may generate an active radical in a similar manner as the alkylamine compounds. Compounds having an S—S bond are also known to have sensitivity enhancing property by the S—S bond cleavage.

α-substituted methylcarbonyl compounds, which may generate an active radical by the cleavage of a bond between a carbonyl moiety and an α-carbon atom through oxidation, can be also classified in this group. Compounds obtained by converting the carbonyl moiety in the α-substituted methylcarbonyl compounds into an oxime ether also show an effect which is similar to that of the α-substituted methylcarbonyl compounds. Specific examples of the compounds include 2-alkyl-1-[4-(alkylthio)phenyl]-2-morpholinopronone-1's, and oxime ethers obtained by reacting a 2-alkyl-1-[4-(alkylthio)phenyl]-2-morpholinopronone-1 with a hydroxylamine and then etherifying the N—OH moiety in the resultant.

Sulfinic acid salts can be also classified in this group. An active radical may be reductively generated therefrom. Specific examples thereof include sodium arylsulfinate.

(c) Compounds Which Convert Less Active Radicals to More Active Radicals by Reacting Therewith, and Compounds Which Act as a Chain Transfer Agent

Compounds having SH, PH, SiH or GeH within the molecule can be classified in this group. These compounds may generate a radical by donating hydrogen to a less active radical species, or may generate a radical by being oxidized and then deprotonated. Specific examples thereof include 2-mercaptobenzothiazoles, 2-mercaptobenzoxazoles, 2-mercaptobenzimidazoles, and the like.

More specific examples of these co-sensitizers are described in, for example, JP-A No. 9-236913, as additives for enhancing the sensitivity, and those may also be applied in the invention. Some examples thereof will be shown below, while the invention is not limited thereto. In the following formulae, “-TMS” represents a trimethylsilyl group.

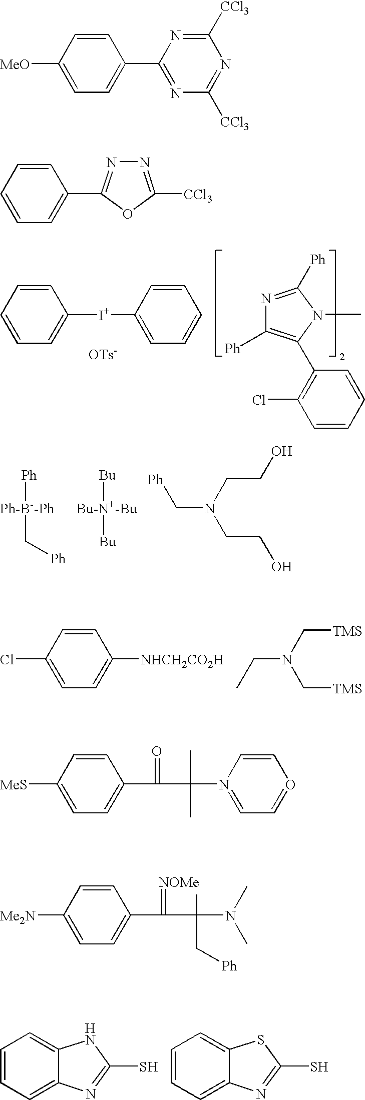

As is similar to the photo-thermal conversion agent, various chemical modifications for improving the properties of the resin composition for laser engraving may be carried out to the co-sensitizer. Examples of a method for the chemical modification include: bonding with the photo-thermal conversion agent, with the polymerizable compound or with some other part; introduction of a hydrophilic site; enhancement of compatibility; introduction of a substituent for suppressing crystal precipitation; introduction of a substituent for enhancing adhesiveness; and conversion into a polymer.

The co-sensitizer may be used singly, or in combination of two or more species thereof. The content of the co-sensitizer in the resin composition for laser engraving is preferably 0.05 parts by mass to 100 parts by mass, more preferably 1 parts by mass to 80 parts by mass, and even more preferably 3 parts by mass to 50 parts by mass, relative to 100 parts by mass of the polymerizable compound.

Polymerization Inhibitor

A small amount of thermal polymerization inhibitor can be preferably added to the resin composition of the invention in view of inhibiting unnecessary thermal polymerization of the polymerizable compound during the production or storage of the resin composition. Suitable examples of the thermal polymerization inhibitor include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), N-nitrosophenylhydroxylamine cerium (I) salt, and the like.

Q-1301 (trade name, manufactured by Wako Pure Chemical Industries, Ltd., a 10% tricresyl phosphate solution) can be preferably used as the polymerization inhibitor from the viewpoint of excellent stability in storage of the relief printing plate precursor for laser engraving having the relief forming layer containing the resin composition for laser engraving of the invention. When Q-1301 is used in combination with the polymerizable compound, the storage stability of the relief printing plate precursor for laser engraving can be significantly excellent, and good laser engraving sensitivity may be obtained. The addition amount of the thermal polymerization inhibitor is preferably 0.01% by mass to 5% by mass with respect to the total mass of the resin composition for laser engraving. Also, if necessary, in order to prevent the inhibition of polymerization caused by oxygen, a higher fatty acid compound such as behenic acid or behenic acid amide may be added to the resin composition and can be localized at the surface of the relief forming layer during the course of drying of the relief forming layer performed after the resin composition is applied over (on or above) a support or the like. The addition amount of the higher fatty acid compound can be preferably 0.5% by mass to 10% by mass with respect to the total mass of the resin composition.

Colorant

A colorant such as a dye or a pigment may also be added to the resin composition for laser engraving for the purpose of coloring the resin composition. The addition of the dye or the pigment may enhance properties of the resin composition such as the visibility of the image part, suitability for image density measuring device and the like. A pigment is particularly preferably used as the colorant in the invention. Specific examples of the colorant include pigments such as phthalocyanine pigments, azo pigments, carbon black or titanium oxide; and dyes such as Ethyl Violet, Crystal Violet, azo dyes, anthraquinone dyes or cyanine dyes. The amount of addition of the colorant is preferably about 0.5% by mass to 5% by mass with respect to the total mass of the resin composition.

Other Additives

In order to improve the properties of a cured film formed of the resin composition for laser engraving, known additives such as a filler may also be added.

Examples of the filler include carbon black, carbon nanotubes, fullerene, graphite, silica, alumina, aluminum, calcium carbonate and the like, and these fillers can be used individually or as mixtures of two or more thereof.

Relief Printing Plate Precursor for Laser Engraving

The relief printing plate precursor for laser engraving of the invention has a relief forming layer which contains the resin composition which contains components as described above. The relief forming layer is preferably provided over (on or above) a support.

The relief printing plate precursor for laser engraving may further have an arbitrary other layer, and examples of such an arbitrary other layer include an adhesive layer which resides between the support and the relief forming layer, and a slip coat layer and/or a protective layer which can be provided on the relief forming layer.

Relief Forming Layer

The relief forming layer is a layer formed of the resin composition for laser engraving of the invention. The relief forming layer can be obtained as a crosslinkable one by employing a crosslinkable resin composition as the resin composition for laser engraving. The relief printing plate precursor for laser engraving of the invention is preferably that having a crosslinkable relief forming layer.

In embodiments, a manufacturing method of a relief printing plate from the relief printing plate precursor for laser engraving preferably includes: crosslinking components of the relief forming layer; and laser engraving the crosslinked relief forming layer to form a relief layer. The crosslinking may enable to suppress wearing of the relief forming layer subjected to printing and provide a relief printing plate having a sharp (well-defined) relief layer by laser engraving.

As described above, the content of the specific polymer (A) in the resin composition in the invention is preferably from 2% by mass to 95% by mass, more preferably from 5% by mass to 80% by mass, and particularly preferably from 10% by mass to 65% by mass with respect to the total solid content of the resin composition. When the properties of the relief forming layer is further taken into consideration, the sum of the content of the specific polymer (A) and that of the auxiliary binder polymer (B) in the relief forming layer is preferably from 30% by mass to 80% by mass, and more preferably from 40% by mass to 70% by mass, with respect to the total mass of the solid content of the relief forming layer. When the content of the sum of the contents thereof is set within this range, the printing plate precursor having thereof can be prevented from causing a cold flow, and effects of other components for improving other properties can be sufficiently obtained, and a sufficient print durability as a printing plate may be provided to the relief printing plate resulting therefrom.

The content of the polymerization initiator is preferably from 0.01% by mass to 10% by mass, and more preferably from 0.1% by mass to 3% by mass, with respect to the total mass of the solid content of the relief forming layer. When the content of the polymerization initiator is set to 0.01% by mass or more, the effect of the addition of the polymerization initiator can be sufficiently obtained to rapidly progress the crosslinking process of the crosslinkable relief forming layer. When the content of the polymerization initiator is set to 10% by mass or less, there can be no occurrence of the lack of other components, and a sufficient print durability as a printing plate may be provided to the relief printing plate resulting therefrom.

The content of the polymerizable compound is preferably from 10% by mass to 60% by mass, and more preferably from 15% by mass to 40% by mass, with respect to the total mass of the solid content of the relief forming layer. When the content of the polymerizable compound is set to 10% by mass or more, the effect of the addition of the polymerization initiator can be sufficiently obtained to provide a sufficient print durability as a printing plate to the relief printing plate resulting therefrom. When the content of the polymerizable compound is set to 60% by mass or less, a sufficient strength as a printing plate may be provided to the relief printing plate resulting therefrom.

The relief forming layer may be obtained by providing the resin composition for forming the relief forming layer to have a sheet shape or a sleeve shape. The relief forming layer is usually provided over (on or above) a surface of a support. Alternatively, the relief forming layer can be directly provided onto a surface of a device such as a cylinder integrated in an apparatus for printing, or can be shaped and then fixed onto a surface of such a device.

Explanation is hereinafter given with respect to an embodiment in which the relief forming layer is formed into a sheet shape.

Support

The support which can be used in the relief printing plate precursor for laser engraving typically has a flat plate shape or a sheet shape. The material used in the support is not particularly limited, while a material having high dimensional stability is preferably used. Examples thereof include metals such as steel, stainless steel or aluminum; thermo-plastic resins such as polyesters (for example, PET, PBT and PAN) or polyvinyl chloride; thermo-setting resins such as epoxy resin or phenolic resin; synthetic rubbers such as styrene-butadiene rubber; and fiber reinformced plastic (FRP) resins formed of resin materials such as epoxy resin or phenolic resin containing reinforcing fibers such as a glass fiber, a carbon fiber or the like. Among these, a polyethylene terephthalate (PET) film and a steel substrate is preferable in view of strength, durability and availability. The shape of the support depends on whether the relief forming layer is a sheet-shaped or a sleeve-shaped. Details of the support in embodiments in which the relief forming layer is sleeve-shaped are explained below.

Adhesive Layer

The relief printing plate precursor according to the invention may have an adhesive layer disposed between the relief forming layer and the support in view of reinforcing adhesive force working between these layers.

Any material that may enhance the adhesive force after the crosslinking in the relief forming layer can be employed, and a material which can also enhance the adhesive force before the crosslinking in the relief forming layer can be preferably employed. The “adhesive force” herein include both of that working between the support and the adhesive layer and that working between the adhesive layer and the relief forming layer.

The adhesive force between the support and the adhesive layer is preferably as follows. Namely, when a combination of the adhesive layer and the relief forming layer are going to peeled off, at a rate of 400 mm/min, from the support provided in a laminate having the support, the adhesive layer and the relief forming layer provided in this order, the peeling force per a unit width of 1 cm of the sample is preferably 1.0 N/cm or larger or the combination is unpeelable from the support under this condition, and is more preferably 3.0 N/cm or larger or the combination is unpeelable from the support under this condition.

The adhesive force between the adhesive layer and the relief forming layer is preferably as follows. Namely, when the adhesive layer is peeled off, at a rate of 400 mm/min, from the relief forming layer provided in a laminate of the adhesive layer and the relief forming layer, the peeling force per a unit width of 1 cm of the sample is preferably 1.0 N/cm or larger or the adhesive layer is unpeelable from the relief forming layer under this condition, and is more preferably 3.0 N/cm or larger or the adhesive layer is unpeelable from the relief forming layer under this condition.

Examples of the material which configures the adhesive layer include materials mentioned in Handbook of Adhesives, Second Edition (1977) edited by I. Skiest.

In view of handling property of the relief printing plate (such as easiness in attaching to devices), thickness of the adhesive layer is preferably in a range of about 0.01 μm to about 500 μm, and more preferably in a range of 0.05 μm to 300 μm.

When an adhesive layer is disposed in the precursor of the invention, the adhesive layer is typically provided by a method including applying a composition for the adhesive layer on a surface of the support followed by drying.

Protective Film and Slip Coat Layer

The relief forming layer becomes the part at which a relief is formed after the laser engraving. The surface of the convex portion of the relief may generally function as an ink deposition portion. There is almost no concern for generation of damages or depressions on the surface of the relief forming layer which might affect printing when the relief forming layer is cured by crosslinking, since the thus-crosslinked relief forming layer has strength and hardness. However, the crosslink-curable relief forming layer which is not subjected to the crosslinking tend to have soft surfaces and are concerned for generation of damages or depressions on the surface thereof when they are handled. From the viewpoint of prevention of the damages or depressions, a protective film may be provided over (on or above) the relief forming layer.

If the protective film is too thin, the effect of preventing damages and depressions may not be obtained, and if the protective film is too thick, inconvenience may arise upon the handling thereof and production costs therefor may become higher. In consideration of these, the thickness of the protective film is preferably 25 μm to 500 μm, and more preferably 50 μm to 200 μm.

Films formed of known materials as that for a protective film of a printing plate, for example can be used in the invention, and examples thereof include polyester films such as those of PET (polyethylene terephthalate), and polyolefin films such as those of PE (polyethylene) or PP (polypropylene). The surface of the film may be plain (smooth), or may also be mattified to have very minute irregularities.

The protective film is required to be capable of being easily removed from the surface of the relief forming layer if desired as well as be capable of stably adhered to the surface of the relief forming layer before being removed, since the protective film is peeled off from the surface of the relief forming layer when the laser engraving is performed.

When the protective film is unpeelable or when the protective film cannot be easily adhered to the relief forming layer, a slip coat layer can be provided on a surface of the protective film to which the relief forming layer contacts.

The material for forming the slip coat layer preferably contains, as the main component, a water-soluble or water-dispersible and less tacky resin such as polyvinyl alcohol, polyvinyl acetate, a partially saponified polyvinyl alcohol, a hydroxyalkylcellulose, an alkylcellulose or a polyamide resin. Among these, a partially saponified polyvinyl alcohol having a degree of saponification of 60% by mole to 99% by mole, a hydroxyalkylcellulose with an alkyl group having 1 to 5 carbon atoms and an alkylcellulose with an alkyl group having 1 to 5 carbon atoms can be particularly preferably used from the viewpoint of lesser tackiness.

In the case where the protective film is peeled off, at a rate of 200 mm/min, from a laminate of the relief forming layer (and the slip coat layer) and the protective film, the peeling force per a unit width of 1 cm of the sample is preferably 5 mN/cm to 200 mN/cm, and more preferably 10 mN/cm to 150 mN/cm. When the peeling force is 5 mN/cm or more, the relief printing plate precursor can be subjected to operation without the removal of the protective film in the middle of the operation, and when the peeling force is 200 mN/cm or less, the protective film may be removed comfortably.

Method for Manufacturing Relief Printing Plate Precursor for Laser Engraving

There is no particular limitation to the preparation of a relief forming layer of a relief printing plate precursor for laser engraving according to the invention. Examples of the method for preparing the relief forming layer include: a method including removing the solvent from the application solution composition for forming a relief forming layer prepared as described above and fusion extruding the composition to on or above a support or a plate cylinder. Alternatively, when the relief forming layer is formed over a support, a method including flowing the application solution composition for forming a relief forming layer over a support and drying the resultant in an oven to remove the solvent from the composition can be employed.

The protective film may be laminated over the surface of the thus-formed relief forming layer in accordance with necessity. When the protective film is provided over the relief forming layer, the protective film and the relief forming layer are typically layered followed by laminating. Examples of a method for the lamination includes: a method in which a body in which the protective film and the relief forming are layered is passed through a space, which resides between a pair of calendar rolls, at least one of which is heated during the passage, so that the protective film and the relief forming layer can be press-contacted with heat to be laminated (attached with each other); and a method in which a surface of the relief forming layer, in which a small amount of solvent is impregnated, is prepared and the relief forming layer is tightly attached to the protective film via the surface so that the protective film and the relief forming layer can be laminated.

In relation thereto, examples of the method for the preparation of the relief forming layer further include a method which includes firstly laminating a relief forming layer on a protective film, and then laminating a support and the relief forming layer. Herein, an adhesive layer can be provided by using a support having the adhesive layer, and a slip coat layer can be provided by using a protective film having the slip coat layer.

An application solution composition for forming a relief forming layer may be prepared, for example, by dissolving or dispersing the specific polymer (A), the optional photo-thermal conversion agent and/or the optional plasticizer to an appropriate solvent, and further dissolving the polymerization initiator and the polymerizable compound to the resulted solution.

It is necessary that most of the solvent component used for preparing the application solution is removed during the preparation of the printing plate precursor. Therefore, it is preferable that a lower alcohol which has a low-boiling solvent such as ethanol is used and that the addition amount of the solvent is small. It is possible to suppress the amount of the solvent added to the application solution by warming the system to form the application solution. However, when the temperature resulted by the warming is too high, polymerizable compound and/or the like in the system may tend to cause polymerization. In consideration of this, when the application solution composition for forming a relief forming layer has a formulation including a polymerizable compound and/or a polymerization initiator, the temperature for preparation of the composition is preferably adjusted to be within a range of 30° C. to 80° C.

A thickness of the relief forming layer of the relief printing plate precursor for laser engraving which is before and after being subjected to the crosslinking is preferably 0.05 mm to 10 mm, more preferably 0.05 mm to 7 mm and, particularly preferably, 0.05 mm to 0.3 mm.

Any known methods for molding a resin may be employed when the relief forming layer is formed in a sleeve shape. Examples thereof include: a casting method; a method including extruding a resin from a nozzle or a dice by a machine such as a pump or an extruder and adjusting a thickness of the resultant by use of a blade or by a calendar processing with rolls. During the molding, heat with a temperature, by which characteristics of a resin composition which configures the relief forming layer are not deteriorated, can be applied to the molding system. A rolling treatment, an abrading treatment, and/or the like may be further performed if necessary.

When the relief forming layer is made into a sleeve form, the relief forming layer may be formed by being molded into a cylindrical shape at the initial stage of the molding, or may be formed by being molded into a sheet shape at first and then made into a cylindrical shape by being fixed on a cylindrical support or a plate cylinder. There is no particular limitation for the fixing of the sheet shaped-support to the cylindrical support, and examples thereof include: fixing the sheet shaped-support to the cylindrical support by using an adhesive tape having an adhesive layer, a tackifying layer, or the like provided on each of both sides; and fixing the sheet shaped-support to the cylindrical support via a layer containing an adhesive agent.

Examples of the adhesive tape include: a tape having a tackifying agent layer or an adhesive agent layer formed of an acrylic resin, a methacrylic resin, a styrene thermoplastic elastomer or the like formed on both sides of a film base material such as a polyester film or a polyolefin film; and a tape which has a base material formed of a foamed body of a polyolefin resin such as polyethylene or a polyurethane resin and provided with a tackifying agent layer or an adhesive agent layer as described above on both of sides thereof and has a cushioning property. A commercially available tape with adhesive on both sides or a cushion tape having tackifying agent layers on both sides may be appropriately used as well.

The adhesive agent layer used in the case that a cylindrical support and the relief forming layer are fixed via the adhesive agent layer can be formed using any known adhesive agents. Examples of an adhesive agent which can be used for the fixing of the relief forming layer to the cylindrical support include a rubber adhesive agent such as a styrene butadiene rubber (SBR), a chloroprene rubber or a nitrile rubber, and an adhesive agent which is hardened by moisture in air such as a silicone resin or a polyurethane resin having silyl group.

When the relief forming layer is made into a cylindrical shape, the relief forming layer may be formed by being molded into a cylindrical shape by a known method at first and then fixed on a cylindrical support, or may be formed by directly molded into a cylindrical shape by extrusion molding or the like so as to be a sleeve shape. The former method is preferably used in view of the productivity. When the relief forming layer is made into a sleeve shape, the thus-formed sleeve-shaped relief forming layer may still be subjected to crosslinking and hardened after being fixed onto a cylindrical support if necessary, and a rolling treatment, an abrading treatment or the like can be further carried out if desired.

Examples of the cylindrical support used in making the relief forming layer into a sleeve shape include: a metal sleeve formed of a metal such as nickel, stainless steel, iron or aluminum; a plastic sleeve formed by molding a resin; a sleeve formed of a fiber reinforced plastics (FRP sleeve) having a glass fiber, a carbon fiber, an aramid fiber or the like as a reinforcing fiber fiber-reinforced plastic; and a sleeve formed of a polymer film and having a shape maintained by compressed air.

The thickness of the cylindrical support may be arbitrarily selected depending upon the object, and the thickness can be typically sufficient as long as it is 0.1 mm or more and as long as the cylindrical support is not destructed by a pressure applied thereto when it is subjected to printing. In the case that the cylindrical support is a metal sleeve or a hard plastic sleeve, those having a thickness of 5 mm or more may be used as well, and it is also possible to use a cylindrical support having a solid body penetrated by a rotation axis (namely, a cylindrical support which is fixed to a rotating axis).

In view of an effective fixation of a shrinkable relief forming layer to the cylindrical support, the cylindrical support preferably has such characteristics that an inner diameter of the cylindrical support can expand by a air compressed to have pressure of about 6 bars and that it returns to have its initial inner diameter after the compressed air is released. A support having such a structure (namely, a structure with a diameter which can be easily adjusted by compressed air or the like) is preferable since a stress can be applied to the relief forming layer having a sleeve shape from inside thereof, a tightly rolling characteristic of the relief forming layer can work and, the relief layer can be stably fixed on a cylindrical plate or a plate cylinder even when a stress is applied thereto when it is subjected to printing.

Method of Manufacturing Relief Printing Plate

The method of manufacturing a relief printing plate according to the invention preferably has at least (1) crosslinking at least a portion of components of the relief forming layer of the relief printing plate precursor for laser engraving of the invention by applying light (by means such as exposure to actinic ray) and/or heat and (2) laser engraving the relief forming layer that has been subjected to the crosslinking to form a relief layer. The method can provide the relief printing plate according to the invention having a relief layer over a support. A relief printing plate having the relief forming layer can be formed by such a method using the relief printing plate precursor according to the invention. When the relief printing plate precursor has a support, the relief forming layer is formed over the support, and the resulted combination thereof is applied to an apparatus for printing.

Further, a process of (3) rinsing, in which the surface of a relief layer after engraving is rinsed, a process of (4) drying, in which the relief layer which has been engraved is dried, and/or a process of (5) post-crosslinking, in which energy is applied to the relief layer which has been engraved to form a crosslinking structure, can be carried out after the process of (2) laser engraving if necessary.

Cross linking in the relief forming layer during the process (1) is carried out by irradiation of actinic rays and/or heat.

In the crosslinking of the relief forming layer during the process (1), in a case that both of crosslinking using light crosslinking using heat are used in combination in the process (1) of crosslinking, these processes may be performed simultaneously or separately.

The process (1) is a process to crosslinking crosslinkable components of the relief forming layer of the relief printing plate precursor for laser engraving by light and/or heat.

The relief forming layer contains the specific polymer (A), and preferably further contains the optional auxiliary binder polymer (B), a photo-thermal conversion agent, a polymerization initiator, and a polymerizable compound. The process (1) preferably includes polymerizing polymerizable compounds to form crosslinking by the effect of the polymerization initiator so that the relief forming layer is made into a hardemed (cured) relief forming layer.

The polymerization initiator is preferably a radical generator. Radical generators are roughly classified into photopolymerization initiators and thermal polymerization initiators, depending on whether the trigger of the respective generating radical is light or heat.

When the relief forming layer contains a photopolymerization initiator, a crosslinked structure can be formed in the relief forming layer by irradiating the relief forming layer with actinic ray which serves as the trigger of the photopolymerization initiator (crosslinking by light).

The irradiation of actinic ray is generally carried out over the entire surface of the relief forming layer. Examples of the actinic ray include visible light, ultraviolet radiation and an electron beam, but ultraviolet radiation is most generally used. While it is acceptable to perform the irradiation of the actinic ray only to a front surface of a support, which is the opposite side of a rear surface of the relief forming layer which faces a base material such as the support to which the relied forming layer is provided, it is preferable to irradiate the actinic ray also from the rear surface as well as from the front surface when the support is a transparent film which transmits actinic ray. When the protective film is present, the irradiation from the front surface may be carried out with the protective film being provided, or may be carried out after the protective film has been removed. Considering the presence of oxygen which may cause a polymerization inhibition, the irradiation with actinic ray may be carried out after coating the crosslinkable relief forming layer with a vinyl chloride sheet under vacuum.

When the relief forming layer contains a thermal polymerization initiator, a crosslinked structure can be formed in the relief forming layer by heating the relief printing plate precursor for laser engraving (crosslinking by heat). Herein, the photopolymerization initiator may be a thermal polymerization initiator in some cases. Examples of the method of heating include a method of heating the printing plate precursor in a hot air oven or a far-infrared oven for a predetermined time and a method of contacting the printing plate precursor with a heated roll for a predetermined time.

The crosslinking by light in the process (1) may require a device for irradiation of active ray which is relatively expensive, it is preferable in that there is almost no limitation to the material to form the relief printing plate precursor, because the temperature of the relief printing plate precursor may not be greatly affected by the irradiation of active ray.

On the other hand, temperature of the printing plate precursor may rise in the crosslinking by heating, which may result in deformation of a thermoplastic polymer and/or denaturation of compound having small stability against heat. Accordingly, cares may be necessarily taken to select a compound used in the relief forming layer.

A thermal polymerization initiator can be added upon the crosslinking by heat. Commercially-available thermal polymerization initiator for free radical polymerization can be used as the thermal polymerization initiator. Examples of the thermal polymerization initiator include an appropriate peroxide, a hydroperoxide, and a compound containing an azo group. Typical vulcanizers can also be used for crosslinking. Crosslinking by heat can be also carried out by adding, as a crosslinking ingredient, a thermally crosslinkable resin (heat-curable resin) such as an epoxy resin to the relief forming layer.

The crosslinking by heat can be preferable as a crosslinking method for the relief forming layer in the process (1) with a viewpoint that the relief forming layer can be uniformly cured (crosslinked) from the surface to the inside.

The crosslinking in the relief forming layer has a first advantage that a relief formed after the laser engraving can become sharp as well as a second advantage that stickiness of engraving wastes formed upon laser engraving can be suppressed. When a relief forming layer which is not subjected to crosslinking is laser-engraved, a portion which is not intended to be engraved tends to be melted or deformed by remaining heat prevailing to the periphery of a portion irradiated with the laser to prevent obtaining a sharp relief layer in some cases. Further, In general, the lower a molecular weight of a material, the more the material tends to be liquid rather than solid to increase the stickiness of the material. Stickiness of engraving wastes formed upon engraving the relief forming layer tends to increase as the amount of using the low molecular weight material increases. Since the polymerizable compound, which is a low molecular material, can be formed into a high molecular weight material by crosslinking, the stickiness of the engraving wastes to be formed from the crosslinked relief forming layer tends to be decreased.

In the process (2) of engraving, the relief forming layer subjected to the crosslinking is engraved with laser to form a relief layer. The process (2) is preferably performed by irradiating the relief forming layer with laser light which corresponds to a desired image to be formed with employing a specific laser described below so that a relief layer to be used for printing can be formed thereby.

More specifically, a relief layer is formed in the process (2) by irradiating the relief forming layer with a laser light and corresponding to a desired image to be formed. The engraving preferably includes controlling the laser head with a computer based on the digital data of a desired image to be formed, and performing scanning irradiation over the relief forming layer. When an infrared laser is irradiated, molecules in the relief forming layer undergo molecular vibration, and thus heat is generated. When a high power laser such as a carbon dioxide laser or a YAG laser is used as the infrared laser, a large amount of heat is generated at the laser-irradiated areas, and the molecules in the photosensitive layer undergo molecular breakage or ionization, so that selective removal (that is, engraving) can be achieved. In a case that a photo-thermal conversion agent is contained in the relief forming layer, heat is generated in the irradiated portion. The heat generated by the photo-thermal conversion agent can also enhance the selective removal.

An advantage of the laser engraving is the ability to three-dimensionally control the structure of the engraved portion since the depth of engraving can be arbitrarily set thereby, For example, when areas for printing fine dots are engraved shallowly or with a shoulder, the relief may be prevented from collapsing under printing pressure. When groove areas for printing cutout characters are engraved deeply, the grooves may be hardly filled with ink, and collapse of the cutout characters may be thus suppressed.

When the engraving is performed with an infrared laser which corresponds to the maximum absorption wavelength of the photo-thermal conversion agent, a more sensitive and well-defined (sharp) relief layer can be obtained.

In view of improving productivity and reducing costs, a CO₂ laser or a semiconductor laser can be preferably used, and among these, a fiber-coupled semiconductor laser recording device described below can be particularly preferably used for the laser engraving.

Plate Making Device Equipped with Semiconductor Laser

In general, a semiconductor laser exhibits high efficiency in laser oscillation, is less expensive and can be made smaller as compared with CO₂ lasers. Moreover, due to its small size, a semiconductor laser can be easily provided in an array. Control of its beam diameter can be done by an imaging lens or a specific optical fiber. A fiber-coupled semiconductor laser can be effective for the image formation of the invention since it can efficiently output laser beam by an optical fiber installed therein. A shape of the laser beam can be controlled by processing the optical fiber. For example, a beam profile of the laser beam can be made into a top-hat shape so as to stably apply energy to a plate surface. Details of the semiconductor laser are described, for example, in “Laser Handbook”, Second Edition, edited by Laser Society and “Practical Laser Technique”, Electronic Communication Society.

While any semiconductor laser can be used as ling as it emits light having a wavelength which is in the range of 700 nm to 1300 nm, it is preferably those emitting light having a wavelength which is in the range of 800 nm to 1200 nm, more preferably those emitting light having a wavelength which is in the range of 860 nm to 1200 nm, and further preferably those emitting light having a wavelength which is in the range of 900 nm to 1100 nm.

Since the band gap of GaAs resides at 860 nm at room temperature, semiconductor lasers having a AlGsAs active layer is generally used when light having a wavelength of 860 nm or less is employed. On the other hand, semiconductor lasers having a InGaAs active layer is generally used when light having a wavelength of 860 nm or more is employed. Employment of a wavelength which is in the range of 860 nm to 1200 nm is preferable since the semiconductor lasers having a InGaAs active layer is reliable relative to those having a AlGsAs active layer, the aluminum used therein being generally easily oxidized.

In consideration of configuration of cladding material and the like in addition to the active layer material, the more preferable embodiment of practically-usable semiconductor lasers having a InGaAs active layer include those emitting light having a wavelength which is in the range of 900 nm to 1100 nm, which would provide higher output and higher reliability. Accordingly, the low cost and high productivity can be more easily obtained by the invention when a semiconductor lasers having a InGaAs active layer and emitting light having a wavelength which is in the range of 900 nm to 1100 nm is employed.

The use of the fiber-coupled semiconductor laser with a specific wavelength as defined in the invention may provide a laser engraving flexo printing system which provides excellent image quality with low cost and high productivity.

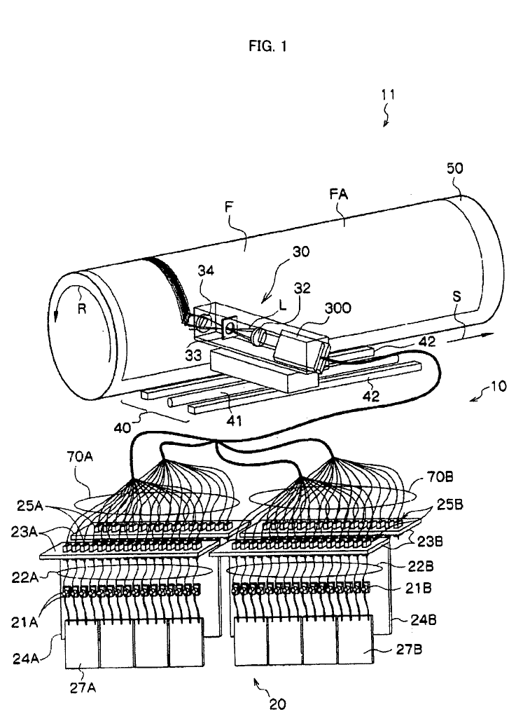

An embodiment of the plate making device equipped with a fiber-coupled semiconductor laser recording device which can be used in the method of making a printing plate of the invention will be illustrated hereinafter with respect its configuration by referring to FIG. 1.

A plate making device 11 which can be used in the method of the invention is equipped with: a fiber-coupled semiconductor laser recording device 10; and a plate making device 11 has a drum 50, which has an outer circumference surface, on which a printing plate precursor F (recording medium) of the invention can be attached. The laser recording device 10 has: a light source unit 20 which generates plural laser beams; a exposure head 30 which expose the relief printing plate precursor F to the plural laser beams generated by the light source unit 20; and a moving unit 40 of exposure head which moves the exposure head 30 in the auxiliary scanning direction.

The plate making device 11 drives the drum 50 to rotate in a main scanning direction (the direction indicated by an arrow R) and, at the same time, have an exposure head 30 to scan the drum 50 in an auxiliary scanning direction, which is at right angle to the main scanning direction and is indicated by an arrow S, while simultaneously emitting plural laser beams corresponding to image data to be engraved (recorded) from the exposure head 30 to the relief printing plate precursor F, so that a two-dimensional image can be engraved (recorded) on the relief printing plate precursor F at high speed. In the case where a narrow region is engraved (namely, when a precise engraving is performed for forming fine lines, fine dots or the like), the relief printing plate precursor F can be engraved shallowly. In the case where a broad region is engraved, the relief printing plate precursor F can be engraved deeply.

The light source unit 20 is equipped with: semiconductor lasers 21A and 21B, each of which has a broad area semiconductor laser to which an end of each of optical fibers 22A or 22B is indivisually coupled; light source supports 24A and 24B, each of which has the semiconductor laser 21A or 21B aligned on the surface thereof, adaptor supports 23A and 23B, each of which is vertically attached to an end of the light source support 24A or 24B and a plural (the same numbers as in the semiconductor lasers 21A, 21B) adaptors of SC-type light connectors 25A or 25B are installed thereon; and LD (laser diode) driver supports 27A and 27B, each of which is horizontally attached to another end of the light source support 24A or 24B and is installed with a LD driver circuit 26 (not shown in FIG. 1) which drives the semiconductor lasers 21A and 21B corresponding to the image data of the image to be engraved (recorded) on the relief printing plate precursor F.

The exposure head 30 is equipped with a fiber array unit 300 by which laser beams emitted from the plural semiconductor lasers 21A and 21B can be emitted together. Each of the laser beams emitted from the semiconductor laser 21A or 21B is conveyed to the fiber array unit 300 by one among plural optical fibers 70A and 70B, which are connected to the SC-type light connector 25A or 25B connected to the adaptor supports 23A or 23B.

As shown in FIG. 1, the exposure head 30 has a collimator lens 32, an opening material 33 and an imaging lens 34 which are aligned in this order with respect to a position in which the fiber array unit 300 is disposed. The opening material 33 is aligned such that its opening resides at the position of a far field when looked from the side of the fiber array unit 300. As a result, a similar degree of light quantity restricting effect can be provided to all laser beams emitted from terminals 71A or 71B of the optical fibers 70A or 70B at the fiber array unit 300.

Laser beam forms an image at a vicinity of the exposure side (surface) FA of the relief printing plate precursor F by an imaging unit having the collimator lens 32 and the imaging lens 34 in its configuration.

The fiber-coupled semiconductor laser can change a shape of the laser beam emitted therefrom. In view of efficient engraving and good reproducibility of fine lines, it is preferable in the invention to control a spot diameter the laser beam to be in a range of 10 μm to 80 μm on the exposed surface (surface of a relief forming layer) FA by, for example, controlling the shape of the laser beam to have the imaging position (image forming position) P be within an area of inner side with respect to the exposure surface FA (the side of forwarding direction of laser beam) or the like.

The exposure head moving unit 40 is equipped with two rails 42 and a ball screw 41 aligned in such a manner that their longitudinal direction are along the auxiliary scanning direction. A pedestal 310 equipped with the exposure head 30 can be moved in an auxiliary scanning direction with being guided by the rail 42 by operating an auxiliary scanning motor 43, which drives and rotates the ball screw 41. The drum 50 can be rotated in the direction of the arrow R when a main scanning motor (not shown) is operated, whereby the main scanning is performed.

It is also possible to control the shape of the engraved region by controlling the amount of energy applied to the surface of the relief forming layer by the laser beam without changing the shape of the laser beam from the fiber-coupled semiconductor laser.

Specific examples of the energy amount controlling-method include a method in which output power of the semiconductor laser is changed and a method in which a time length employed for the laser irradiation is changed.

If engraving remnants remain and adhere to the engraved surface, the process (3) of rinsing, in which the engraved surface is rinsed with water or with a liquid containing water as a main component to wash away the engraving remnants, may be further performed. Examples of the method of the rinsing include a method of spraying water at high pressure, or a method of brush rubbing the engraved surface, mainly in the presence of water, using a batch type- or conveyor type- brush washout machine known as a developing machine for photosensitive resin letterpress plates, and the like. If the viscous liquid of the engraving remnants cannot be removed by simply washing with the water or the liquid, a rinsing solution containing soap may be used.

When the process (3) of rinsing the engraved surface is performed, it is preferable to further perform the process (4) of drying, in which the relief layer which has been engraved is dried to volatilize the rinsing solution.

Further, the process (5) of post-crosslinking, in which a crosslinked structure is formed in the relief layer, can be carried out if necessity. By carrying out the process (5) of post-crosslinking, the relief formed by engraving may be further strengthened.

The relief printing plate according to one aspect of the invention, that has a relief layer over a support, can be thus obtained.

A thickness of the relief layer of the relief printing plate is preferably in a range of 0.05 mm to 10 mm, more preferably in a range of 0.05 mm to 7 mm, and particularly preferably in a range of 0.05 mm to 3 mm in view of satisfying various applicability to flexographic printing such as wearing resistance or ink transfer property.

The Shore A hardness of the relief forming layer subjected to the crosslinking is preferably from 50° to 90°.

When the Shore A hardness of the relief layer is 50° or more, the fine dots formed by engraving may not be fall and break even under the high printing pressure of a letterpress printing machine, and proper printing may be achieved. When the Shore A hardness of the relief layer is 90° or less, print scratches at solid parts may be prevented even in flexographic printing with a kiss-touch printing pressure.

The “Shore A hardness” herein means a value measured by a durometer (spring type rubber hardness meter), which impinges a presser (referred to as a penetration needle or an indenter) to a surface of an object to cause deformation of the surface, and measures the amount of the deformation (penetration depth) of the surface and expresses the result in a numerical value.

The relief printing plate produced by the method of the invention allows printing with a letterpress printing machine using any of an aqueous ink, oily ink or UV ink, and also allows printing with a flexographic printing machine using UV ink. The relief printing plate obtained from the relief printing plate precursor of the invention can be excellent in both of the suitability for an aqueous ink and the suitability for a UV ink. Accordingly, printing can be performed by employing the relief printing plate without concern for deterioration of strength or printing durability of the relief forming layer due to effects of such inks.

### EXAMPLES

The invention will be hereinafter described in more detail by way of Examples, while the invention is not limited thereto. The weight average molecular weight (Mw) of each of the following examples is that measured by gel permeation chromatography (GPC) unless otherwise stated.

### Example 1

1. Preparation of Crosslinkable Resin Composition for Laser Engraving

In a three necked flask equipped with a stirring blade and a cooling tube, 50 parts by mass of polyvinylbutyral (trade name: BL-1, manufactured by Sekisui Chemical Co., Ltd., Mw: 19,000) as the specific polymer (A), 1 part by mass of carbon black (trade name: KETJEN BLACK EC60OJD, manufactured by Lion Corporation) as the photo-thermal conversion agent (E), 20 parts by mass of diethylene glycol as the plasticizer, and 47 parts by mass of ethanol as the solvent were charged and heated while stirring at 70° C. for 120 min to dissolve the specific polymer (A). Further, the resultant was cooled 40° C., and added with 15 parts by mass of an ethylenically unsaturated monomer M-1 having a chemical structure shown below, 13 parts by mass of hydroxyethyl (meth)acrylate (trade name; BLEMMER PME200, manufactured by NOF Corp.), and 1 part by mass of t-butyloxybenzoate (trade name: PERBUTYL Z, manufactured by NOF Corp.) as the polymerization initiator (D) were added and stirred for 30 min to obtain a coating solution 1 for forming a crosslinkable relief forming layer (crosslinkable resin composition for laser engraving) having fluidity.

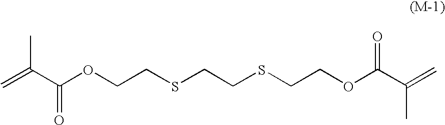

2. Preparation of Relief Printing Plate Precursor for Laser Engraving

A spacer of a predetermined thickness was placed on a PET substrate to form a frame, and the coating solution 1 for the crosslinkable relief forming layer was quietly cast into the frame to such an extent as not flowing out of the spacer and dried in an oven at 40° C. for 3 hrs to dispose a relief forming layer of about 1 mm thickness, so that a relief printing plate precursor 1 for laser engraving was manufactured.

3. Production of Relief Printing Plate

The relief forming layer of the thus-obtained relief printing plate precursor 1 was heated at 120° C. for 2.5 hrs to subject the relief forming layer to crosslinking by heat.

Further, the relief forming layer subjected to the crosslinking was further subjected to laser engraving by any one of the following three methods to form a relief layer. A relief printing plate of Example 1 was thus obtained.

In a first laser engraving method, high-quality CO₂ laser marker ML-9100 series (trade name, manufactured by Keyence, wavelength: 10.6 μm) was used as a CO₂ gas laser engraving device for engraving by laser irradiation. After a protective film was released from the printing plate precursor 1 for printing plate for laser engraving, a solid image of 1 cm-square was subjected to a raster engraving using the CO₂ gas laser engraving device under the condition in which output power was 12 W, head speed was 200 mm/second and pitch setting was 2,400 DPI. The samples subjected to the first laser engraving method are shown as “CO₂ laser” in the columns of the light source in the following Tables together with results of evaluations thereof.

In a second laser engraving method, a laser recording device as shown in FIG. 1 equipped with a fiber-coupled semiconductor laser diode (FC-LD) having the maximum output power of 8.0 W (trade name: SDL-6390, manufactured by JDSU; wavelength: 915 nm) was used. A solid image of 1 cm-square was subjected to a raster engraving using a semiconductor laser engraving device under the condition where laser output power was 6 W, head speed was 100 mm/second and pitch setting was 2,400 DPI. The samples subjected to the second laser engraving method are shown as “FC-LD” in the columns of the light source in the following Tables together with results of evaluations thereof.

In a third laser engraving method, a semiconductor laser engraving device “FD-100” which was prepared by employing SCT 200-808-Z6-01 (trade name, manufactured by ProLiteR, wavelength: 808 nm)”, which has no fiber, in place of the FC-LD in the second laser engraving method. The device (light source) is indicated as “LD” in Tables 4 and 5. A solid image of 1 cm-square was subjected to a raster engraving using the semiconductor laser engraving device under the condition where laser output power was 6 W, head speed was 100 mm/second and pitch setting was 2,400 DPI. The samples subjected to the third laser engraving method are shown as “FD-100” in the columns of the light source in the following Tables together with results of evaluations thereof.

The thickness of the relief forming layer present in the relief printing plate precursor was about 1 mm.

The Shore A hardness of the relief layer measured by the method described above was 75°. The measurement for the Shore A hardness was also carried out in the same manner in each of the following examples and comparative examples.

### Examples 2 to 17 and Comparative Examples 1 to 8

1. Preparation of Crosslinkable Resin Composition for Laser Engraving

Coating solutions for forming a crosslinkable relief forming layer (crosslinkable resin composition for laser engraving) for Examples 2 to 17 and Comparative examples 1 to 8 were respectively prepared in the same manner as Example 1, except that specific polymers 2 to 14 and comparative polymers C-1 to C-6 were respectively used in place of the BL-1 (described above), which is the specific polymer (A), as shown in the following Tables 4 and 5, and the polymerizable compound (C), the polymerization initiator (D) and the photo-thermal conversion agent (E) were respectively changed as shown in the following Tables 4 and 5.

Details of the specific polymers (A) and comparative binder polymers used in the Examples and Comparative Examples are as follows.

Specific polymer 2: polyvinyl butyral (Mw: 66000) (trade name: BH-S, manufactured by Sekisui Chemical Co., Ltd.)

Specific polymer 3: polyvinyl butyral (Mw: 90000) (trade name: #3000-2, manufactured by Denki Kagaku Kogyo Kabushiki Kaisha)

Specific polymer 4: polyvinyl butyral (Mw: 308000) (trade name: #6000-C, manufactured by Denki Kagaku Kogyo Kabushiki Kaisha)

Specific polymer 5: methoxymethylated polyamide (trade name: TORESIN F-30K, manufactured by Nagase ChemteX Corporation)

Specific polymer 6: methoxymethylated polyamide (trade name: TORESIN EF-30T, manufactured by Nagase ChemteX Corporation)

Specific polymer 7: cellulose compound (trade name: ETHYL CELLULOSE 45, manufactured by Wako Pure Chemical Industries, Ltd.)

Specific polymer 8: modified epoxy resin (trade name: ARAKYD 9201N, manufactured by Arakawa Kagaku Industries, Ltd.)

Specific polymer 9: modified epoxy resin (trade name: ARAKYD 9203N, manufactured by Arakawa Kagaku Industries, Ltd.)

Specific polymer 10: modified epoxy resin (trade name: ARAKYD 9203N, manufactured by Arakawa Kagaku Industries, Ltd.)

Specific polymer 11: 20/80 (molar ratio) copolymer of BLEMMER PME200/methyl methacrylate (acrylic resin having a hydrophilic group in a side chain thereof, Mw: 32000)

Specific polymer 12: 10/90 (molar ratio) copolymer of BLEMMER PME 100/methyl methacrylate (acrylic resin having a hydrophilic group in a side chain thereof, Mw: 32000)

Specific polymer 13: 45/55 (molar ratio) copolymer of styrene/2-hydroxyethyl methacrylate (acrylic resin having a hydrophilic group in a side chain thereof, Mw: 56000)

Specific polymer 14: 20/50/30 (molar ratio) copolymer of styrene/2-hydroxyethyl methacrylate/n-butyl methacrylate (acrylic resin having a hydrophilic group in a side chain thereof, Mw: 56000)

Comparative polymer C-1: styrene-isoprene-styrene block copolymer (trade name: KRATON 1107, manufactured by Shell Chemical Co., Houston. Tex.)

Comparative polymer C-2: polyurethane elastomer (trade name: N2304, manufactured by Nippon Polyurethane Industry Co., Ltd.)

Comparative polymer C-3: ethylene-propylene-nonconjugated diene rubber (trade name: JSR manufactured by JSR Corporation, ethylene content: 61% by weight)

Comparative polymer C-4: polymer (Mw: 10000) prepared by blocking the terminals of a 1/1 (molar ratio) polyaddition product of polycarbonate diol (trade name: PCDL L4672, Mn: 1990, manufactured by Asahi Kasei Chemicals Corporation)/tolylenediisocyanate with 2-methacryloyloxy ethyl isocyanate

Comparative polymer C-5: silicone rubber (trade name: ELASTOSIL® R300/30S, manufactured by Wacker)

Comparative polymer C-6: water-soluble PVA compound (trade name: GOHSENAL T-215, manufactured by Nippon Synthetic Chemical Industry Co., Ltd.)

Details about the polymerizable compounda (C), the polymerization initiators (D), and the photo-thermal conversion agents (E) used in the Examples and Comparative examples and listed in Tables 4 and 5 are as follows.

### (C) Polymerizable Compound

M-1: ethylenically unsaturated monomer (structure shown above)

M-2: glycerol 1,3-dimethacrylate (manufactured by Tokyo Chemical Industry Co., Ltd.)

### (D) Polymerization Initiator

PERBUTYL®Z (manufactured by NOF Corporation, organic peroxide)

V-601 (trade name, manufactured by Wako Pure Chemical Industries, Ltd., dimethyl 2,2′-azobisisobutyrate)

### (E) Photo-Thermal Conversion Agent

Carbon black (trade name: KETJEN BLACK EC600JD, manufactured by Lion Corp.)

ADS-820HO (trade name, manufactured by American Dye Source, Inc.)

2. Preparation of Relief Printing Plate Precursor for Laser Engraving

Relief printing plate precursors for laser engraving for Examples 2 to 17 and Comparative examples 1 to 8 were prepared in the same manner as the relief printing plate precursor of Example 1, except that the coating solutions for forming a crosslinkable relief forming layer for Examples 2 to 17 and Comparative examples 1 to 8 were respectively used in place of the coating solution for forming a crosslinkable relief forming layer for Example 1.

3. Production of Relief Printing Plate

The relief printing plate precursors for Examples 2 to 17 and Comparative examples 1 to 8 were respectively subjected to thermal crosslinking and laser engraving in the same manner as Example 1 so as to provide relief printing plates of Examples 2 to 17 and Comparative examples 1 to 8. The thickness of each of the relief forming layers present in the relief printing plate precursors was about 1 mm.

4. Evaluations of Properties of Binder Polymer Used for Preparing Relief Forming Layer

The specific polymers (A) 1 to 14 used in Examples and comparative binder polymers C-1 to C-6 used in Comparative Examples were evaluated for their properties. The results are listed in Tables 1 to 3. Whether these binder polymers are non-elastomers having a glass transition temperature not lower than room temperature (20° C.) or elastomers having a glass transition temperature lower than room temperature (20° C.) are also shown in Tables 1 to 3.

(4-1) Water Swelling Property

A film having a thickness of 1 mm was formed using each of the sample binder polymer. 5 g of the film was taken as a test sample, and the test sample was immersed in water at 25° C. for 24 hours at room temperature. Thereafter, the test sample was taken out, and weighed after drying at 100° C. for 5 hours.

The ratio of the sample weight measured after the immersion to that measured before the immersion was calculated with setting the sample weight measured before the immersion as 100%. The larger the value is, the more elution of the relief forming layer into water caused by swelling was prevented, indicating its excellence in the resistance to water.

(4-2) Alcohol Solubility

### (4-2-1) Methanol Solubility (Solubility in Alcohol Having One Carbon Atom)

0.1 g of a powdery binder polymer was mixed with 2 ml of methanol, allowed to stand in a container with a cap thereon at room temperature for 24 hours. Thereafter, the solution was visually observed and graded according to the following criteria.

A (soluble): The solution (dispersion) contains no precipitate of the binder polymer, and is transparent and uniform.

X (insoluble): The solution (dispersion) contains precipitates of the binder polymer, or is cloudy.

### (4-2-2) Ethanol Solubility (Solubility in Alcohol Having Two Carbon Atoms)

Ethanol solubility was evaluated in the same manner as in the evaluation of methanol solubility, except that ethanol was used in place of methanol.

(4-2-3) 1-methoxy-2-propanol Solubility (Solubility in Alcohol Having Four Carbon Atoms)

1-methoxy-2-propanol solubility solubility was evaluated in the same manner as in the evaluation of methanol solubility, except that 1-methoxy-2-propanol was used in place of methanol.

(4-3) Ethyl Acetate Swelling Property

A film having a thickness of 1 mm was formed using each of the sample binder polymer. 5 g of the film was taken as a test sample, and the test sample was immersed in ethyl acetate at 25° C. for 24 hours at room temperature. Thereafter, the sample was taken out, and weighed after drying at 80° C. for 3 hours.

The ratio of the sample weight measured after the immersion to that measured before the immersion was calculated with setting the sample weight measured before the immersion as 100%. The larger the value is, the more elution of the relief forming layer caused by swelling of the relief forming layer with ethyl acetate was prevented, indicating its excellence in the resistance to solvent.

TABLE 1

| | | | Weight | | | | |
|---|---|---|---|---|---|---|---|
| | (A) Specific polymer | Glass | after water | | | | Weight after |
| | or comparative binder | transition | immersion | Methanol | Ethanol | 1-methoxy-2- | ethyl acetate |
| | polymer | temperature | (%) | solubility | solubility | propanol solubility | immersion (%) |
| Specific | BL-1 | 20° C. or higher | 95 | A | A | A | 95 |
| polymer 1 | | | | | | | |
| Specific | BH-S | 20° C. or higher | 96 | A | A | A | 95 |
| polymer 2 | | | | | | | |
| Specific | #3000-1 | 20° C. or higher | 97 | A | A | A | 95 |
| polymer 3 | | | | | | | |
| Specific | #6000-C | 20° C. or higher | 95 | A | A | A | 97 |
| polymer 4 | | | | | | | |
| Specific | TORESIN F-30K | 20° C. or higher | 96 | A | A | A | 98 |
| polymer 5 | | | | | | | |
| Specific | TORESIN EF-30T | 20° C. or higher | 97 | A | A | A | 96 |
| polymer 6 | | | | | | | |
| Specific | ETHYL | 20° C. or higher | 90 | A | A | A | 91 |
| polymer 7 | CELLULOSE 45 | | | | | | |

TABLE 2

| | (A) Specific polymer or | Glass | Weight after | | | 1-methoxy-2- | Weight after |
|---|---|---|---|---|---|---|---|
| | comparative binder | transition | water | Methanol | Ethanol | propanol | ethyl acetate |
| | polymer | temperature | immersion (%) | solubility | solubility | solubility | immersion (%) |
| Specific | ARAKYD 9201N | 20° C. or | 90 | A | A | A | 90 |
| polymer 8 | | higher | | | | | |
| Specific | ARAKYD 9203N | 20° C. or | 90 | A | A | A | 89 |
| polymer 9 | | higher | | | | | |
| Specific | ARAKYD 9205 | 20° C. or | 90 | A | A | A | 88 |
| polymer 10 | | higher | | | | | |
| Specific | BLEMMER | 20° C. or | 85 | A | A | A | 85 |
| polymer 11 | PME200/methyl | higher | | | | | |
| | methacrylate | | | | | | |
| Specific | BLEMMER | 20° C. or | 86 | X | A | A | 84 |
| polymer 12 | PME100/methyl | higher | | | | | |
| | methacrylate | | | | | | |
| Specific | Styrene/2-hydroxyethyl | 20° C. or | 84 | X | X | A | 85 |
| polymer 13 | methacrylate | higher | | | | | |
| Specific | Styrene/2-hydroxyethyl | Below 20° C. | 82 | X | X | A | 82 |
| polymer 14 | methacrylate/n-butyl | | | | | | |
| | methacrylate | | | | | | |

TABLE 3

| | (A) Specific polymer | Glass | Weight after | | | 1-methoxy-2- | Weight after |
|---|---|---|---|---|---|---|---|
| | or comparative binder | transition | water | Methanol | Ethanol | propanol | ethyl acetate |
| | polymer | temperature | immersion (%) | solubility | solubility | solubility | immersion (%) |
| Comparative | Styrene-isoprene- | Below 20° C. | 100 | X | X | X | 52 |
| polymer C-1 | styrene block | | | | | | |
| | copolymer | | | | | | |
| Comparative | N 2304 | Below 20° C. | 75 | X | X | X | 33 |
| polymer C-2 | | | | | | | |
| Comparative | JSR EP21 | Below 20° C. | 100 | X | X | X | 53 |
| polymer C-3 | | | | | | | |
| Comparative | Polymer prepared by blocking | Below 20° C. | 75 | X | X | X | 22 |
| polymer C-4 | the terminals of a | | | | | | |
| | polyaddition product of | | | | | | |
| | polycarbonate | | | | | | |
| | diol/tolylenediisocyanate with | | | | | | |
| | 2-methacryloyloxy ethyl | | | | | | |
| | isocyanate | | | | | | |
| Comparative | Elastosil | Below 20° C. | 100 | X | X | X | 69 |
| polymer C-5 | | | | | | | |
| Comparative | GOHSENAL T-215 | 20° C. or higher | 0 | X | X | X | 98 |
| polymer C-6 | | | | | | | |

TABLE 4

| | Composition of relief forming layer | | | | |
|---|---|---|---|---|---|
| | (A) Specific polymer or | | (C) Polymerizable | (D) Polymerization | (E) Photo-thermal |
| | comparative binder polymer | Polymer Tg (° C.) | compound | initiator | conversion agent |
| Example 1 | Specific polymer 1 | Room temperature or higher | M-1 | PERBUTYL Z | Carbon black |
| Example 2 | Specific polymer 1 | Room temperature or higher | M-1 | PERBUTYL Z | ADS-820HO |
| Example 3 | Specific polymer 1 | Room temperature or higher | M-1 | V-601 | ADS-820HO |
| Example 4 | Specific polymer 1 | Room temperature or higher | M-2 | PERBUTYL Z | Carbon black |
| Example 5 | Specific polymer 2 | Room temperature or higher | M-1 | PERBUTYL Z | Carbon black |
| Example 6 | Specific polymer 3 | Room temperature or higher | M-1 | PERBUTYL Z | Carbon black |
| Example 7 | Specific polymer 4 | Room temperature or higher | M-1 | PERBUTYL Z | Carbon black |
| Example 8 | Specific polymer 5 | Room temperature or higher | M-2 | PERBUTYL Z | Carbon black |
| Example 9 | Specific polymer 6 | Room temperature or higher | M-2 | PERBUTYL Z | Carbon black |
| Example 10 | Specific polymer 7 | Room temperature or higher | M-2 | PERBUTYL Z | Carbon black |
| Example 11 | Specific polymer 8 | Room temperature or higher | M-2 | PERBUTYL Z | Carbon black |
| Example 12 | Specific polymer 9 | Room temperature or higher | M-2 | PERBUTYL Z | Carbon black |
| Example 13 | Specific polymer 10 | Room temperature or higher | M-2 | PERBUTYL Z | Carbon black |
| Example 14 | Specific polymer 11 | Room temperature or higher | M-2 | PERBUTYL Z | Carbon black |
| Example 15 | Specific polymer 12 | Room temperature or higher | M-2 | PERBUTYL Z | Carbon black |

TABLE 5

| | Composition of relief forming layer | | | | |
|---|---|---|---|---|---|
| | | | | (D) | |
| | (A) Specific polymer or comparative | | (C) Polymerizable | Polymerization | (E) Photo-thermal |
| | binder polymer | Polymer Tg (° C.) | compound | initiator | conversion agent |
| Example 16 | Specific polymer 13 | Room temperature or higher | M-2 | PERBUTYL Z | Carbon black |
| Example 17 | Specific polymer 14 | Below room temperature | M-2 | PERBUTYL Z | Carbon black |
| Comparative example 1 | Comparative polymer C-1 | Below room temperature | M-2 | PERBUTYL Z | Carbon black |
| Comparative example 2 | Comparative polymer C-2 | Below room temperature | M-2 | PERBUTYL Z | Carbon black |
| Comparative example 3 | Comparative polymer C-3 | Below room temperature | M-2 | PERBUTYL Z | Carbon black |
| Comparative example 4 | Comparative polymer C-4 | Below room temperature | M-2 | PERBUTYL Z | Carbon black |
| Comparative example 5 | Comparative polymer C-4 | Below room temperature | M-2 | PERBUTYL Z | ADS-820HO |
| Comparative example 6 | Comparative polymer C-4 | Below room temperature | M-2 | V-601 | ADS-820HO |
| Comparative example 7 | Comparative polymer C-5 | Below room temperature | M-2 | PERBUTYL Z | ADS-820HO |
| Comparative example 8 | Comparative polymer C-6 | Room temperature or higher | M-2 | PERBUTYL Z | ADS-820HO |

5. Evaluation of Relief Printing Plate

### (5-1) Evaluation of Engraving Depth

“Engraving depth” of the relief layer of in the relief printing plate obtained by laser engraving each of the relief printing plate precursors for Examples 1 to 17 and Comparative examples 1 to 8 was measured as described below. The “engraving depth” herein means a distance between an engraved position (height) and a not-engraved position (height) observed in a cross section of the relief layer. The engraving depth was measured by observing the cross section of the relief layer by a super depth color 3D measuring microscope (trade name: VK9510, manufactured by Keyence Corporation). It is estimated that the engraving sensitivity is more excellent as the graving depth is larger. The results of the evaluation of the engraving depth are shown in the following Tables 6 to 8.

### (5-2) Width of Engraved Fine Line

The minimum width of a laser engraved fine line which allows the engraved depth of not less than 0.002 mm, which is shown as “Minimum Open Fine Line Width” in Table 2, was measured herein. The smaller the fine line width is, the higher the engraving sensitivity and reproducibility in highly fine image are. The results of the evaluation of the engraving depth are shown in the following Tables 6 to 8 together with the types of the laser used for the engraving.

(5-3) Aqueous Ink Resistance

An immersion test was performed using an aqueous ink (trade name: SAC KI-74-19 BLACK, manufactured by INCTEC INC) with no dilution. A PET support was removed from each of the relief printing plate precursors having a relief forming layer subjected to the thermal crosslinking, which had been made in Examples 1 to 17 and Comparative Examples 1 to 8, and 5 g of the 1-mm thick relief forming layer was taken to make a sample. The sample was immersed in the aqueous ink for 24 hours in an atmosphere at 25° C., and then taken out and weighed after drying at 100° C. for 5 hours. Then, the ratio (residual ratio) of the weight of the sample measured after the immersion and drying was calculated with setting the sample weight measured before the immersion as 100%.

When the residual ratio was 75% or more, the sample was evaluated as having sufficient suitability for aqueous inks for practical applications. The results are listed in Tables 6 to 8.

(5-4) UV Ink Resistance

An immersion test was performed using an aqueous ink (trade name: TOKA UV500 INDIGO, manufactured by T&K TOKA Co., Ltd.) with no dilution. A PET support was removed from each of the relief printing plate precursors having a relief forming layer subjected to the thermal crosslinking, which had been made in Examples 1 to 17 and Comparative Examples 1 to 8, and 5 g of the 1-mm thick relief forming layer was taken to make a sample. The sample was immersed in the UV ink for 24 hours in an atmosphere at 25° C., and then taken out and weighed after drying at 100° C. for 5 hours. Then, the ratio (residual ratio) of the weight of the sample measured after the immersion and drying was calculated with setting the sample weight measured before the immersion as 100%.

When the residual ratio was 75% or more, the sample was evaluated as having sufficient suitability for UV inks for practical applications. The results are listed in Tables 6 to 8.

(5-5) Shore A Hardness

The Shore A hardness of each of the relief forming layers of the relief printing plate precursors for Examples 2 to 17 and Comparative Examples 1 to 8 was measured in the same manner as in Example 1. The results are listed in Tables 6 to 8.

(5-6) Removability of Remnants by Rinsing

Each of the relief forming layers of the relief printing plate precursors for Examples 2 to 17 and Comparative Examples 1 to 8 was immersed in water and rubbed with a toothbrush (trade name: CLINICA HABIRASHI FLAT, manufactured by Lion Corporation) for ten times. After the rubbing, the presence of remnants on a rubbed surface of the relief forming layer was observed by visual observation and graded according to the following criteria. The results are listed in Tables 6 to 8.

A: No remnant was observed.

B: Almost no remnant was observed.

C: A little amount of remnant was observed.

X: Remnant was observed (namely, remnants could not be removed by the rinsing.)

TABLE 6

| | | | | Minimum | | | Weight | Weight | | |
|---|---|---|---|---|---|---|---|---|---|---|
| | Engraved depth (μm) | | | hollow line width (mm) | | | after | after UV | | |
| | Light | Light | Light | Light | Light | Light | aqueous ink | ink | Shore A | Removability |
| | source: | source: | source: | source: | source: FC- | source: | immersion | immersion | hardness | of Remnants |
| | CO₂ | FC-LD | FD-100 | CO₂ | LD | FD-100 | (%) | (%) | (° C.) | by Rinsing |
| Example 1 | 370 | 666 | 555 | 0.040 | 0.024 | 0.038 | 100 | 100 | 75 | B |
| Example 2 | 345 | 623 | 520 | 0.047 | 0.028 | 0.045 | 100 | 100 | 76 | B |
| Example 3 | 327 | 589 | 490 | 0.049 | 0.029 | 0.046 | 100 | 100 | 78 | B |
| Example 4 | 356 | 637 | 532 | 0.045 | 0.027 | 0.043 | 100 | 100 | 74 | B |
| Example 5 | 353 | 635 | 530 | 0.045 | 0.027 | 0.043 | 100 | 100 | 79 | A |
| Example 6 | 352 | 636 | 530 | 0.042 | 0.025 | 0.040 | 100 | 100 | 80 | A |
| Example 7 | 352 | 634 | 528 | 0.044 | 0.026 | 0.042 | 100 | 100 | 80 | A |
| Example 8 | 351 | 633 | 528 | 0.044 | 0.026 | 0.042 | 100 | 100 | 80 | B |
| Example 9 | 352 | 634 | 528 | 0.044 | 0.026 | 0.042 | 100 | 100 | 74 | B |
| Example | 340 | 612 | 510 | 0.047 | 0.028 | 0.045 | 95 | 93 | 88 | B |
| 10 | | | | | | | | | | |

TABLE 7

| | | | | Minimum | | | Weight | Weight | | |
|---|---|---|---|---|---|---|---|---|---|---|
| | Engraved depth (μm) | | | hollow line width (mm) | | | after | after UV | | |
| | Light | Light | Light | Light | Light | Light | aqueous ink | ink | Shore A | Removability |
| | source: | source: | source: | source: | source: FC- | source: | immersion | immersion | hardness | of Remnants |
| | CO₂ | FC-LD | FD-100 | CO₂ | LD | FD-100 | (%) | (%) | (° C.) | by Rinsing |
| Example | 341 | 611 | 510 | 0.045 | 0.027 | 0.043 | 94 | 92 | 78 | B |
| 11 | | | | | | | | | | |
| Example | 340 | 611 | 510 | 0.049 | 0.029 | 0.046 | 94 | 94 | 78 | B |
| 12 | | | | | | | | | | |
| Example | 333 | 600 | 500 | 0.050 | 0.03 | 0.048 | 93 | 95 | 74 | B |
| 13 | | | | | | | | | | |
| Example | 334 | 599 | 500 | 0.050 | 0.03 | 0.048 | 89 | 90 | 84 | B |
| 14 | | | | | | | | | | |
| Example | 327 | 587 | 490 | 0.052 | 0.031 | 0.050 | 86 | 86 | 80 | B |
| 15 | | | | | | | | | | |
| Example | 312 | 564 | 470 | 0.057 | 0.034 | 0.054 | 84 | 84 | 80 | B |
| 16 | | | | | | | | | | |
| Example | 303 | 546 | 455 | 0.059 | 0.035 | 0.056 | 81 | 80 | 74 | B |
| 17 | | | | | | | | | | |

TABLE 8

| | | | | | | | | Weight | | |
|---|---|---|---|---|---|---|---|---|---|---|
| | Engraved depth (μm) | | | Minimum hollow line width (mm) | | | Weight after | after | | |
| | Light | Light | Light | Light | | Light | aqueous ink | UV ink | Shore A | Removability |
| | source: | source: | source: | source: | Light source: | source: FD- | immersion | immersion | hardness | of Remnants |
| | CO₂ | FC-LD | FD-100 | CO₂ | FC-LD | 100 | (%) | (%) | (° C.) | by Rinsing |
| Comparative | 243 | 437 | 365 | 0.074 | 0.045 | 0.072 | 100 | 52 | 48 | D |
| example 1 | | | | | | | | | | |
| Comparative | 241 | 431 | 360 | 0.076 | 0.045 | 0.072 | 100 | 53 | 45 | D |
| example 3 | | | | | | | | | | |
| Comparative | 298 | 533 | 445 | 0.059 | 0.035 | 0.056 | 75 | 22 | 96 | C |
| example 4 | | | | | | | | | | |
| Comparative | 293 | 527 | 440 | 0.060 | 0.036 | 0.058 | 75 | 20 | 95 | C |
| example 5 | | | | | | | | | | |
| Comparative | 297 | 534 | 445 | 0.060 | 0.036 | 0.058 | 70 | 20 | 95 | C |
| example 6 | | | | | | | | | | |
| Comparative | 227 | 407 | 340 | 0.076 | 0.047 | 0.075 | 100 | 69 | 40 | C |
| example 7 | | | | | | | | | | |
| Comparative | 294 | 527 | 440 | 0.060 | 0.036 | 0.058 | 0 | 98 | 45 | B |
| example 8 | | | | | | | | | | |

As shown in Table 3, larger engraved depth could be obtained by the relief printing plates of Examples, which are made of resin compositions for laser engraving containing the specific polymer (A) as the binder polymer, as compared to the relief printing plates of Comparative Examples. In addition, the relief printing plates of Examples were superior in both of aqueous ink resistance and UV ink resistance as compared to the relief printing plates of Comparative Examples. These results indicate that the resin compositions for laser engraving prepared in Examples can provide high engraving sensitivity and good productivity as well as be suitable for various printing inks including aqueous inks and UV inks.

Comparison between Examples 1 and 2 indicates that the printing plates having carbon black as the photo-thermal conversion agent can exhibit higher engraving sensitivity than those having a near-infrared absorbing pigment. Comparison between Examples 2 and 3 indicates that the printing plates having an organic peroxide as the polymerization initiator can exhibit higher engraving sensitivity than those having an azo compound.

Further, comparison between Example 1 and Examples 5, 6, and 7 indicates that the printing plates having the specific polymer having a higher molecular weight can exhibit better removability of remnants by rinsing.

The evaluation results may further indicate that the use of a plate making apparatus equipped with a fiber semiconductor laser and a FC-LD light source can further improve the engraved depth and thin line reproducibility for the same relief printing plate precursor.

What is claimed is:

1. A relief printing plate precursor for laser engraving, comprising a relief forming layer, the relief forming layer comprising a resin composition for laser engraving, and the resin composition for laser engraving comprising a binder polymer (A) that is insoluble in water and soluble in an alcohol having 1 to 4 carbon atoms.

2. The relief printing plate precursor for laser engraving of claim 1, wherein the glass transition temperature of the binder polymer (A) is from 20° C. to below 200° C.

3. The relief printing plate precursor for laser engraving of claim 1, wherein the binder polymer (A) comprises one or more selected from the group consisting of polyurethane, a polyvinyl butyral compound, polyamide, a cellulose compound, and an acrylic resin.

4. The relief printing plate precursor for laser engraving of claim 1, wherein:
the relief forming layer further comprises a binder polymer (B) which is either soluble in water, soluble in an alcohol having 1 to 4 carbon atoms or soluble both in water and in an alcohol having 1 to 4 carbon atoms; and
the mass ratio of the amount of the specific polymer (A) contained in the relief layer to the sum of the amounts of the specific polymer (A) and the binder polymer (B) contained in the relief layer is from 0.3 to 1.0.

5. The relief printing plate precursor for laser engraving of claim 1, wherein the relief forming layer comprises a polymerizable compound (C).

6. The relief printing plate precursor for laser engraving of claim 5, wherein the relief forming layer further comprises a polymerization initiator (D).

7. The relief printing plate precursor for laser engraving of claim 1, wherein the relief forming layer further comprises a photo-thermal conversion agent which absorbs light having a wavelength in a range of 700 nm to 1,300 nm.

8. A method for manufacturing a relief printing plate, the method comprising:
crosslinking at least a portion of components of the relief forming layer of the relief printing plate precursor for laser engraving of claim 1 by applying at least one of light or heat; and
laser engraving the relief forming layer that has been subjected to the crosslinking to form a relief layer.

9. The method for manufacturing a relief printing plate of claim 8, wherein the crosslinking comprises application of heat to the relief forming layer.

10. A relief printing plate, comprising a relief layer provided over a support and manufactured by the method for manufacturing a relief printing plate of claim 8.

11. The relief printing plate of claim 10, wherein the thickness of the relief layer is in the range of 0.05 mm to 10 mm.

12. The relief printing plate of claim 10, wherein the Shore A hardness of the relief layer is in the range of 50° to 90°.
